(19) United States
(12) Patent Application Publication
(10) Pub. No.: US 2026/0079190 A1
(43) Pub. Date: Mar. 19, 2026

(54) WI-FI SENSING TAKING INTO CONSIDERATION RECEIVED NOISE POWER INFORMATION

(71) Applicant: COGNITIVE SYSTEMS CORP., Waterloo (CA)

(72) Inventors: Chris BEG, Waterloo, Ontario (CA); Mohammad OMER, Waterloo, Ontario (CA)

(21) Appl. No.: 19/107,981

(22) PCT Filed: Aug. 29, 2023
(86) PCT No.: PCT/IB2023/058534

§ 371 Date: Feb. 28, 2025

Related U.S. Application Data
(60) Provisional application No. 63/374,318, filed on Sep. 1, 2022.
(60) Provisional application No. 63/378,066, filed on Oct. 1, 2022.

(51) Int. Cl. G01R 29/26

(52) U.S. Cl. CPC G01R 29/26

(57) ABSTRACT

A method and system for Wi-Fi sensing are provided. A networking device is configured to operate as a sensing responder and includes at least one processor configured to execute instructions. The instructions cause the networking device to receive a sensing transmission transmitted from a sensing transmitter, perform a sensing measurement on the sensing transmission and obtain a received noise power measurement. The received noise power measurement is associated with the sensing measurement; and the sensing measurement and the received noise power measurement are transferred to a sensing initiator.

### RELATED APPLICATIONS

The present application claims priority to U.S. Provisional Application No. 63/374,318, filed on Sep. 1, 2022 and to U.S. Provisional Application No. 63/378,066, filed on Oct. 1, 2022.

### TECHNICAL FIELD

The present disclosure generally relates to systems and methods for Wi-Fi sensing. In particular, the present disclosure relates to systems and methods for Wi-Fi sensing taking into consideration received noise power information.

### BACKGROUND OF THE DISCLOSURE

A Wi-Fi sensing system may be configured to detect features of interest in a sensing space. The Wi-Fi sensing system may be a network of Wi-Fi-enabled devices which are part of an IEEE 802.11 network (sometimes referred to as a basic service set (BSS) or extended service set (ESS)). The features of interest may include motion of objects and motion tracking, presence detection, intrusion detection, gesture recognition, fall detection, breathing rate detection, and other applications. The sensing space may refer to any physical space in which a Wi-Fi sensing system may operate and may include a place of abode, a place of work, a shopping mall, a sports hall or sports stadium, a garden, or any other physical space.

A typical Wi-Fi sensing system includes a sensing transmitter (which may be an access point (AP) or a non-AP station (STA)) and a sensing receiver (which is an AP if the sensing transmitter is a STA, and a STA if the sensing transmitter is an AP). A sensing transmission is sent from the sensing transmitter to the sensing receiver. The sensing measurement is made using the sensing transmission at the sensing receiver.

### BRIEF SUMMARY OF THE DISCLOSURE

The present disclosure generally relates to systems and methods for Wi-Fi sensing. In particular, the present disclosure relates to systems and methods for Wi-Fi sensing using received noise power information.

Methods are provided for Wi-Fi sensing. In an example embodiment, a method for Wi-Fi sensing is described. The method may be carried out by a networking device configured to operate as a sensing responder and including at least one processor configured to execute instructions. The method includes receiving, by the sensing responder, a sensing transmission transmitted from a sensing transmitter, and performing, by the sensing responder, a sensing measurement on the sensing transmission. In some embodiments, the method includes obtaining, by the sensing responder, a received noise power measurement, and associating, by the sensing responder, the received noise power measurement with the sensing measurement. In some embodiments, the method includes transferring, by the sensing responder, the sensing measurement and the received noise power measurement to a sensing initiator.

In some embodiments, obtaining the received noise power measurement includes accessing the received noise power measurement from data storage. In examples, accessing the received noise power measurement from data storage includes accessing the received noise power measurement according to a gain and a frequency.

In some embodiments, the sensing responder is a sensing receiver.

In some embodiments, transmission of the sensing transmission is performed responsive to an action of a sensing initiator.

In some embodiments, associating the received noise power measurement with the sensing measurement is performed based upon a gain or a frequency or both.

In some embodiments, obtaining the received noise power measurement includes modeling a response of the sensing responder and optionally a transmission channel.

In some embodiments, obtaining the received noise power measurement includes calibrating the sensing responder.

In some embodiments, obtaining the received noise power measurement includes operating the sensing responder in an engineering mode, and determining the received noise power measurement in the engineering mode.

In some embodiments, obtaining the received noise power measurement includes determining the received noise power measurement during a standard operational mode of the sensing responder. The standard operational mode is the normal operating mode (i.e., not the calibration mode or the engineering mode) of the sensing responder (which may also be a sensing receiver). In an example, determining the received noise power measurement may occur between receiving the sensing transmission and transferring the sensing measurement and the received noise power measurement. In examples, determining the received noise power measurement includes performing the received noise power measurement during a period in which no signal is received. Further, in examples, the period in which no signal is received is associated with null carriers in the sensing transmission. In an example, the period in which no signal is received is associated with gaps between the sensing transmission and another transmission.

In some embodiments, the method further includes determining a time of measurement and associating the time of measurement with the received noise power measurement.

In some embodiments, the method further includes generating time domain channel representation information (TD-CRI) of the sensing transmission, and generating a time domain received noise power measurement.

In some embodiments, the method further includes transferring the sensing measurement and the received noise power measurement to a sensing application, and performing, by the sensing application, a sensing algorithm to achieve a sensing goal according to the sensing measurement and the received noise power measurement. In examples, transferring the sensing measurement and the received noise power measurement to the sensing application and transferring the sensing measurement and the received noise power measurement to the sensing initiator are performed by transferring the sensing measurement and the received noise power measurement to a second networking device acting as the sensing initiator and executing the sensing application. In some examples, transferring the sensing measurement and the received noise power measurement to the sensing application includes transferring the sensing measurement and the received noise power measurement from a second networking device acting as the sensing initiator to a third networking device executing the sensing application.

In some embodiments, transferring the sensing measurement and the received noise power measurement to the sensing initiator includes transmitting the sensing measurement and the received noise power measurement to a second networking device acting as the sensing initiator in a sensing measurement report.

In some embodiments, the method further includes generating a data table including a plurality of received noise power measurements stored according to associated gains and associated frequencies, the data table including the received noise power measurement. In some embodiments, the method includes transferring the data table to a second networking device configured to execute a sensing application.

In another example embodiment, a method for Wi-Fi sensing is described. The method may be carried out by a networking device configured to operate as a sensing initiator and including at least one processor configured to execute instructions. The method includes transmitting, by the sensing initiator, a sensing transmission to a sensing responder, and receiving, by the sensing initiator, a sensing measurement based on the sensing transmission. In some embodiments, the method includes obtaining, by the sensing initiator, a received noise power measurement associated with the sensing responder, and transferring, by the sensing initiator, the sensing measurement and the received noise power measurement to a sensing application.

Other aspects and advantages of the disclosure will become apparent from the following detailed description, taken in conjunction with the accompanying drawings, which illustrate by way of example, the principles of the disclosure.

### BRIEF DESCRIPTION OF THE DRAWINGS

The foregoing and other objects, aspects, features, and advantages of the disclosure will become more apparent and better understood by referring to the following description taken in conjunction with the accompanying drawings, in which:

FIG. 1 is a diagram showing an example wireless communication system.

FIG. 2A and FIG. 2B are diagrams showing example wireless signals communicated between wireless communication devices.

FIG. 3A and FIG. 3B are plots showing examples of channel responses computed from the wireless signals communicated between wireless communication devices in FIG. 2A and FIG. 2B.

FIG. 4A and FIG. 4B are diagrams showing example channel responses associated with motion of an object in distinct regions of a space.

FIG. 4C and FIG. 4D are plots showing the example channel responses of FIG. 4A and FIG. 4B overlaid on an example channel response associated with no motion occurring in the space.

FIG. 5 depicts an implementation of some of an architecture of a system for Wi-Fi sensing, according to some embodiments.

FIG. 6 depicts an example of a WLAN sensing procedure, according to some embodiments.

FIG. 7A depicts an example of a Sensing Measurement Setup Request frame format, according to some embodiments.

FIG. 7B illustrates an example of a Sensing Measurement Parameters element, according to some embodiments.

FIG. 7C illustrates an example of a format of a Sensing Measurement Parameters field, according to some embodiments.

FIG. 7D depicts an example of a Sensing Measurement Setup Response frame, according to some embodiments.

FIG. 8A depicts one-to-many and many-to-one aspects of an example of a WLAN sensing procedure, according to some embodiments.

FIG. 8B depicts pairwise aspects of an example of a WLAN sensing procedure, according to some embodiments.

FIG. 9 depicts a message flow of a trigger-based (TB) sensing measurement instance of a WLAN sensing procedure that consists of either NDPA sounding or TF sounding, according to some embodiments.

FIG. 10A and FIG. 10B depict examples of trigger-based (TB) sensing measurement instances, according to some embodiments.

FIG. 11A and FIG. 11B depict an example of a single TB sensing measurement instance including a polling phase, a trigger frame sounding phase, and an NDPA sounding phase, according to some embodiments.

FIG. 12 depicts a message flow of a non-TB sensing measurement instance of a WLAN sensing procedure with both uplink and downlink sounding, according to some embodiments.

FIG. 13 depicts an example of a single non-TB sensing measurement instance, according to some embodiments.

FIG. 14 depicts an example of a Public Action frame format of a Sensing Measurement Report frame and a Sensing Measurement Report field format, according to some embodiments.

FIG. 15A to FIG. 15H depict a hierarchy of fields within a sensing trigger, according to some embodiments.

FIG. 16 depicts an example of a Sensing Measurement Report frame, according to some embodiments.

FIG. 17 illustrates an example of a simplified receive chain of a sensing receiver, according to some embodiments.

FIG. 18 illustrates an example of Sensing Measurement Report element including a provision for received noise power measurement, according to some embodiments.

FIG. 19 illustrates an example of a Sensing Measurement Report frame implemented as a field and including a provision for received noise power measurement, according to some embodiments.

FIG. 20 depicts a flowchart for associating a received noise power measurement with a sensing measurement, and transferring the sensing measurement and the received noise power measurement to a sensing initiator, according to some embodiments.

FIG. 21A and FIG. 21B depict a flowchart for associating a received noise power measurement with a sensing measurement, and transferring the sensing measurement and the received noise power measurement to a sensing application for achieving a sensing goal according to the sensing measurement and the received noise power measurement, according to some embodiments.

FIG. 22 depicts a flowchart for generating a data table including a received noise power measurement, and transferring a sensing measurement and the data table to a sensing initiator, according to some embodiments.

FIG. 23 depicts a flowchart for obtaining a sensing measurement and a received noise power measurement associated with a sensing responder, and transferring the sensing measurement and the received noise power measurement to a sensing application, according to some embodiments.

### DETAILED DESCRIPTION

Wireless sensing enables a device to obtain sensing measurements of transmission channel(s) between two or more devices. With the execution of a wireless sensing procedure, it is possible for a device to obtain sensing measurements useful for detecting and tracking changes in the environment. In some aspects of what is described herein, a wireless sensing system may be used for a variety of wireless sensing applications by processing wireless signals (e.g., radio frequency (RF) signals) transmitted through a space between wireless communication devices. Example wireless sensing applications include motion detection, which can include the following: detecting motion of objects in the space, motion tracking, breathing detection, breathing monitoring, presence detection, gesture detection, gesture recognition, human detection (moving and stationary human detection), human tracking, fall detection, speed estimation, intrusion detection, walking detection, step counting, respiration rate detection, apnea estimation, posture change detection, activity recognition, gait rate classification, gesture decoding, sign language recognition, hand tracking, heart rate estimation, breathing rate estimation, room occupancy detection, human dynamics monitoring, and other types of motion detection applications. Other examples of wireless sensing applications include object recognition, speaking recognition, keystroke detection and recognition, tamper detection, touch detection, attack detection, user authentication, driver fatigue detection, traffic monitoring, smoking detection, school violence detection, human counting, human recognition, bike localization, human queue estimation, Wi-Fi imaging, and other types of wireless sensing applications. For instance, the wireless sensing system may operate as a motion detection system to detect the existence and location of motion based on Wi-Fi signals or other types of wireless signals. As described in more detail below, a wireless sensing system may be configured to control measurement rates, wireless connections, and device participation, for example, to improve system operation or to achieve other technical advantages. The system improvements and technical advantages achieved when the wireless sensing system is used for motion detection are also achieved in examples where the wireless sensing system is used for another type of wireless sensing application.

In some example wireless sensing systems, a wireless signal includes a component (e.g., a synchronization preamble in a Wi-Fi PHY frame, or another type of component) that wireless devices can use to estimate a channel response or other channel information, and the wireless sensing system can detect motion (or another characteristic depending on the wireless sensing application) by analyzing changes in the channel information collected over time. In some examples, a wireless sensing system can operate similar to a bistatic radar system, where a Wi-Fi access point (AP) assumes the receiver role, and each Wi-Fi device (station (STA), node, or peer) connected to the AP assumes the transmitter role. The wireless sensing system may trigger a connected device to generate a transmission and produce a channel response measurement at a receiver device. This triggering process can be repeated periodically to obtain a sequence of time variant measurements. A wireless sensing algorithm may then receive the generated time-series of channel response measurements (e.g., computed by Wi-Fi receivers) as input, and through a correlation or filtering process, may then make a determination (e.g., determine if there is motion or no motion within the environment represented by the channel response, for example, based on changes or patterns in the channel estimations). In examples where the wireless sensing system detects motion, it may also be possible to identify a location of the motion within the environment based on motion detection results among a number of wireless devices.

Accordingly, wireless signals received at each of the wireless communication devices in a wireless communication network may be analyzed to determine channel information for the various communication links (between respective pairs of wireless communication devices) in the network. The channel information may be representative of a physical medium that applies a transfer function to wireless signals that traverse a space. In some instances, the channel information includes a channel response. Channel responses can characterize a physical communication path, representing the combined effect of, for example, scattering, fading, and power decay within the space between the transmitter and receiver. In some instances, the channel information includes beamforming state information (e.g., a feedback matrix, a steering matrix, channel state information, etc.) provided by a beamforming system. Beamforming is a signal processing technique often used in multi antenna (multiple-input/multiple-output (MIMO)) radio systems for directional signal transmission or reception. Beamforming can be achieved by operating elements in an antenna array in such a way that signals at some angles experience constructive interference while others experience destructive interference.

The channel information for each of the communication links may be analyzed (e.g., by a hub device or other device in a wireless communication network, or a sensing transmitter, sensing receiver, or sensing initiator communicably coupled to the network) to, for example, detect whether motion has occurred in the space, to determine a relative location of the detected motion, or both. In some aspects, the channel information for each of the communication links may be analyzed to detect whether an object is present or absent, e.g., when no motion is detected in the space.

In some cases, a wireless sensing system can control a node measurement rate. For instance, a Wi-Fi motion system may configure variable measurement rates (e.g., channel estimation/environment measurement/sampling rates) based on criteria given by a current wireless sensing application (e.g., motion detection). In some implementations, when no motion is present or detected for a period of time, for example, the wireless sensing system can reduce the rate that the environment is measured, such that the connected device will be triggered or caused to make sensing transmissions or sensing measurements less frequently. In some implementations, when motion is present, for example, the wireless sensing system can increase the triggering rate or sensing transmissions rate or sensing measurement rate to produce a time-series of measurements with finer time resolution. Controlling a variable sensing measurement rate can allow energy conservation (through the device triggering), reduce processing (less data to correlate or filter), and improve resolution during specified times.

In some cases, a wireless sensing system can perform band steering or client steering of nodes throughout a wireless network, for example, in a Wi-Fi multi-AP or extended service set (ESS) topology, multiple coordinating wireless APs each provide a basic service set (BSS) which may occupy different frequency bands and allow devices to transparently move between from one participating AP to another (e.g., mesh). For instance, within a home mesh network, Wi-Fi devices can connect to any of the APs, but typically select one with good signal strength. The coverage footprint of the mesh APs typically overlap, often putting each device within communication range or more than one AP. If the AP supports multi-bands (e.g., 2.4 GHz and 5 GHZ), the wireless sensing system may keep a device connected to the same physical AP but instruct it to use a different frequency band to obtain more diverse information to help improve the accuracy or results of the wireless sensing algorithm (e.g., motion detection algorithm). In some implementations, the wireless sensing system can change a device from being connected to one mesh AP to being connected to another mesh AP. Such device steering can be performed, for example, during wireless sensing (e.g., motion detection), based on criteria detected in a specific area to improve detection coverage, or to better localize motion within an area.

In some cases, beamforming may be performed between wireless communication devices based on some knowledge of the communication channel (e.g., through feedback properties generated by a receiver), which can be used to generate one or more steering properties (e.g., a steering matrix) that are applied by a transmitter device to shape the transmitted beam/signal in a particular direction or directions. Thus, changes to the steering or feedback properties used in the beamforming process indicate changes, which may be caused by moving objects, in the space accessed by the wireless communication system. For example, motion may be detected by substantial changes in the communication channel, e.g., as indicated by a channel response, or steering or feedback properties, or any combination thereof, over a period of time.

In some implementations, for example, a steering matrix may be generated at a transmitter device (beamformer) based on a feedback matrix provided by a receiver device (beamformee) based on channel sounding. Because the steering and feedback matrices are related to propagation characteristics of the channel, these matrices change as objects move within the channel. Changes in the channel characteristics are accordingly reflected in these matrices, and by analyzing the matrices, motion can be detected, and different characteristics of the detected motion can be determined. In some implementations, a spatial map may be generated based on one or more beamforming matrices. The spatial map may indicate a general direction of an object in a space relative to a wireless communication device. In some cases, many beamforming matrices (e.g., feedback matrices or steering matrices) may be generated to represent a multitude of directions that an object may be located relative to a wireless communication device. These many beamforming matrices may be used to generate the spatial map. The spatial map may be used to detect the presence of motion in the space or to detect a location of the detected motion.

In some instances, a motion detection system can control a variable device measurement rate in a motion detection process. For example, a feedback control system for a multi-node wireless motion detection system may adaptively change the sample rate based on environmental conditions. In some cases, such controls can improve operation of the motion detection system or provide other technical advantages. For example, the measurement rate may be controlled in a manner that optimizes or otherwise improves air-time usage versus detection ability suitable for a wide range of different environments and different motion detection applications. The measurement rate may be controlled in a manner that reduces redundant measurement data to be processed, thereby reducing processor load/power requirements. In some cases, the measurement rate is controlled in a manner that is adaptive, for instance, an adaptive sample can be controlled individually for each participating device. An adaptive sample rate can be used with a tuning control loop for different use cases, or device characteristics.

In some cases, a wireless sensing system can allow devices to dynamically indicate and communicate their wireless sensing capability or wireless sensing willingness to the wireless sensing system. For example, there may be times when a device does not want to be periodically interrupted or triggered to transmit a wireless signal that would allow the AP to produce a channel measurement. For instance, if a device is sleeping, frequently waking the device up to transmit or receive wireless sensing signals could consume resources (e.g., causing a cell phone battery to discharge faster). These and other events could make a device willing or not willing to participate in wireless sensing system operations. In some cases, a cell phone running on its battery may not want to participate, but when the cell phone is plugged into the charger, it may be willing to participate. Accordingly, if the cell phone is unplugged, it may indicate to the wireless sensing system to exclude the cell phone from participating; whereas if the cell phone is plugged in, it may indicate to the wireless sensing system to include the cell phone in wireless sensing system operations. In some cases, if a device is under load (e.g., a device streaming audio or video) or busy performing a primary function, the device may not want to participate; whereas when the same device's load is reduced and participating will not interfere with a primary function, the device may indicate to the wireless sensing system that it is willing to participate.

Example wireless sensing systems are described below in the context of motion detection (detecting motion of objects in the space, motion tracking, breathing detection, breathing monitoring, presence detection, gesture detection, gesture recognition, human detection (moving and stationary human detection), human tracking, fall detection, speed estimation, intrusion detection, walking detection, step counting, respiration rate detection, apnea estimation, posture change detection, activity recognition, gait rate classification, gesture decoding, sign language recognition, hand tracking, heart rate estimation, breathing rate estimation, room occupancy detection, human dynamics monitoring, and other types of motion detection applications). However, the operation, system improvements, and technical advantages achieved when the wireless sensing system is operating as a motion detection system are also applicable in examples where the wireless sensing system is used for another type of wireless sensing application.

In various embodiments of the disclosure, non-limiting definitions of one or more terms that will be used in the description are provided below.

A wireless access point (WAP) or simply an access point (AP) is a networking device in a WLAN network that allows other networking devices in a WLAN network to connect to a wired network. In examples, an AP creates a wireless local area network.

A station (STA) is any device that is connected to a WLAN network and which contains 802.11 compliant MAC and PHY interfaces to the wireless medium. A STA may be a laptop, desktop, smartphone, or a smart appliance. A STA may be fixed, mobile or portable. A STA that does not take on the roles of an AP may be referred to as a non-AP STA.

A term “transmission opportunity (TXOP)” may refer to a negotiated interval of time during which a particular quality of service (QoS) station (e.g., a STA, an AP, or either a STA or an AP, for example in the role of a sensing initiator, a sensing responder, a sensing transmitter or a sensing receiver) may have the right to initiate a frame exchange onto a wireless medium. A QoS access category (AC) of the transmission opportunity may be requested as part of a service or session negotiation.

A term “Quality of Service (QoS) access category (AC)” may refer to an identifier for a frame which classifies a priority of transmission that the frame requires. In an example, four QoS access categories are defined namely AC_VI: Video, AC_VO: Voice, AC_BE: Best-Effort, and AC_BK: Background. Further, each QoS access category may have different TXOP parameters defined for it.

A term “short interframe space (SIFS)” may refer to a period within which a processing element (for example, a microprocessor, dedicated hardware, or any such element) within a device of a Wi-Fi sensing system is able to process data presented to it in a frame. In an example, a short interframe space may be 10 ms.

A term “PHY-layer Protocol Data Unit (PPDU)” may refer to a data unit that includes preamble and data fields. The preamble field may include transmission vector format information and the data field may include payload and higher layer headers.

A term “null data PPDU (NDP)” may refer to a PPDU that does not include a data field. In an example, a null data PPDU may be used for a sensing transmission, where a MAC header of the NDP includes information required for a sensing receiver to make a sensing measurement on the sensing transmission.

A term “transmission parameters” may refer to a set of IEEE 802.11 PHY transmitter configuration parameters which are defined as a part of transmission vector (TXVECTOR) corresponding to a specific PHY and which may be configurable for each PHY-layer PPDU transmission or each null data PPDU (NDP) transmission.

A term “resource unit (RU)” may refer to an allocation of orthogonal frequency division multiplexing (OFDM) channels which may be used to carry a modulated signal. An RU may include a variable number of carriers depending on the mode of the modem.

A term “tone” may refer to an individual subcarrier in an OFDM signal. A tone may be represented in time domain or frequency domain. In time domain, a tone may also be referred to as a symbol. In frequency domain, a tone may also be referred to as a subcarrier.

A term “time domain pulse” may refer to a complex number that represents amplitude and phase of discretized energy in time domain. When frequency domain channel state information values are obtained for each tone from a baseband receiver, time domain pulses may be obtained by performing an IFFT on the channel state information values.

A term “sensing goal” may refer to a goal of a sensing activity at a time. A sensing goal is not static and may change at any time. In an example, a sensing goal may require sensing measurements of a specific type, a specific format, or a specific precision, resolution, or accuracy to be available to a sensing algorithm.

A term “sensing space” may refer to any physical space in which a Wi-Fi sensing system may operate.

A term “wireless local area network (WLAN) sensing session” or “Wi-Fi sensing session” may refer to a period during which objects in a physical space may be probed, detected and/or characterized. In an example, during a WLAN sensing session, several devices participate in, and thereby contribute to the generation of sensing measurements. A WLAN sensing session may be referred to as a “measurement campaign.”

A term “non-sensing message” may refer to a message which is not primarily related to sensing. In an example, non-sensing messages may include data, management, and control messages.

A term “sensing measurement” may refer to a measurement of a state of a wireless channel between a transmitter device (for example, a sensing transmitter) and a receiver device (for example, a sensing receiver) derived from a sensing transmission. In an example, sensing measurement may also be referred to as channel response measurement.

A term “sensing algorithm” may refer to a computational algorithm that achieves a sensing goal. A sensing algorithm may be executed on any device in a Wi-Fi sensing system.

Wireless network management (WNM) may provide information on network conditions and may also provide a means to obtain and exchange WLAN sensing information.

A sensing receiver is a station (STA) that receives sensing transmissions (for example, PPDUs or any other transmission including a data transmission which may be opportunistically used as a sensing transmission) sent by a sensing transmitter and performs sensing measurements as part of a WLAN sensing procedure. An AP is an example of a sensing receiver. In some examples, a STA may also be a sensing receiver.

A sensing transmitter is a station (STA) that transmits a sensing transmission (for example, PPDUs or any other transmission) used for sensing measurements (for example, channel state information) in a WLAN sensing procedure. In an example, a STA is an example of a sensing transmitter. In some examples, an AP may be a sensing transmitter for Wi-Fi sensing purposes, for example where a STA acts as a sensing receiver.

A sensing initiator is a station (STA) that initiates a WLAN sensing procedure. The role of sensing initiator may be taken on by a sensing receiver, a sensing transmitter, or a separate device which includes a sensing algorithm (for example, a remote processing device).

A sensing responder is a station (STA) that participates in a WLAN sensing procedure initiated by a sensing initiator. The role of sensing responder may be taken on by a sensing receiver or a sensing transmitter. In examples, multiple sensing responders may take part in a Wi-Fi sensing session.

A sensing by proxy (SBP) initiator is defined as a non-AP STA acting as a sensing initiator that transmits a SBP Request frame. In examples, sensing by proxy (SBP) enables a non-AP STA to obtain sensing measurements of the channel between an AP and one or more non-AP STAs or between a receive antenna and a transmit antenna of an AP. With the execution of the SBP procedure, it is possible for a non-AP STA to obtain sensing measurements necessary for detecting and tracking changes in the environment. A sensing by proxy (SBP) responder is an AP that receives or is the intended recipient of an SBP Request frame.

A term “sensing transmission” may refer to a transmission made from a sensing transmitter to a sensing receiver which may be used to make a sensing measurement. In an example, a sensing transmission may also be referred to as wireless sensing signal or wireless signal.

A term “sensing trigger message” may refer to a message sent from a sensing initiator to a sensing transmitter to initiate or trigger one or more sensing transmissions.

A term “sensing response message” may refer to a message which is included within a sensing transmission from a sensing transmitter to a sensing receiver. A sensing transmission that includes a sensing response message may be used by a sensing receiver to perform a sensing measurement.

A term “sensing response announcement” may refer to a message that is included within a sensing transmission from a sensing transmitter to a sensing receiver that announces that a sensing response NDP will follow within a short interframe space (SIFS). An example of a sensing response announcement is an NDP announcement, or NDPA. In examples, a sensing response NDP may be transmitted using a requested transmission configuration.

A term “sensing response NDP” may refer to a response transmitted by a sensing transmitter and used for a sensing measurement at a sensing receiver. In examples, a sensing response NDP may be used when a requested transmission configuration is incompatible with transmission parameters required for successful non-sensing message reception. A sensing response NDP may be announced by a sensing response announcement. In an example, a sensing response NDP may be implemented with a null data PPDU. In some examples, a sensing response NDP may be implemented with a frame that does not contain any data.

A term “channel representation information (CRI)” may refer to properties of a communications channel, such as how wireless signals propagate from a sensing transmitter to a sensing receiver along multiple paths, which are known or measured by a technique of channel estimation. For example, CRI may refer to one or more sensing measurements made on one or more sensing transmissions during a sampling instance which together represent the state of the channel at the sampling instance between two devices.

A term “channel state information (CSI)” may refer to an example of CRI which is represented in a frequency domain. CSI is typically a matrix of complex values representing the amplitude attenuation and phase shift of signals (or in-phase and quadrature components of signals), which provides an estimation of a communications channel.

A term “time-domain channel representation information (TD-CRI)” may refer to an example of CRI which is represented in a time domain. TD-CRI may be generated by applying an inverse transform, such as an IDFT or an IFFT, to CSI.

A term “feature of interest” may refer to an item or state of an item in a sensing space which is positively detected and/or identified by a sensing algorithm.

A term “requested transmission configuration” may refer to transmission parameters a sensing transmitter is requested to use when sending a sensing transmission.

A term “delivered transmission configuration” may refer to transmission parameters applied by a sensing transmitter to a sensing transmission.

A term “steering matrix configuration” may refer to a matrix of complex values representing real and complex phase required to pre-condition one or more antenna of a radio frequency (RF) transmission signal chain for each transmit signal. Application of a steering matrix configuration (for example, by a spatial mapper) enables beamforming and beam-steering.

A term “spatial mapper” may refer to a signal processing element that adjusts the amplitude and phase of a signal input to an RF transmission chain in a sensing transmitter. A spatial mapper may include elements to process the signal to each RF chain implemented. The operation carried out may be called spatial mapping. The output of a spatial mapper is one or more spatial streams.

A term “received noise power” may refer to the noise power received or measured at a sensing receiver. In an example, a noise may include random, unwanted variation or fluctuation, and/or frequency interference that interferes with a sensing transmission.

A term “time domain received noise power” may refer to the received noise power in the time domain. The transformation of the received noise power (which are frequency-dependent) into the time domain received noise power may be achieved by use of an IDFT or IFFT.

A term “delay-dependent received noise power” may refer to the received noise power in the time domain, which is dependent on the time delay of the time domain noise pulses received at the sensing receiver.

For purposes of reading the description of the various embodiments below, the following descriptions of the sections of the specifications and their respective contents may be helpful:
Section A describes a wireless communications system, wireless transmissions and sensing measurements which may be useful for practicing embodiments described herein.
Section B describes systems and methods that are useful for a wireless sensing system configurated to send sensing transmissions and make sensing measurements.
Section C describes embodiments of systems and methods that are useful for Wi-Fi sensing taking into consideration received noise power information.

### A. Wireless Communications System, Wireless Transmissions and Sensing Measurements

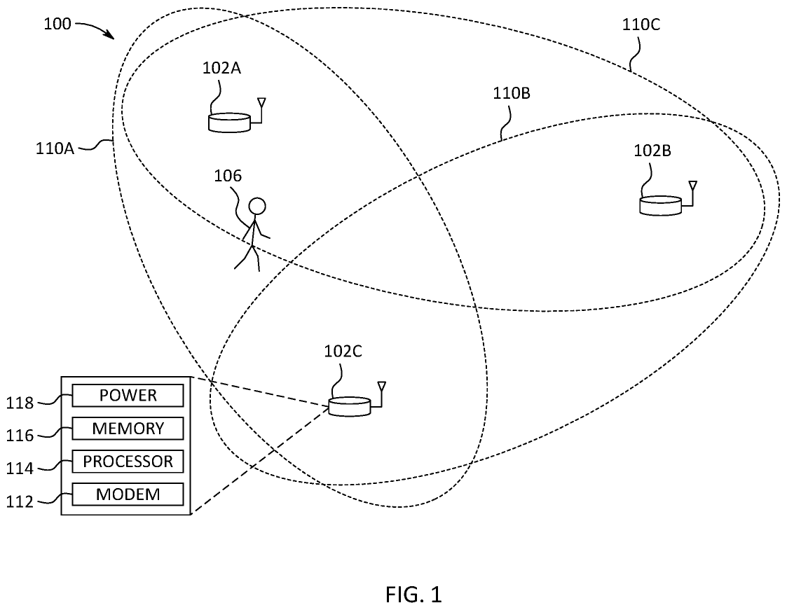

FIG. 1 illustrates wireless communication system 100. Wireless communication system 100 includes three wireless communication devices: first wireless communication device 102A, second wireless communication device 102B, and third wireless communication device 102C. Wireless communication system 100 may include additional wireless communication devices and other components (e.g., additional wireless communication devices, one or more network servers, network routers, network switches, cables, or other communication links, etc.).

Wireless communication devices 102A, 102B, 102C can operate in a wireless network, for example, according to a wireless network standard or another type of wireless communication protocol. For example, the wireless network may be configured to operate as a wireless local area network (WLAN), a personal area network (PAN), a metropolitan area network (MAN), or another type of wireless network. Examples of WLANs include networks configured to operate according to one or more of the 802.11 family of standards developed by IEEE (e.g., Wi-Fi networks), and others. Examples of PANs include networks that operate according to short-range communication standards (e.g., Bluetooth®., Near Field Communication (NFC), ZigBee), millimeter wave communications, and others.

In some implementations, wireless communication devices 102A, 102B, 102C may be configured to communicate in a cellular network, for example, according to a cellular network standard. Examples of cellular networks include networks configured according to 2G standards such as Global System for Mobile (GSM) and Enhanced Data rates for GSM Evolution (EDGE) or EGPRS; 3G standards such as code division multiple access (CDMA), wideband code division multiple access (WCDMA), Universal Mobile Telecommunications System (UMTS), and time division synchronous code division multiple access (TD-SCDMA); 4G standards such as Long-Term Evolution (LTE) and LTE-Advanced (LTE-A); 5G standards, and others.

In the example shown in FIG. 1, wireless communication devices 102A, 102B, 102C can be, or they may include standard wireless network components. For example, wireless communication devices 102A, 102B, 102C may be commercially-available Wi-Fi APs or another type of wireless access point (WAP) performing one or more operations as described herein that are embedded as instructions (e.g., software or firmware) on the modem of the WAP. In some cases, wireless communication devices 102A, 102B, 102C may be nodes of a wireless mesh network, such as, for example, a commercially-available mesh network system (e.g., Plume Wi-Fi, Google Wi-Fi, Qualcomm Wi-Fi SON, etc.). In some cases, another type of standard or conventional Wi-Fi transmitter device may be used. In some instances, one or more of wireless communication devices 102A, 102B, 102C may be implemented as WAPs in a mesh network, while other wireless communication device(s) 102A, 102B, 102C are implemented as leaf devices (e.g., mobile devices, smart devices, etc.) that access the mesh network through one of the WAPs. In some cases, one or more of wireless communication devices 102A, 102B, 102C is a mobile device (e.g., a smartphone, a smart watch, a tablet, a laptop computer, etc.), a wireless-enabled device (e.g., a smart thermostat, a Wi-Fi enabled camera, a smart TV), or another type of device that communicates in a wireless network.

Wireless communication devices 102A, 102B, 102C may be implemented without Wi-Fi components; for example, other types of standard or non-standard wireless communication may be used for motion detection. In some cases, wireless communication devices 102A, 102B, 102C can be, or they may be part of, a dedicated motion detection system. For example, the dedicated motion detection system can include a hub device and one or more beacon devices (as remote sensor devices), and wireless communication devices 102A, 102B, 102C can be either a hub device or a beacon device in the motion detection system.

As shown in FIG. 1, wireless communication device 102C includes modem 112, processor 114, memory 116, and power unit 118; any of wireless communication devices 102A, 102B, 102C in wireless communication system 100 may include the same, additional, or different components, and the components may be configured to operate as shown in FIG. 1 or in another manner. In some implementations, modem 112, processor 114, memory 116, and power unit 118 of a wireless communication device are housed together in a common housing or other assembly. In some implementations, one or more of the components of a wireless communication device can be housed separately, for example, in a separate housing or other assembly.

Modem 112 can communicate (receive, transmit, or both) wireless signals. For example, modem 112 may be configured to communicate RF signals formatted according to a wireless communication standard (e.g., Wi-Fi or Bluetooth). Modem 112 may be implemented as the example wireless network modem 112 shown in FIG. 1, or may be implemented in another manner, for example, with other types of components or subsystems. In some implementations, modem 112 includes a radio subsystem and a baseband subsystem. In some cases, the baseband subsystem and radio subsystem can be implemented on a common chip or chipset, or they may be implemented in a card or another type of assembled device. The baseband subsystem can be coupled to the radio subsystem, for example, by leads, pins, wires, or other types of connections.

In some cases, a radio subsystem in modem 112 can include one or more antennas and RF circuitry. The RF circuitry can include, for example, circuitry that filters, amplifies, or otherwise conditions analog signals, circuitry that up-converts baseband signals to RF signals, circuitry that down-converts RF signals to baseband signals, etc. Such circuitry may include, for example, filters, amplifiers, mixers, a local oscillator, etc. The radio subsystem can be configured to communicate radio frequency wireless signals on the wireless communication channels. As an example, the radio subsystem may include a radio chip, an RF front end, and one or more antennas. A radio subsystem may include additional or different components. In some implementations, the radio subsystem can be or may include the radio electronics (e.g., RF front end, radio chip, or analogous components) from a conventional modem, for example, from a Wi-Fi modem, pico base station modem, etc. In some implementations, the antenna includes multiple antennas.

In some cases, a baseband subsystem in modem 112 can include, for example, digital electronics configured to process digital baseband data. As an example, the baseband subsystem may include a baseband chip. A baseband subsystem may include additional or different components. In some cases, the baseband subsystem may include a digital signal processor (DSP) device or another type of processor device. In some cases, the baseband system includes digital processing logic to operate the radio subsystem, to communicate wireless network traffic through the radio subsystem, to detect motion based on motion detection signals received through the radio subsystem or to perform other types of processes. For instance, the baseband subsystem may include one or more chips, chipsets, or other types of devices that are configured to encode signals and deliver the encoded signals to the radio subsystem for transmission, or to identify and analyze data encoded in signals from the radio subsystem (e.g., by decoding the signals according to a wireless communication standard, by processing the signals according to a motion detection process, or otherwise).

In some instances, the radio subsystem in modem 112 receives baseband signals from the baseband subsystem, up-converts the baseband signals to RF signals, and wirelessly transmits the RF signals (e.g., through an antenna). In some instances, the radio subsystem in modem 112 wirelessly receives RF signals (e.g., through an antenna), down-converts the RF to baseband signals, and sends the baseband signals to the baseband subsystem. The signals exchanged between the radio subsystem and the baseband subsystem may be digital or analog signals. In some examples, the baseband subsystem includes conversion circuitry (e.g., a digital-to-analog converter, an analog-to-digital converter) and exchanges analog signals with the radio subsystem. In some examples, the radio subsystem includes conversion circuitry (e.g., a digital-to-analog converter, an analog-to-digital converter) and exchanges digital signals with the baseband subsystem.

In some cases, the baseband subsystem of modem 112 can communicate wireless network traffic (e.g., data packets) in the wireless communication network through the radio subsystem on one or more network traffic channels. The baseband subsystem of modem 112 may also transmit or receive (or both) signals (e.g., motion probe signals or motion detection signals) through the radio subsystem on a dedicated wireless communication channel. In some instances, the baseband subsystem generates motion probe signals for transmission, for example, to probe a space for motion. In some instances, the baseband subsystem processes received motion detection signals (signals based on motion probe signals transmitted through the space), for example, to detect motion of an object in a space.

Processor 114 can execute instructions, for example, to generate output data based on data inputs. The instructions can include programs, codes, scripts, or other types of data stored in memory. Additionally, or alternatively, the instructions can be encoded as pre-programmed or re-programmable logic circuits, logic gates, or other types of hardware or firmware components. Processor 114 may be or include a general-purpose microprocessor, as a specialized co-processor or another type of data processing apparatus. In some cases, processor 114 performs high level operation of the wireless communication device 102C. For example, processor 114 may be configured to execute or interpret software, scripts, programs, functions, executables, or other instructions stored in memory 116. In some implementations, processor 114 may be included in modem 112.

Memory 116 can include computer-readable storage media, for example, a volatile memory device, a non-volatile memory device, or both. Memory 116 can include one or more read-only memory devices, random-access memory devices, buffer memory devices, or a combination of these and other types of memory devices. In some instances, one or more components of the memory can be integrated or otherwise associated with another component of wireless communication device 102C. Memory 116 may store instructions that are executable by processor 114. For example, the instructions may include instructions for time-aligning signals using an interference buffer and a motion detection buffer, such as through one or more of the operations of the example processes herein disclosed.

Power unit 118 provides power to the other components of wireless communication device 102C. For example, the other components may operate based on electrical power provided by power unit 118 through a voltage bus or other connection. In some implementations, power unit 118 includes a battery or a battery system, for example, a rechargeable battery. In some implementations, power unit 118 includes an adapter (e.g., an alternating current (AC) adapter) that receives an external power signal (from an external source) and coverts the external power signal to an internal power signal conditioned for a component of wireless communication device 102C. Power unit 118 may include other components or operate in another manner.

In the example shown in FIG. 1, wireless communication devices 102A, 102B transmit wireless signals (e.g., according to a wireless network standard, a motion detection protocol, or otherwise). For instance, wireless communication devices 102A, 102B may broadcast wireless motion probe signals (e.g., reference signals, beacon signals, status signals, etc.), or they may send wireless signals addressed to other devices (e.g., a user equipment, a client device, a server, etc.), and the other devices (not shown) as well as wireless communication device 102C may receive the wireless signals transmitted by wireless communication devices 102A, 102B. In some cases, the wireless signals transmitted by wireless communication devices 102A, 102B are repeated periodically, for example, according to a wireless communication standard or otherwise.

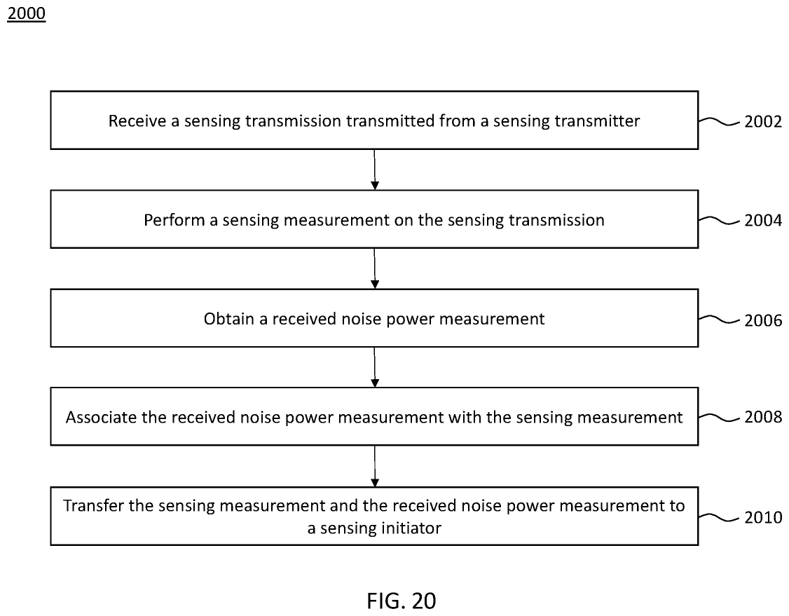

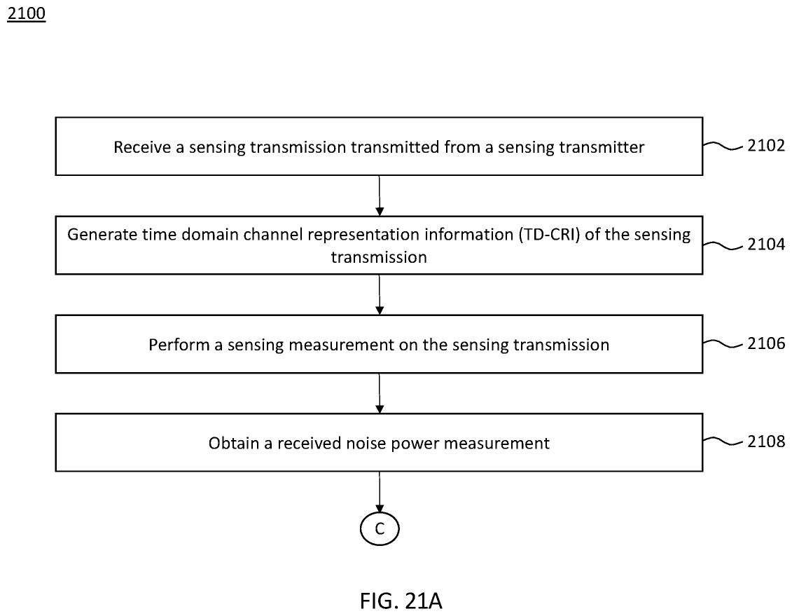

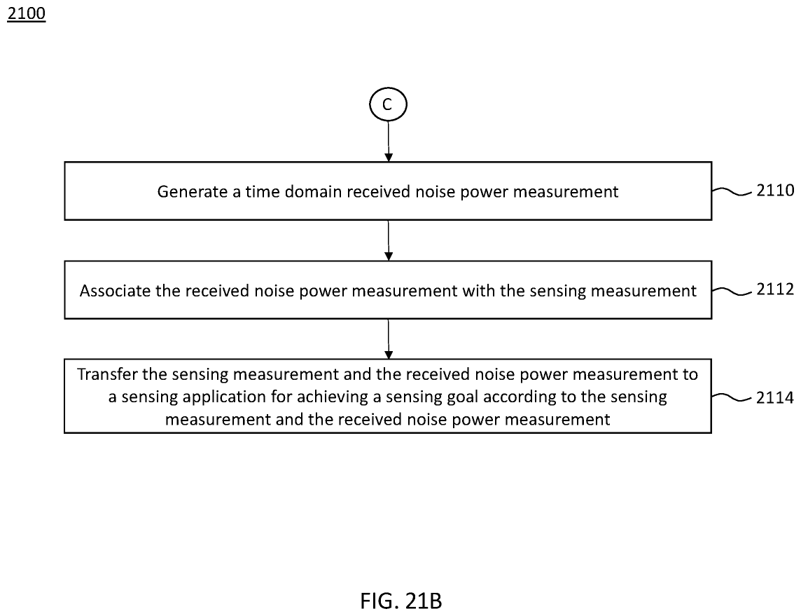

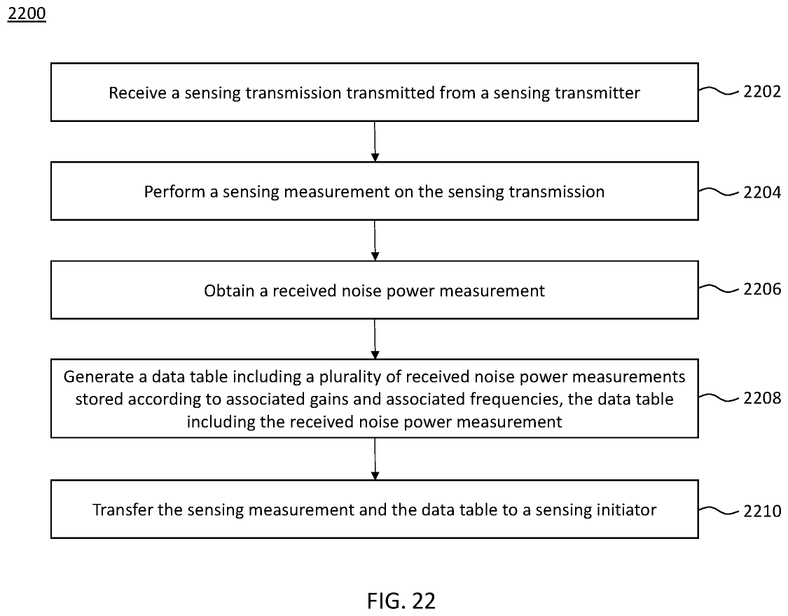

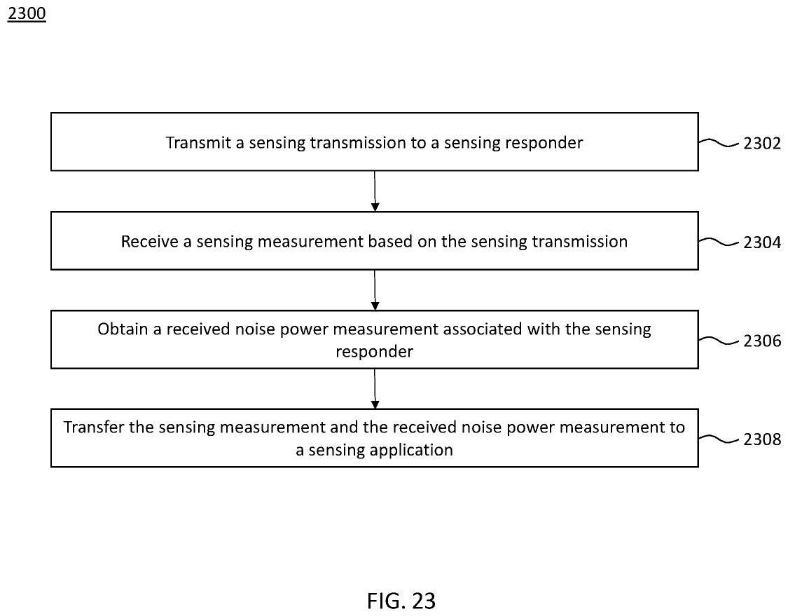

In the example shown, wireless communication device 102C processes the wireless signals from wireless communication devices 102A, 102B to detect motion of an object in a space accessed by the wireless signals, to determine a location of the detected motion, or both. For example, wireless communication device 102C may perform one or more operations of the example processes described below with respect to FIG. 20, FIG. 21A, FIG. 21B, FIG. 22, FIG. 23, or another type of process for detecting motion or determining a location of detected motion. The space accessed by the wireless signals can be an indoor or outdoor space, which may include, for example, one or more fully or partially enclosed areas, an open area without enclosure, etc. The space can be or can include an interior of a room, multiple rooms, a building, or the like. In some cases, the wireless communication system 100 can be modified, for instance, such that wireless communication device 102C can transmit wireless signals and wireless communication devices 102A, 102B can processes the wireless signals from wireless communication device 102C to detect motion or determine a location of detected motion.

The wireless signals used for motion detection can include, for example, a beacon signal (e.g., Bluetooth Beacons, Wi-Fi Beacons, other wireless beacon signals), another standard signal generated for other purposes according to a wireless network standard, or non-standard signals (e.g., random signals, reference signals, etc.) generated for motion detection or other purposes. In examples, motion detection may be carried out by analyzing one or more training fields carried by the wireless signals or by analyzing other data carried by the signal. In some examples data will be added for the express purpose of motion detection or the data used will nominally be for another purpose and reused or repurposed for motion detection. In some examples, the wireless signals propagate through an object (e.g., a wall) before or after interacting with a moving object, which may allow the moving object's movement to be detected without an optical line-of-sight between the moving object and the transmission or receiving hardware. Based on the received signals, wireless communication device 102C may generate motion detection data. In some instances, wireless communication device 102C may communicate the motion detection data to another device or system, such as a security system, which may include a control center for monitoring movement within a space, such as a room, building, outdoor area, etc.

In some implementations, wireless communication devices 102A, 102B can be modified to transmit motion probe signals (which may include, e.g., a reference signal, beacon signal, or another signal used to probe a space for motion) on a separate wireless communication channel (e.g., a frequency channel or coded channel) from wireless network traffic signals. For example, the modulation applied to the payload of a motion probe signal and the type of data or data structure in the payload may be known by wireless communication device 102C, which may reduce the amount of processing that wireless communication device 102C performs for motion sensing. The header may include additional information such as, for example, an indication of whether motion was detected by another device in communication system 100, an indication of the modulation type, an identification of the device transmitting the signal, etc.

In the example shown in FIG. 1, wireless communication system 100 is a wireless mesh network, with wireless communication links between each of wireless communication devices 102. In the example shown, the wireless communication link between wireless communication device 102C and wireless communication device 102A can be used to probe motion detection field 110A, the wireless communication link between wireless communication device 102C and wireless communication device 102B can be used to probe motion detection field 110B, and the wireless communication link between wireless communication device 102A and wireless communication device 102B can be used to probe motion detection field 110C. In some instances, each wireless communication device 102 detects motion in motion detection fields 110 accessed by that device by processing received signals that are based on wireless signals transmitted by wireless communication devices 102 through motion detection fields 110. For example, when person 106 shown in FIG. 1 moves in motion detection field 110A and motion detection field 110C, wireless communication devices 102 may detect the motion based on signals they received that are based on wireless signals transmitted through respective motion detection fields 110. For instance, wireless communication device 102A can detect motion of person 106 in motion detection fields 110A, 110C, wireless communication device 102B can detect motion of person 106 in motion detection field 110C, and wireless communication device 102C can detect motion of person 106 in motion detection field 110A.

In some instances, motion detection fields 110 can include, for example, air, solid materials, liquids, or another medium through which wireless electromagnetic signals may propagate. In the example shown in FIG. 1, motion detection field 110A provides a wireless communication channel between wireless communication device 102A and wireless communication device 102C, motion detection field 110B provides a wireless communication channel between wireless communication device 102B and wireless communication device 102C, and motion detection field 110C provides a wireless communication channel between wireless communication device 102A and wireless communication device 102B. In some aspects of operation, wireless signals transmitted on a wireless communication channel (separate from or shared with the wireless communication channel for network traffic) are used to detect movement of an object in a space. The objects can be any type of static or moveable object and can be living or inanimate. For example, the object can be a human (e.g., person 106 shown in FIG. 1), an animal, an inorganic object, or another device, apparatus, or assembly, an object that defines all or part of the boundary of a space (e.g., a wall, door, window, etc.), or another type of object. In some implementations, motion information from the wireless communication devices may be analyzed to determine a location of the detected motion. For example, as described further below, one of wireless communication devices 102 (or another device communicably coupled to wireless communications devices 102) may determine that the detected motion is nearby a particular wireless communication device.

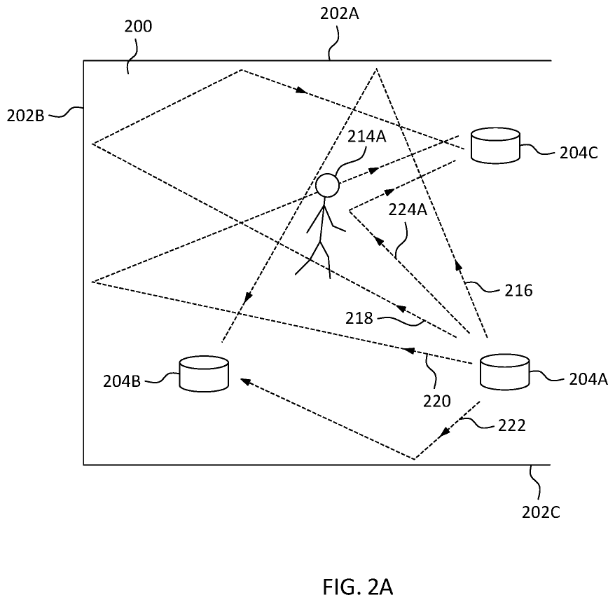

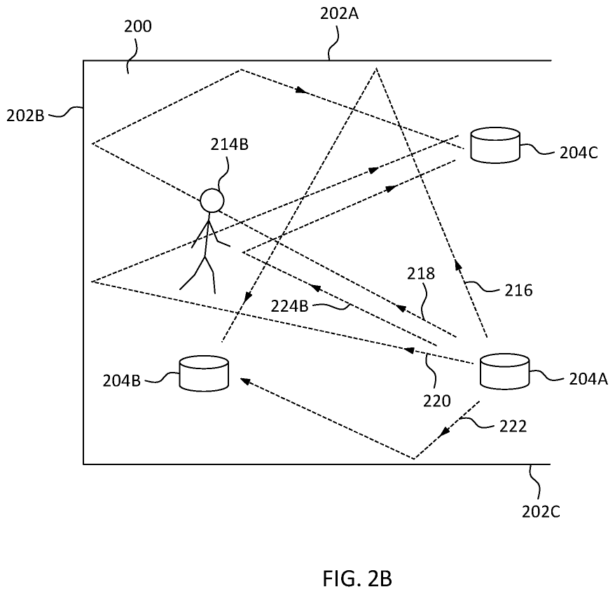

FIG. 2A and FIG. 2B are diagrams showing example wireless signals communicated between wireless communication devices 204A, 204B, 204C. Wireless communication devices 204A, 204B, 204C can be, for example, wireless communication devices 102A, 102B, 102C shown in FIG. 1, or other types of wireless communication devices. Wireless communication devices 204A, 204B, 204C transmit wireless signals through space 200. Space 200 can be completely or partially enclosed or open at one or more boundaries. In an example, space 200 may be a sensing space. Space 200 can be or can include an interior of a room, multiple rooms, a building, an indoor area, outdoor area, or the like. First wall 202A, second wall 202B, and third wall 202C at least partially enclose space 200 in the example shown.

In the example shown in FIG. 2A and FIG. 2B, wireless communication device 204A is operable to transmit wireless signals repeatedly (e.g., periodically, intermittently, at scheduled, unscheduled or random intervals, etc.). Wireless communication devices 204B, 204C are operable to receive signals based on those transmitted by wireless communication device 204A. Wireless communication devices 204B, 204C each have a modem (e.g., modem 112 shown in FIG. 1) that is configured to process received signals to detect motion of an object in space 200.

As shown, an object is in first position 214A in FIG. 2A, and the object has moved to second position 214B in FIG. 2B. In FIG. 2A and FIG. 2B, the moving object in space 200 is represented as a human, but the moving object can be another type of object. For example, the moving object can be an animal, an inorganic object (e.g., a system, device, apparatus, or assembly), an object that defines all or part of the boundary of space 200 (e.g., a wall, door, window, etc.), or another type of object.

As shown in FIG. 2A and FIG. 2B, multiple example paths of the wireless signals transmitted from wireless communication device 204A are illustrated by dashed lines. Along first signal path 216, the wireless signal is transmitted from wireless communication device 204A and reflected off first wall 202A toward the wireless communication device 204B. Along second signal path 218, the wireless signal is transmitted from the wireless communication device 204A and reflected off second wall 202B and first wall 202A toward wireless communication device 204C. Along third signal path 220, the wireless signal is transmitted from the wireless communication device 204A and reflected off second wall 202B toward wireless communication device 204C. Along fourth signal path 222, the wireless signal is transmitted from the wireless communication device 204A and reflected off third wall 202C toward the wireless communication device 204B.

In FIG. 2A, along fifth signal path 224A, the wireless signal is transmitted from wireless communication device 204A and reflected off the object at first position 214A toward wireless communication device 204C. Between FIG. 2A and FIG. 2B, a surface of the object moves from first position 214A to second position 214B in space 200 (e.g., some distance away from first position 214A). In FIG. 2B, along sixth signal path 224B, the wireless signal is transmitted from wireless communication device 204A and reflected off the object at second position 214B toward wireless communication device 204C. Sixth signal path 224B depicted in FIG. 2B is longer than fifth signal path 224A depicted in FIG. 2A due to the movement of the object from first position 214A to second position 214B. In some examples, a signal path can be added, removed, or otherwise modified due to movement of an object in a space.

The example wireless signals shown in FIG. 2A and FIG. 2B may experience attenuation, frequency shifts, phase shifts, or other effects through their respective paths and may have portions that propagate in another direction, for example, through the first, second and third walls 202A, 202B, and 202C. In some examples, the wireless signals are radio frequency (RF) signals. The wireless signals may include other types of signals.

In the example shown in FIG. 2A and FIG. 2B, wireless communication device 204A can repeatedly transmit a wireless signal. In particular, FIG. 2A shows the wireless signal being transmitted from wireless communication device 204A at a first time, and FIG. 2B shows the same wireless signal being transmitted from wireless communication device 204A at a second, later time. The transmitted signal can be transmitted continuously, periodically, at random or intermittent times or the like, or a combination thereof. The transmitted signal can have a number of frequency components in a frequency bandwidth. The transmitted signal can be transmitted from wireless communication device 204A in an omnidirectional manner, in a directional manner or otherwise. In the example shown, the wireless signals traverse multiple respective paths in space 200, and the signal along each path may become attenuated due to path losses, scattering, reflection, or the like and may have a phase or frequency offset.

As shown in FIG. 2A and FIG. 2B, the signals from first to sixth paths 216, 218, 220, 222, 224A, and 224B combine at wireless communication device 204C and wireless communication device 204B to form received signals. Because of the effects of the multiple paths in space 200 on the transmitted signal, space 200 may be represented as a transfer function (e.g., a filter) in which the transmitted signal is input and the received signal is output. When an object moves in space 200, the attenuation or phase offset affected upon a signal in a signal path can change, and hence, the transfer function of space 200 can change. Assuming the same wireless signal is transmitted from wireless communication device 204A, if the transfer function of space 200 changes, the output of that transfer function—the received signal—will also change. A change in the received signal can be used to detect movement of an object.

Mathematically, a transmitted signal ƒ(t) transmitted from the first wireless communication device 204A may be described according to Equation (1):

$$f ( r ) = {Σ}_{n = - ∞}^{∞} {c}_{n} {e}^{j {ω}_{{n}^{t}}} \qquad ( 1 )$$

Where ωₙ represents the frequency of nth frequency component of the transmitted signal, cₙ represents the complex coefficient of the nth frequency component, and t represents time. With the ƒ(t) being transmitted from the first wireless communication device 204A, an output signal rₖ (t) from a path, k, may be described according to Equation (2):

$${r}_{k} ( t ) = {Σ}_{n = - ∞}^{∞} {α}_{n , k} {c}_{n} {e}^{j ( {ω}_{n} t + {ϕ}_{n , k} )} \qquad ( 2 )$$

Where α_{n,k} represents an attenuation factor (or channel response; e.g., due to scattering, reflection, and path losses) for the nth frequency component along k, and φ_{n,k} represents the phase of the signal for nth frequency component along k. Then, the received signal, R, at a wireless communication device can be described as the summation of all output signals rₖ (t) from all paths to the wireless communication device, which is shown in Equation (3):

$$R = {Σ}_{k} {r}_{k} ( t ) \qquad ( 3 )$$

Substituting Equation (2) into Equation (3) renders the following Equation (4):

$$R = {Σ}_{k} {Σ}_{n = - ∞}^{∞} ( {α}_{n , k} {e}^{j {ϕ}_{n , k}} ) {c}_{n} {e}^{j {ω}_{{n}^{t}}} \qquad ( 4 )$$

R at a wireless communication device can then be analyzed. R at a wireless communication device can be transformed to the frequency domain, for example, using a fast Fourier transform (FFT) or another type of algorithm. The transformed signal can represent R as a series of n complex values, one for each of the respective frequency components (at the n frequencies ωₙ). For a frequency component at frequency ωₙ, a complex value, Hₙ, may be represented as follows in Equation (5):

$${H}_{n} = {Σ}_{k} {c}_{n} {α}_{n , k} {e}^{j {ϕ}_{n , k}} \qquad ( 5 )$$

Hₙ for a given ωₙ indicates a relative magnitude and phase offset of the received signal at ωₙ. When an object moves in the space, Hₙ changes due to α_{n,k} of the space changing. Accordingly, a change detected in the channel response can be indicative of movement of an object within the communication channel. In some instances, noise, interference, or other phenomena can influence the channel response detected by the receiver, and the motion detection system can reduce or isolate such influences to improve the accuracy and quality of motion detection capabilities. In some implementations, the overall channel response can be represented as follows in Equation (6):

$${h}_{c h} = {Σ}_{k} {Σ}_{n = - ∞}^{∞} {α}_{n , k} \qquad ( 6 )$$

In some instances, the channel response, h_{ch}, for a space can be determined, for example, based on the mathematical theory of estimation. For instance, a reference signal, R_{ef}, can be modified with candidate h_{ch}, and then a maximum likelihood approach can be used to select the candidate channel which gives best match to the received signal (R_{cvd}). In some cases, an estimated received signal (\hat{R}_{cvd}) is obtained from the convolution of R_{ef} with the candidate h_{ch}, and then the channel coefficients of h_{ch} are varied to minimize the squared error of \hat{R}_{cvd}. This can be mathematically illustrated as follows in Equation (7):

$${R}_{cvd} = {R}_{e f} ⊗ {h}_{c h} = {Σ}_{k = - m}^{m} {R}_{e f} ( n - k ) {h}_{c h} ( k ) \qquad ( 7 )$$

with the optimization criterion as in Equation (8):

$${min}_{{h}_{c h}} \{ {Σ ( {\hat{R}}_{cvd} - {R}_{cvd} )}^{2} \} \qquad ( 8 )$$

The minimizing, or optimizing, process can utilize an adaptive filtering technique, such as least mean squares (LMS), recursive least squares (RLS), batch least squares (BLS), etc. The channel response can be a finite impulse response (FIR) filter, infinite impulse response (IIR) filter, or the like. As shown in the equation above, the received signal can be considered as a convolution of the reference signal and the channel response. The convolution operation means that the channel coefficients possess a degree of correlation with each of the delayed replicas of the reference signal. The convolution operation as shown in the equation above, therefore shows that the received signal appears at different delay points, each delayed replica being weighted by the channel coefficient.

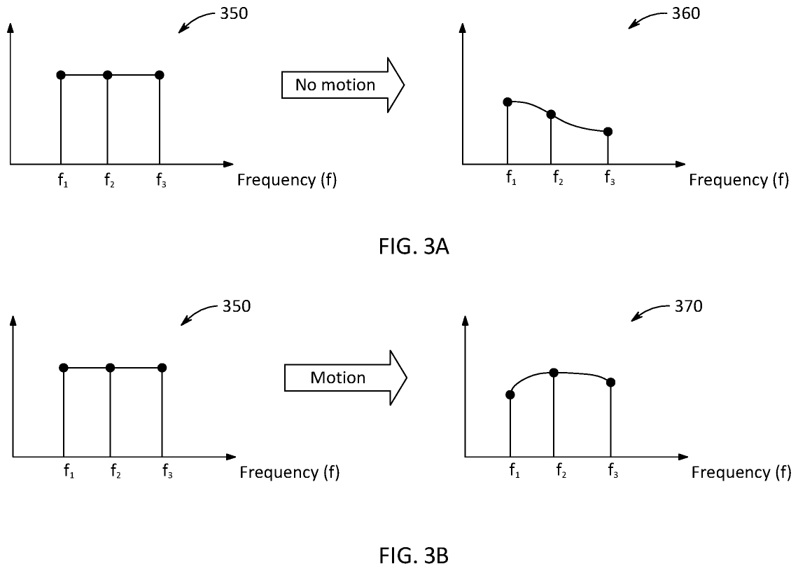

FIG. 3A and FIG. 3B are plots showing examples of channel responses 360, 370 computed from the wireless signals communicated between wireless communication devices 204A, 204B, 204C in FIG. 2A and FIG. 2B. FIG. 3A and FIG. 3B also show frequency domain representation 350 of an initial wireless signal transmitted by wireless communication device 204A. In the examples shown, channel response 360 in FIG. 3A represents the signals received by wireless communication device 204B when there is no motion in space 200, and channel response 370 in FIG. 3B represents the signals received by wireless communication device 204B in FIG. 2B after the object has moved in space 200.

In the example shown in FIG. 3A and FIG. 3B, for illustration purposes, wireless communication device 204A transmits a signal that has a flat frequency profile (the magnitude of each frequency component, ƒ₁, ƒ₂ and ƒ₃ is the same), as shown in frequency domain representation 350. Because of the interaction of the signal with space 200 (and the objects therein), the signals received at wireless communication device 204B that are based on the signal sent from wireless communication device 204A are different from the transmitted signal. In this example, where the transmitted signal has a flat frequency profile, the received signal represents the channel response of space 200. As shown in FIG. 3A and FIG. 3B, channel responses 360, 370 are different from frequency domain representation 350 of the transmitted signal. When motion occurs in space 200, a variation in the channel response will also occur. For example, as shown in FIG. 3B, channel response 370 that is associated with motion of object in space 200 varies from channel response 360 that is associated with no motion in space 200.

Furthermore, as an object moves within space 200, the channel response may vary from channel response 370. In some cases, space 200 can be divided into distinct regions and the channel responses associated with each region may share one or more characteristics (e.g., shape), as described below. Thus, motion of an object within different distinct regions can be distinguished, and the location of detected motion can be determined based on an analysis of channel responses.

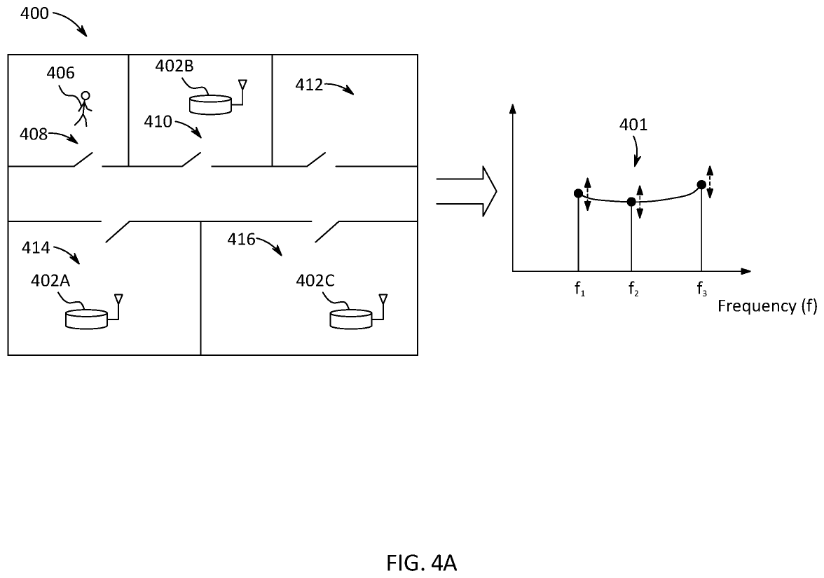

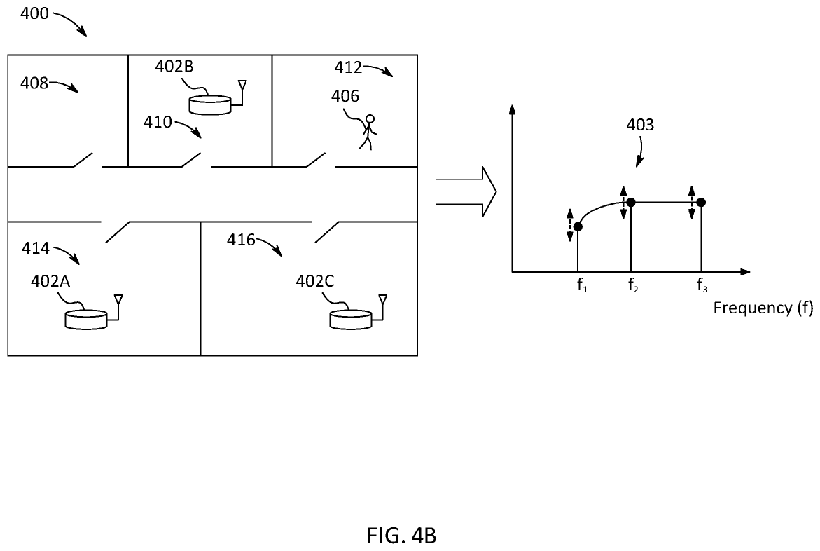

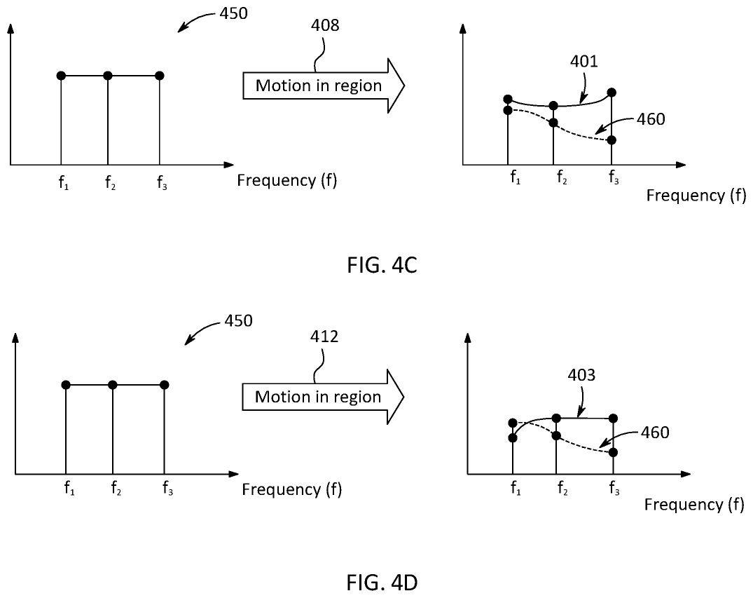

FIG. 4A and FIG. 4B are diagrams showing example channel responses 401, 403 associated with motion of object 406 in distinct regions 408, 412 of space 400. In the examples shown, space 400 is a building, and space 400 is divided into a plurality of distinct regions-first region 408, second region 410, third region 412, fourth region 414, and fifth region 416. Space 400 may include additional or fewer regions, in some instances. As shown in FIG. 4A and FIG. 4B, the regions within space 400 may be defined by walls between rooms. In addition, the regions may be defined by ceilings between floors of a building. For example, space 400 may include additional floors with additional rooms. In addition, in some instances, the plurality of regions of a space can be or include a number of floors in a multistory building, a number of rooms in the building, or a number of rooms on a particular floor of the building. In the example shown in FIG. 4A, an object located in first region 408 is represented as person 406, but the moving object can be another type of object, such as an animal or an inorganic object.

In the example shown, wireless communication device 402A is located in fourth region 414 of space 400, wireless communication device 402B is located in second region 410 of space 400, and wireless communication device 402C is located in fifth region 416 of space 400. Wireless communication devices 402 can operate in the same or similar manner as wireless communication devices 102 of FIG. 1. For instance, wireless communication devices 402 may be configured to transmit and receive wireless signals and detect whether motion has occurred in space 400 based on the received signals. As an example, wireless communication devices 402 may periodically or repeatedly transmit motion probe signals through space 400, and receive signals based on the motion probe signals. Wireless communication devices 402 can analyze the received signals to detect whether an object has moved in space 400, such as, for example, by analyzing channel responses associated with space 400 based on the received signals. In addition, in some implementations, wireless communication devices 402 can analyze the received signals to identify a location of detected motion within space 400. For example, wireless communication devices 402 can analyze characteristics of the channel response to determine whether the channel responses share the same or similar characteristics to channel responses known to be associated with first to fifth regions 408, 410, 412, 414, 416 of space 400.

In the examples shown, one (or more) of wireless communication devices 402 repeatedly transmits a motion probe signal (e.g., a reference signal) through space 400. The motion probe signals may have a flat frequency profile in some instances, wherein the magnitude of ƒ₁, ƒ₂ and ƒ₃ is the same or nearly the same. For example, the motion probe signals may have a frequency response similar to frequency domain representation 350 shown in FIG. 3A and FIG. 3B. The motion probe signals may have a different frequency profile in some instances. Because of the interaction of the reference signal with space 400 (and the objects therein), the signals received at another wireless communication device 402 that are based on the motion probe signal transmitted from the other wireless communication device 402 are different from the transmitted reference signal.

Based on the received signals, wireless communication devices 402 can determine a channel response for space 400. When motion occurs in distinct regions within the space, distinct characteristics may be seen in the channel responses. For example, while the channel responses may differ slightly for motion within the same region of space 400, the channel responses associated with motion in distinct regions may generally share the same shape or other characteristics. For instance, channel response 401 of FIG. 4A represents an example channel response associated with motion of object 406 in first region 408 of space 400, while channel response 403 of FIG. 4B represents an example channel response associated with motion of object 406 in third region 412 of space 400. Channel responses 401, 403 are associated with signals received by the same wireless communication device 402 in space 400.

FIG. 4C and FIG. 4D are plots showing channel responses 401, 403 of FIG. 4A and FIG. 4B overlaid on channel response 460 associated with no motion occurring in space 400. In the example shown, wireless communication device 402 transmits a motion probe signal that has a flat frequency profile as shown in frequency domain representation 450. When motion occurs in space 400, a variation in the channel response will occur relative to channel response 460 associated with no motion, and thus, motion of an object in space 400 can be detected by analyzing variations in the channel responses. In addition, a relative location of the detected motion within space 400 can be identified. For example, the shape of channel responses associated with motion can be compared with reference information (e.g., using a trained artificial intelligence (AI) model) to categorize the motion as having occurred within a distinct region of space 400.

When there is no motion in space 400 (e.g., when object 406 is not present), wireless communication device 402 may compute channel response 460 associated with no motion. Slight variations may occur in the channel response due to a number of factors; however, multiple channel responses 460 associated with different periods of time may share one or more characteristics. In the example shown, channel response 460 associated with no motion has a decreasing frequency profile (the magnitude of each of ƒ₁, ƒ₂ and ƒ₃ is less than the previous). The profile of channel response 460 may differ in some instances (e.g., based on different room layouts or placement of wireless communication devices 402).

When motion occurs in space 400, a variation in the channel response will occur. For instance, in the examples shown in FIG. 4C and FIG. 4D, channel response 401 associated with motion of object 406 in first region 408 differs from channel response 460 associated with no motion and channel response 403 associated with motion of object 406 in third region 412 differs from channel response 460 associated with no motion. Channel response 401 has a concave-parabolic frequency profile (the magnitude of the middle frequency component, ƒ₂, is less than the outer frequency components ƒ₁ and ƒ₃), while channel response 403 has a convex-asymptotic frequency profile (the magnitude of the middle frequency component ƒ₂ is greater than the outer frequency components, ƒ₁ and ƒ₃). The profiles of channel responses 401, 403 may differ in some instances (e.g., based on different room layouts or placement of the wireless communication devices 402).

Analyzing channel responses may be considered similar to analyzing a digital filter. A channel response may be formed through the reflections of objects in a space as well as reflections created by a moving or static human. When a reflector (e.g., a human) moves, it changes the channel response. This may translate to a change in equivalent taps of a digital filter, which can be thought of as having poles and zeros (poles amplify the frequency components of a channel response and appear as peaks or high points in the response, while zeros attenuate the frequency components of a channel response and appear as troughs, low points, or nulls in the response). A changing digital filter can be characterized by the locations of its peaks and troughs, and a channel response may be characterized similarly by its peaks and troughs. For example, in some implementations, analyzing nulls and peaks in the frequency components of a channel response (e.g., by marking their location on the frequency axis and their magnitude), motion can be detected.

In some implementations, a time series aggregation can be used to detect motion. A time series aggregation may be performed by observing the features of a channel response over a moving window and aggregating the windowed result by using statistical measures (e.g., mean, variance, principal components, etc.). During instances of motion, the characteristic digital-filter features would be displaced in location and flip-flop between some values due to the continuous change in the scattering scene. That is, an equivalent digital filter exhibits a range of values for its peaks and nulls (due to the motion). By looking this range of values, unique profiles (in examples profiles may also be referred to as signatures) may be identified for distinct regions within a space.

In some implementations, an AI model may be used to process data. AI models may be of a variety of types, for example linear regression models, logistic regression models, linear discriminant analysis models, decision tree models, naïve bayes models, K-nearest neighbors models, learning vector quantization models, support vector machines, bagging and random forest models, and deep neural networks. In general, all AI models aim to learn a function which provides the most precise correlation between input values and output values and are trained using historic sets of inputs and outputs that are known to be correlated. In examples, artificial intelligence may also be referred to as machine learning.

In some implementations, the profiles of the channel responses associated with motion in distinct regions of space 400 can be learned. For example, machine learning may be used to categorize channel response characteristics with motion of an object within distinct regions of a space. In some cases, a user associated with wireless communication devices 402 (e.g., an owner or other occupier of space 400) can assist with the learning process. For instance, referring to the examples shown in FIG. 4A and FIG. 4B, the user can move in each of first to fifth regions 408, 410, 412, 414, 416 during a learning phase and may indicate (e.g., through a user interface on a mobile computing device) that he/she is moving in one of the particular regions in space 400. For example, while the user is moving through first region 408 (e.g., as shown in FIG. 4A) the user may indicate on a mobile computing device that he/she is in first region 408 (and may name the region as “bedroom”, “living room”, “kitchen”, or another type of room of a building, as appropriate). Channel responses may be obtained as the user moves through the region, and the channel responses may be “tagged” with the user's indicated location (region). The user may repeat the same process for the other regions of space 400. The term “tagged” as used herein may refer to marking and identifying channel responses with the user's indicated location or any other information.

The tagged channel responses can then be processed (e.g., by machine learning software) to identify unique characteristics of the channel responses associated with motion in the distinct regions. Once identified, the identified unique characteristics may be used to determine a location of detected motion for newly computed channel responses. For example, an AI model may be trained using the tagged channel responses, and once trained, newly computed channel responses can be input to the AI model, and the AI model can output a location of the detected motion. For example, in some cases, mean, range, and absolute values are input to an AI model. In some instances, magnitude and phase of the complex channel response itself may be input as well. These values allow the AI model to design arbitrary front-end filters to pick up the features that are most relevant to making accurate predictions with respect to motion in distinct regions of a space. In some implementations, the AI model is trained by performing a stochastic gradient descent. For instance, channel response variations that are most active during a certain zone may be monitored during the training, and the specific channel variations may be weighted heavily (by training and adapting the weights in the first layer to correlate with those shapes, trends, etc.). The weighted channel variations may be used to create a metric that activates when a user is present in a certain region.

For extracted features like channel response nulls and peaks, a time-series (of the nulls/peaks) may be created using an aggregation within a moving window, taking a snapshot of few features in the past and present, and using that aggregated value as input to the network. Thus, the network, while adapting its weights, will be trying to aggregate values in a certain region to cluster them, which can be done by creating a logistic classifier based decision surfaces. The decision surfaces divide different clusters and subsequent layers can form categories based on a single cluster or a combination of clusters.

In some implementations, an AI model includes two or more layers of inference. The first layer acts as a logistic classifier which can divide different concentrations of values into separate clusters, while the second layer combines some of these clusters together to create a category for a distinct region. Additionally, subsequent layers can help in extending the distinct regions over more than two categories of clusters. For example, a fully-connected AI model may include an input layer corresponding to the number of features tracked, a middle layer corresponding to the number of effective clusters (through iterating between choices), and a final layer corresponding to different regions. Where complete channel response information is input to the AI model, the first layer may act as a shape filter that can correlate certain shapes. Thus, the first layer may lock to a certain shape, the second layer may generate a measure of variation happening in those shapes, and third and subsequent layers may create a combination of those variations and map them to different regions within the space. The output of different layers may then be combined through a fusing layer.

### B. Wi-Fi Sensing System Example Methods and Apparatus

Section B describes systems and methods that are useful for a wireless sensing system configured to send sensing transmissions and make sensing measurements.

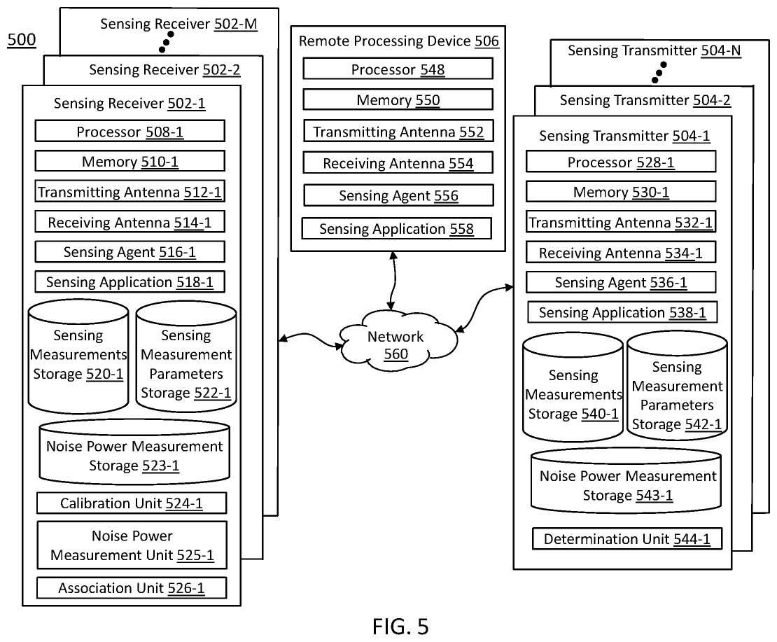

FIG. 5 depicts an implementation of some of an architecture of an implementation of system 500 for Wi-Fi sensing, according to some embodiments.

System 500 may include a plurality of networking devices. In an example, system 500 may include plurality of sensing receivers 502-(1-M) (which may also be sensing responders), plurality of sensing transmitters 504-(1-N), remote processing device 506, and network 560 enabling communication between the system components for information exchange. In an example implementation, plurality of sensing transmitters 504-(1-N) may include at least first sensing transmitter 504-1 and second sensing transmitter 504-2. In an example implementation, plurality of sensing receivers 502-(1-M) may include at least first sensing receiver 502-1 (which may also be a sensing responder) and second sensing receiver 502-2. System 500 may be an example or instance of wireless communication system 100 and network 560 may be an example or instance of wireless network or cellular network, details of which are provided with reference to FIG. 1 and its accompanying description.

According to an embodiment, plurality of sensing receivers 502-(1-M) may be configured to receive one or more sensing transmissions (for example, from one or more of plurality of sensing transmitters 504-(1-N)) and perform one or more measurements (for example, channel representation information (CRI) measurements such as channel state information (CSI) or time domain channel representation information (TD-CRI)) useful for Wi-Fi sensing. In examples, these measurements may be known as sensing measurements. Sensing measurements may be processed to achieve a sensing goal of system 500. In an embodiment, one or more of plurality of sensing receivers 502-(1-M) may be an AP. In some embodiments, one or more of plurality of sensing receivers 502-(1-M) may take a role of sensing initiator and/or sensing responder.

According to an implementation, one or more of plurality of sensing receivers 502-(1-M) may be implemented by a device, such as wireless communication device 102 shown in FIG. 1. In some implementations, one or more of plurality of sensing receivers 502-(1-M) may be implemented by a device, such as wireless communication device 204 shown in FIG. 2A and FIG. 2B. Further, one or more of plurality of sensing receivers 502-(1-M) may be implemented by a device, such as wireless communication device 402 shown in FIG. 4A and FIG. 4B. In an implementation, one or more of plurality of sensing receivers 502-(1-M) may coordinate and control communication among plurality of sensing transmitters 504-(1-N). According to an implementation, one or more of plurality of sensing receivers 502-(1-M) may be enabled to control a sensing measurement session comprising one or more sensing measurement instances to ensure that required sensing transmissions are made at a required times and to ensure an accurate determination of one or more sensing measurements. In some embodiments, one or more of plurality of sensing receivers 502-(1-M) may process sensing measurements to achieve the sensing goal of system 500. In some embodiments, one or more of plurality of sensing receivers 502-(1-M) may be configured to transmit sensing measurements to one or more of plurality of sensing transmitters 504-(1-N), and one or more of plurality of sensing transmitters 504-(1-N) may be configured to process the sensing measurements to achieve a sensing result of system 500.

In an embodiment, one or more of plurality of sensing receivers 502-(1-M) may be a STA. In an embodiment, one or more of plurality of sensing receivers 502-(1-M) may be an AP. In some embodiments, one or more of plurality of sensing receivers 502-(1-M) may be configured to transmit sensing measurements to remote processing device 506, and remote processing device 506 may be configured to process sensing measurements to achieve the sensing goal of system 500. In some embodiments, first sensing receiver 502-1 may be any computing device, such as a desktop computer, a laptop, a tablet computer, a mobile device, a personal digital assistant (PDA), or any other computing device.

Referring again to FIG. 5, in some embodiments, one or more of plurality of sensing transmitters 504-(1-N) may be configured to send one or more sensing transmissions to one or more of plurality of sensing receivers 502-(1-M) based on which one or more sensing measurements may be performed for Wi-Fi sensing. In an embodiment, one or more of plurality of sensing transmitters 504-(1-N) may be a STA. In an embodiment, one or more of plurality of sensing transmitters 504-(1-N) may be an AP. In some embodiments, one or more of plurality of sensing transmitters 504-(1-N) may take a role of sensing initiator and/or sensing responder.

According to an implementation, one or more of plurality of sensing transmitters 504-(1-N) may be implemented by a device, such as wireless communication device 102 shown in FIG. 1. In some implementations, one or more of plurality of sensing transmitters 504-(1-M) may be implemented by a device, such as wireless communication device 204 shown in FIG. 2A and FIG. 2B. Further, one or more of plurality of sensing transmitters 504-(1-M) may be implemented by a device, such as wireless communication device 402 shown in FIG. 4A and FIG. 4B. In some embodiments, first sensing transmitter 504-1 may be any computing device, such as a desktop computer, a laptop, a tablet computer, a mobile device, a PDA, or any other computing device. In some implementations, communication between one or more of plurality of sensing receivers 502-(1-M) and one or more of plurality of sensing transmitters 504-(1-N) may happen via station management entity (SME) and MAC layer management entity (MLME) protocols.

In some embodiments, remote processing device 506 may be configured to receive sensing measurements from one or more of plurality of sensing receivers 502-(1-M) and process the sensing measurements. In an example, remote processing device 506 may process and analyze sensing measurements to identify one or more features of interest. According to some implementations, remote processing device 506 may include/execute a sensing algorithm. In an embodiment, remote processing device 506 may be a STA. In some embodiments, remote processing device 506 may be an AP. According to an implementation, remote processing device 506 may be implemented by a device, such as wireless communication device 102 shown in FIG. 1. In some implementations, remote processing device 506 may be implemented by a device, such as wireless communication device 204 shown in FIG. 2A and FIG. 2B. Further, remote processing device 506 may be implemented by a device, such as wireless communication device 402 shown in FIG. 4A and FIG. 4B. In some embodiments, remote processing device 506 may be any computing device, such as a desktop computer, a laptop, a tablet computer, a mobile device, a personal digital assistant (PDA) or any other computing device. In embodiments, remote processing device 506 may take a role of sensing initiator where a sensing algorithm determines a Wi-Fi sensing session and the sensing measurements required to fulfill the measurement campaign.

In an example, remote processing device 506 may communicate sensing measurement parameters and/or transmission parameters required to initiate a Wi-Fi sensing session to one or more of plurality of sensing receivers 502-(1-M) and/or to one or more of plurality of sensing transmitters 504-(1-N) to coordinate and control sensing transmissions for performing sensing measurements.

Referring to FIG. 5 in more detail, sensing receiver 502-1 (which is an example of one or more of plurality of sensing receivers 502-(1-M)) may include processor 508-1 and memory 510-1. For example, processor 508-1 and memory 510-1 of sensing receiver 502-1 may be processor 114 and memory 116, respectively, as shown in FIG. 1. In an embodiment, sensing receiver 502-1 may further include transmitting antenna(s) 512-1, receiving antenna(s) 514-1, and sensing agent 516-1. In some embodiments, an antenna may be used to both transmit and receive signals in a half-duplex format. When the antenna is transmitting, it may be referred to as transmitting antenna 512-1, and when the antenna is receiving, it may be referred to as receiving antenna 514-1. It is understood by a person of normal skill in the art that the same antenna may be transmitting antenna 512-1 in some instances and receiving antenna 514-1 in other instances. In the case of an antenna array, one or more antenna elements may be used to transmit or receive a signal, for example, in a beamforming environment. In some examples, a group of antenna elements used to transmit a composite signal may be referred to as transmitting antenna 512-1, and a group of antenna elements used to receive a composite signal may be referred to as receiving antenna 514-1. In some examples, each antenna is equipped with its own transmission and receive paths, which may be alternately switched to connect to the antenna depending on whether the antenna is operating as transmitting antenna 512-1 or receiving antenna 514-1.

In an implementation, sensing agent 516-1 may be responsible for causing sensing receiver 502-1 to receive sensing transmissions and associated sensing measurement parameters and/or transmission parameters, to calculate sensing measurements. In examples, sensing agent 516-1 may be responsible for processing sensing measurements to fulfill a sensing goal. In some implementations, receiving sensing transmissions and optionally associated sensing measurement parameters and/or transmission parameters, and calculating sensing measurements may be carried out by sensing agent 516-1 running in the medium access control (MAC) layer of sensing receiver 502-1 and processing sensing measurements to fulfill a sensing goal may be carried out by an algorithm running in the application layer of sensing receiver 502-1, for example sensing application 518-1. In examples, a sensing application 518-1 running in the application layer of sensing receiver 502-1 may be known as a Wi-Fi sensing agent, a sensing application, or sensing algorithm. In examples, sensing application 518-1 may include and/or execute sensing agent 516-1. According to some implementations, sensing agent 516-1 may include and/or execute sensing application 518-1. In some implementations, sensing agent 516-1 running in the MAC layer of sensing receiver 502-1 and sensing application 518-1 running in the application layer of sensing receiver 502-1 may run separately on processor 508-1. In an implementation, sensing agent 516-1 may pass one or more of sensing measurement parameters, transmission parameters, or physical layer parameters (e.g., such as channel representation information, examples of which are CSI and TD-CRI) between the MAC layer of sensing receiver 502-1 and the application layer of sensing receiver 502-1. In an example, sensing agent 516-1 in the MAC layer or sensing application 518-1 in the application layer may operate on physical layer parameters, for example, to detect one or more features of interest. In examples, sensing application 518-1 may form services or features, which may be presented to an end-user. According to an implementation, communication between the MAC layer of sensing receiver 502-1 and other layers or components of sensing receiver 502-1 (including the application layer) may take place based on communication interfaces, such as an MLME interface and a data interface. In examples, sensing agent 516-1 may be configured to determine a number and timing of sensing transmissions and sensing measurements for the purpose of Wi-Fi sensing. In some implementations, sensing agent 516-1 may be configured to transmit sensing measurements to plurality of sensing transmitters 504-(1-N) and/or remote processing device 506 for further processing. In an implementation, sensing agent 516-1 may be configured to cause at least one transmitting antenna of transmitting antenna(s) 512-1 to transmit messages to one or more of plurality of sensing transmitters 504-(1-N) or to remote processing device 506. Further, sensing agent 516-1 may be configured to receive, via at least one receiving antenna of receiving antennas(s) 514-1, messages from one or more of plurality of sensing transmitters 504-(1-N) or from remote processing device 506. In an example, sensing agent 516-1 may be configured to make sensing measurements based on sensing transmissions received from one or more of plurality of sensing transmitters 504-(1-N).

In some embodiments, sensing receiver 502-1 may include sensing measurements storage 520-1. In an implementation, sensing measurements storage 520-1 may store sensing measurements computed by sensing receiver 502-1 based on received sensing transmissions. In an example, sensing measurements stored in sensing measurements storage 520-1 may be periodically or dynamically updated as required. In some embodiments, sensing receiver 502-1 may include sensing measurement parameters storage 522-1. In an implementation, sensing measurement parameters storage 522-1 may store sensing measurement parameters and/or transmission parameters applicable to one or more sensing measurement setups. In an implementation, sensing measurement parameters storage 522-1 may store sensing measurement parameters and/or transmission parameters applicable to one or more sensing measurement sessions. In an implementation, sensing measurement parameters storage 522-1 may store sensing measurement parameters and/or transmission parameters applicable to one or more sensing measurement instances. In an example, sensing measurement parameters and/or transmission parameters stored in sensing measurement parameters storage 522-1 may be periodically or dynamically updated as required. In an implementation, sensing measurements storage 520-1 and sensing measurement parameters storage 522-1 may include any type or form of storage, such as a database or a file system or coupled to memory 510-1.

In some implementations, sensing receiver 502-1 may include noise power measurement storage 523-1. In an implementation, noise power measurement storage 523-1 may store a plurality of received noise power measurements of sensing receiver 502-1 according to associated gains and associated frequencies. In an implementation, the plurality of received noise power measurements may be stored in form of a data table. In examples, the data table may include the plurality of received noise power measurements stored according to associated gains and associated frequencies. In an example, the plurality of received noise power measurements stored in noise power measurement storage 523-1 may be periodically or dynamically updated as required. In an implementation, noise power measurement storage 523-1 may include any type or form of storage, such as a database or a file system or coupled to memory 510-1.

According to some implementations, sensing receiver 502-1 may include calibration unit 524-1, noise power measurement unit 525-1, and association unit 526-1. In an implementation, calibration unit 524-1, noise power measurement unit 525-1, and association unit 526-1 may be coupled to processor 508-1 and memory 510-1. In some embodiments, calibration unit 524-1, noise power measurement unit 525-1, and association unit 526-1 amongst other units, may include routines, programs, objects, components, data structures, etc., which may perform particular tasks or implement particular abstract data types. Calibration unit 524-1, noise power measurement unit 525-1, and association unit 526-1 may also be implemented as, signal processor(s), state machine(s), logic circuitries, and/or any other device or component that manipulates signals based on operational instructions.

In some embodiments, calibration unit 524-1, noise power measurement unit 525-1, and association unit 526-1 may be implemented in hardware, instructions executed by a processing unit, or by a combination thereof. The processing unit may comprise a computer, a processor, a state machine, a logic array or any other suitable devices capable of processing instructions. The processing unit may be a general-purpose processor that executes instructions to cause the general-purpose processor to perform the required tasks or, the processing unit may be dedicated to performing the required functions. In some embodiments, calibration unit 524-1, noise power measurement unit 525-1, and association unit 526-1 may be machine-readable instructions that, when executed by a processor/processing unit, perform any of desired functionalities. The machine-readable instructions may be stored on an electronic memory device, hard disk, optical disk or other machine-readable storage medium or non-transitory medium. In an implementation, the machine-readable instructions may also be downloaded to the storage medium via a network connection. In an example, machine-readable instructions may be stored in memory 510-1.

Referring again to FIG. 5, sensing transmitter 504-1 (which is an example of one or more of plurality of sensing transmitters 504-(1-N)) may include processor 528-1 and memory 530-1. For example, processor 528-1 and memory 530-1 of sensing transmitter 504-1 may be processor 114 and memory 116, respectively, as shown in FIG. 1. In an embodiment, sensing transmitter 504-1 may further include transmitting antenna(s) 532-1, receiving antenna(s) 534-1, and sensing agent 536-1.

Sensing agent 536-1 may be configured to cause at least one transmitting antenna of transmitting antenna(s) 532-1 and at least one receiving antenna of receiving antennas(s) 534-1 to exchange messages with one or more of plurality of sensing receivers 502-(1-M)) or with remote processing device 506. In some embodiments, an antenna may be used to both transmit and receive in a half-duplex format. When the antenna is transmitting, it may be referred to as transmitting antenna 532-1, and when the antenna is receiving, it may be referred to as receiving antenna 534-1. It is understood by a person of normal skill in the art that the same antenna may be transmitting antenna 532-1 in some instances and receiving antenna 534-1 in other instances. In the case of an antenna array, one or more antenna elements may be used to transmit or receive a signal, for example, in a beamforming environment. In some examples, a group of antenna elements used to transmit a composite signal may be referred to as transmitting antenna 532-1, and a group of antenna elements used to receive a composite signal may be referred to as receiving antenna 534-1. In some examples, each antenna is equipped with its own transmission and receive paths, which may be alternately switched to connect to the antenna depending on whether the antenna is operating as transmitting antenna 532-1 or receiving antenna 534-1.

In an implementation, sensing agent 536-1 may be responsible for causing sensing transmitter 504-1 to send sensing transmissions and, in examples, receive associated sensing measurements from one or more of plurality of sensing receivers 502-(1-M). In examples, sensing agent 536-1 may be responsible for processing sensing measurements to fulfill a sensing goal. In some implementations, sensing agent 536-1 may run in the medium access control (MAC) layer of sensing transmitter 504-1, and processing sensing measurements to fulfill a sensing goal may be carried out by sensing application 538-1, which in examples may run in the application layer of sensing transmitter 504-1. In examples, sensing application 538-1 running in the application layer of sensing transmitter 504-1 may be known as a Wi-Fi sensing agent, a sensing application, or a sensing algorithm. In examples, sensing application 538-1 may include and/or execute sensing agent 536-1. According to some implementations, sensing agent 536-1 may include and/or execute sensing application 538-1. In some implementations, sensing agent 536-1 may run in the MAC layer of sensing transmitter 504-1 and sensing application 538-1 may run in the application layer of sensing transmitter 504-1. In some implementations, sensing agent 536-1 of sensing transmitter 504-1 and sensing application 538-1 may run separately on processor 528-1. In an implementation, sensing agent 536-1 may pass sensing measurement parameters, transmission parameters, or physical layer parameters between the MAC layer of sensing transmitter 504-1 and the application layer of sensing transmitter 504-1. In an example, sensing agent 536-1 in the MAC layer or sensing application 538-1 in the application layer may control physical layer parameters, for example physical layer parameters used to generate one or more sensing transmissions. In examples, sensing application 538-1 may form services or features, which may be presented to an end-user. According to an implementation, communication between the MAC layer of sensing transmitter 504-1 and other layers or components of sensing transmitter 504-1 (including the application layer) may take place based on communication interfaces, such as an MLME interface and a data interface. In examples, sensing agent 536-1 may be configured to determine a number and timing of sensing transmissions for the purpose of Wi-Fi sensing. In some implementations, sensing agent 536-1 may be configured to cause sensing transmitter 504-1 to transmit sensing transmissions to one or more of plurality of sensing receivers 502-(1-M). In an implementation, sensing agent 536-1 may be configured to cause at least one transmitting antenna of transmitting antenna(s) 532-1 to transmit messages to one or more of plurality of sensing receivers 502-(1-M) or to remote processing device 506. Further, sensing agent 536-1 may be configured to receive, via at least one receiving antenna of receiving antennas(s) 534-1, messages from one or more of plurality of sensing receivers 502-(1-M) or from remote processing device 506.

In some embodiments, sensing transmitter 504-1 may include sensing measurements storage 540-1. In an implementation, sensing measurements storage 540-1 may store sensing measurements computed by one or more of plurality of sensing receivers 502-(1-M) based on sensing transmissions sent by sensing transmitter 504-1 and sent by one or more of plurality of sensing receivers 502-(1-M) to sensing transmitter 504-1. In an example, sensing measurements stored in sensing measurements storage 540-1 may be periodically or dynamically updated as required. In an implementation, sensing measurements storage 540-1 may include any type or form of storage, such as a database or a file system or coupled to memory 530-1.

In some embodiments, sensing transmitter 504-1 may include sensing measurement parameters storage 542-1. In an implementation, sensing measurement parameters storage 542-1 may store sensing measurement parameters and/or transmission parameters applicable to one or more sensing measurement sessions. In an implementation, sensing measurement parameters storage 542-1 may store sensing measurement parameters and/or transmission parameters applicable to one or more sensing measurement setups. In an implementation, sensing measurement parameters storage 542-1 may store sensing measurement parameters and/or transmission parameters applicable to one or more sensing measurement instances. In an example, sensing measurement parameters and/or transmission parameters stored in sensing measurement parameters storage 542-1 may be periodically or dynamically updated as required. In an implementation, sensing measurements storage 540-1 and sensing measurement parameters storage 542-1 may include any type or form of storage, such as a database or a file system or coupled to memory 530-1.

In some implementations, sensing transmitter 504-1 may include noise power measurement storage 543-1. In an implementation, noise power measurement storage 543-1 may store a plurality of received noise power measurements of sensing receiver 502-1 according to associated gains and associated frequencies. In an example, noise power measurement storage 543-1 may store the plurality of received noise power measurements of sensing receiver 502-1 in form of a data table. In examples, the data table including the plurality of received noise power measurements stored according to the associated gains and the associated frequencies may be received from sensing receiver 502-1. In an example, the plurality of received noise power measurements of sensing receiver 502-1 stored in noise power measurement storage 543-1 may be periodically or dynamically updated as required. In an implementation, noise power measurement storage 543-1 may include any type or form of storage, such as a database or a file system or coupled to memory 530-1.

According to some implementations, sensing transmitter 504-1 may include determination unit 544-1. In an implementation, determination unit 544-1 may be coupled to processor 528-1 and memory 530-1. In some embodiments, determination unit 544-1 amongst other units, may include routines, programs, objects, components, data structures, etc., which may perform particular tasks or implement particular abstract data types. Determination unit 544-1 may also be implemented as, signal processor(s), state machine(s), logic circuitries, and/or any other device or component that manipulates signals based on operational instructions.

In some embodiments, determination unit 544-1 may be implemented in hardware, instructions executed by a processing unit, or by a combination thereof. The processing unit may comprise a computer, a processor, a state machine, a logic array or any other suitable devices capable of processing instructions. The processing unit may be a general-purpose processor that executes instructions to cause the general-purpose processor to perform the required tasks or, the processing unit may be dedicated to performing the required functions. In some embodiments, determination unit 544-1 may be machine-readable instructions that, when executed by a processor/processing unit, perform any of desired functionalities. The machine-readable instructions may be stored on an electronic memory device, hard disk, optical disk or other machine-readable storage medium or non-transitory medium. In an implementation, the machine-readable instructions may also be downloaded to the storage medium via a network connection. In an example, machine-readable instructions may be stored in memory 530-1.

Referring to FIG. 5 in more detail, remote processing device 506 may include processor 548 and memory 550. For example, processor 548 and memory 550 of remote processing device 506 may be processor 114 and memory 116, respectively, as shown in FIG. 1. In an embodiment, remote processing device 506 may further include transmitting antenna(s) 552, receiving antenna(s) 554, sensing agent 556, and sensing application 558. In some embodiments, an antenna may be used to both transmit and receive signals in a half-duplex format. When the antenna is transmitting, it may be referred to as transmitting antenna 552, and when the antenna is receiving, it may be referred to as receiving antenna 554. It is understood by a person of normal skill in the art that the same antenna may be transmitting antenna 552 in some instances and receiving antenna 554 in other instances. In the case of an antenna array, one or more antenna elements may be used to transmit or receive a signal, for example, in a beamforming environment. In some examples, a group of antenna elements used to transmit a composite signal may be referred to as transmitting antenna 552, and a group of antenna elements used to receive a composite signal may be referred to as receiving antenna 554. In some examples, each antenna is equipped with its own transmission and receive paths, which may be alternately switched to connect to the antenna depending on whether the antenna is operating as transmitting antenna 552 or receiving antenna 554.

In an implementation, sensing agent 556 may be responsible for determining sensing measurement parameters and/or transmission parameters for one or more sensing measurement setups. In examples, sensing agent 556 may receive sensing measurement parameters and/or transmission parameters for one or more sensing measurement setups from sensing application 558. In an example, sensing agent 556 may receive sensing measurements from one or more of plurality of sensing receivers 502-(1-M) and may process the sensing measurements to fulfill a sensing goal. In an example, sensing agent 556 may receive channel representation information (such as CSI or TD-CRI) from one or more of plurality of sensing receivers 502-(1-M) and may process the channel representation information to fulfill a sensing goal. In implementations, sensing agent 556 may receive sensing measurements or channel representation information and may provide the received sensing measurements or channel representation information to sensing application 558, and sensing application 558 may receive the sensing measurements or channel representation information from sensing agent 556 and may process the information to fulfill a sensing goal.

In some implementations, receiving sensing measurements may be carried out by an algorithm running in the medium access control (MAC) layer of remote processing device 506 and processing sensing measurements to fulfill a sensing goal may be carried out by an algorithm running in the application layer of remote processing device 506. In examples, the algorithm running in the application layer of remote processing device 506 may be known as a Wi-Fi sensing agent, a sensing application, or sensing algorithm. In some implementations, the algorithm running in the MAC layer of remote processing device 506 and the algorithm running in the application layer of remote processing device 506 may run separately on processor 548. In an implementation, sensing agent 556 may pass physical layer parameters (e.g., such as channel representation information, examples of which are CSI and TD-CRI) from the MAC layer of remote processing device 506 to the application layer of remote processing device 506 and may use the physical layer parameters to detect one or more features of interest. In an example, the application layer may operate on the physical layer parameters and form services or features, which may be presented to an end-user. According to an implementation, communication between the MAC layer of remote processing device 506 and other layers or components of remote processing device 506 may take place based on communication interfaces, such as an MLME interface and a data interface. According to some implementations, sensing agent 556 may include/execute a sensing application 558. In an implementation, sensing agent 556 may process and analyze sensing measurements using sensing application 558 and identify one or more features of interest. Further, sensing agent 556 may be configured to determine a number and timing of sensing transmissions and sensing measurements for the purpose of Wi-Fi sensing. In some implementations, sensing agent 556 may be configured to cause one or more of plurality of sensing transmitters 504-(1-N) to transmit sensing measurements to one or more of plurality of sensing receivers 502-(1-M).

For ease of explanation and understanding, descriptions provided above may be with reference to sensing receiver 502-1 or sensing transmitter 504-1, however, the description is equally applicable to one or more of plurality of sensing receivers 502-(1-M) and/or one or more of plurality of sensing transmitters 504-(1-N).

According to one or more implementations, communications in network 560 may be governed by one or more of the 802.11 family of standards developed by IEEE. Some example IEEE standards may include IEEE 802.11-2020, IEEE 802.11ax-2021, IEEE 802.11me, IEEE 802.11az and IEEE 802.11be. IEEE 802.11-2020 and IEEE 802.11ax-2021 are fully-ratified standards whilst IEEE 802.11 me reflects an ongoing maintenance update to the IEEE 802.11-2020 standard and IEEE 802.11be defines the next generation of standard. IEEE 802.11az is an extension of the IEEE 802.11-2020 and IEEE 802.11ax-2021 standards which adds new functionality. In some implementations, communications may be governed by other standards (other or additional IEEE standards or other types of standards). In some embodiments, parts of network 560 which are not required by system 500 to be governed by one or more of the 802.11 family of standards may be implemented by an instance of any type of network, including wireless network or cellular network. Further, IEEE 802.11ax included OFDMA, which allows sensing receiver 502 to simultaneously transmit data to all participating devices, such as plurality of sensing transmitters 504-(1-N), and vice versa using a single transmission opportunity (TXOP). The efficiency of OFDMA depends on how sensing receiver 502 schedules channel resources (interchangeably referred to as RUs) among plurality of sensing transmitters 504-(1-N) and configures transmission parameters. According to an implementation, system 500 may be an OFDMA enabled system.

Referring back to FIG. 5, according to one or more implementations, Wi-Fi sensing system 500 may participate in a sensing session. In examples, a sensing session is an agreement between a sensing initiator and a sensing responder to participate in a WLAN sensing procedure (also known as a Wi-Fi sensing procedure.) In examples, sensing measurement parameters associated with a sensing session may be determined by a sensing initiator and may be exchanged between the sensing initiator and a sensing responder. In examples, sensing initiator may be sensing transmitter 504-1 and sensing responder may be sensing receiver 502-1. In examples, sensing initiator may be sensing receiver 502-1 and sensing responder may be sensing transmitter 504-1. In examples, sensing initiator may be remote processing device 506, and both sensing transmitter 504-1 and sensing receiver 502-1 are sensing responders. In examples, sensing transmitter 504-1 may participate in multiple sensing sessions either as a sensing initiator or as a sensing responder. In examples, sensing receiver 502-1 may participate in multiple sensing sessions either as a sensing initiator or as a sensing responder. In examples, remote processing device may participate in multiple sensing sessions as a sensing initiator.

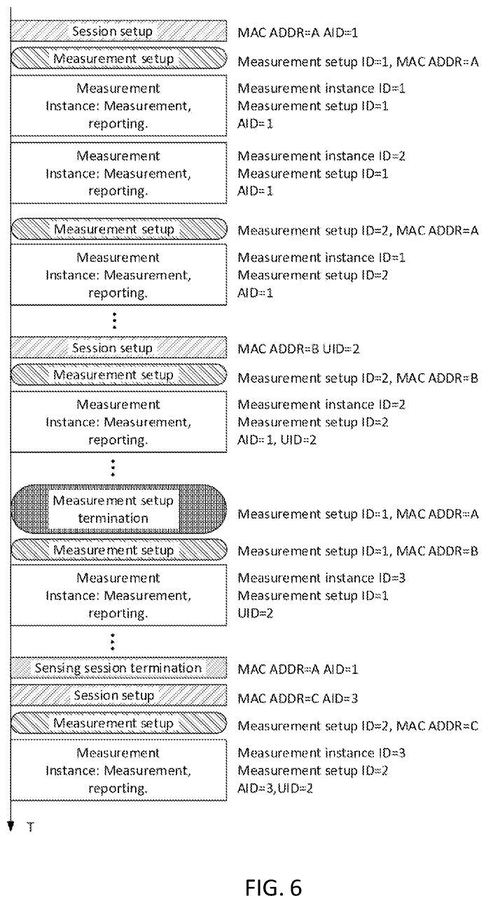

FIG. 6 illustrates an example of a WLAN sensing procedure (also known as a Wi-Fi sensing procedure) according to some embodiments. In examples, a WLAN sensing procedure allows a STA to perform WLAN sensing. In an example, a WLAN sensing procedure enables a STA to obtain one or more sensing measurements of the wireless transmission channel between two or more STAs and or the wireless transmission channel between a receive antenna and a transmit antenna of a STA. In examples, a WLAN sensing procedure is composed of one or more of a sensing session setup, a sensing measurement setup, one or more sensing measurement instances, sensing measurement setup termination, and sensing session termination.

FIG. 6 illustrates a sensing session setup with a STA with MAC ADDR=A and AID=1, In examples, a sensing session setup establishes a sensing session. In examples, the sensing session may be identified by the AID of the STA involved in the sensing session. FIG. 6 illustrates a sensing measurement setup procedure for the STA with MAC ADDR=A, where the sensing measurement setup ID=1.

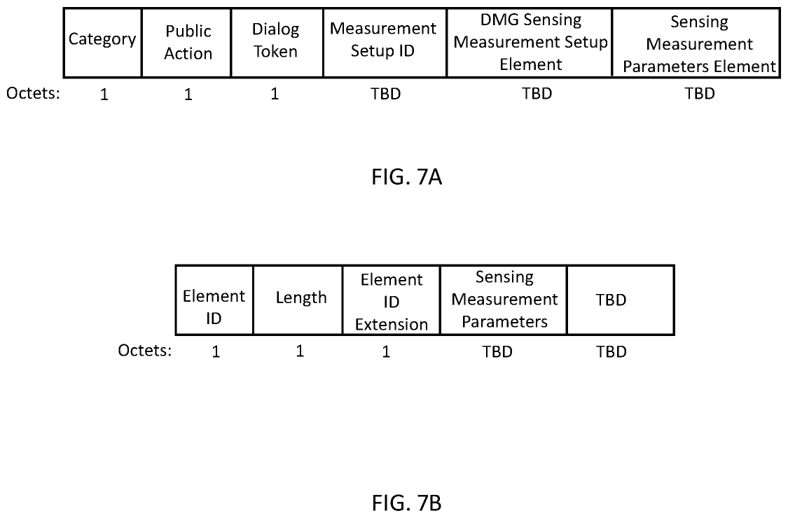

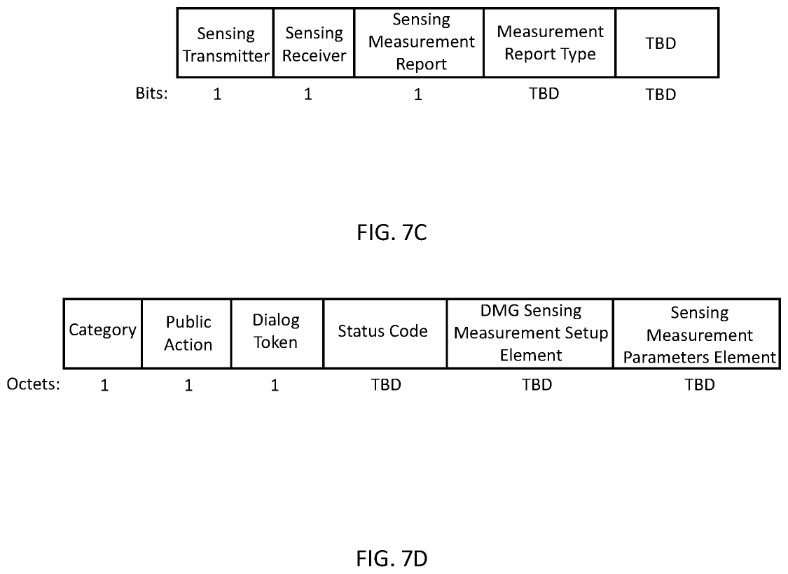

In examples, a sensing measurement setup allows for a sensing initiator and a sensing responder to exchange and agree on operational attributes associated with a sensing measurement instance. A sensing initiator may transmit a Sensing Measurement Setup Request frame to a sensing responder with which it intends to perform a sensing measurement setup. An example of a Sensing Measurement Setup Request frame is provided in FIG. 7A. In examples, the Sensing Measurement Setup Request frame is a Public Action frame, and in examples is identified by a Public Action field value. As shown in the example illustrated in FIG. 7A, in embodiments, a Sensing Measurement Set Request frame format may include one or more of a Category field, a Public Action field, a Dialog Token field, a Measurement Setup ID field, a DMG Sensing Measurement Setup Element field, and a Sensing Measurement Parameters element. In examples, a Category value code is defined for a “Protected Sensing Frame.” In an embodiment, a Protected Sensing Action field is defined in the octet immediately after the Category field in order to differentiate Protected Sensing Frame formats from Public Sensing Frame formats.

FIG. 7B illustrates an example, according to some embodiments, of a Sensing Measurement Parameters element. In examples, a Sensing Measurement Parameters element indicates operational attributes of a corresponding sensing measurement instance. In examples, the Sensing Measurement Parameters element comprises a Sensing Measurement Parameters field. FIG. 7C illustrates an example of a format of a Sensing Measurement Parameters field, according to some embodiments. In an example, a Sensing Measurement Parameters field comprises a Sensing Transmitter subfield. The Sensing Transmitter subfield may be set to 1 to indicate a sensing responder assumes a sensing transmitter role, such as sensing transmitter 504-1. In an example the sensing responder assumes a sensing transmitter role according to the Sensing Transmitter subfield for the Sensing Measurement Setup ID associated with the Sensing Measurement Parameters field. In an example, the Sensing Measurement Parameters field comprises a Sensing Receiver subfield. The Sensing Receiver subfield may be set to 1 to indicate a sensing responder assumes a sensing receiver role, such as sensing receiver 502-1. In an example the sensing responder assumes a sensing receiver role according to the Sensing Receiver subfield for the Sensing Measurement Setup ID associated with the Sensing Measurement Parameters field.

Referring again to FIG. 7C, in examples, a Sensing Measurement Parameters field format includes a Sensing Measurement Report subfield if the Sensing Receiver subfield indicates that the sensing responder should assume a sensing receiver role. In an example, the Sensing Measurement Report subfield may indicate whether or not a sensing responder sends Sensing Measurement Report frames in sensing measurement instances that result from the sensing measurement setup.

Referring again to FIG. 7C, in examples, a Sensing Measurement Parameters field format includes a Measurement Report Type subfield. In examples, the Measurement Report Type subfield indicates the type of measurement result reported in sensing measurement instance(s) corresponding to the sensing measurement setup ID, for example when the sensing initiator is a sensing transmitter, such as sensing transmitter 504-1.

In examples, after the sensing responder receiver the Sensing Measurement Setup Request frame, the sensing responder may transmit a Sensing Measurement Setup Response frame. An example of a Sensing Measurement Setup Response frame is provided in FIG. 7D. In examples, the sensing responder may use a Status Code field in the Sensing Measurement Setup Response frame to indicate whether the sensing responder accepts the requested sensing measurement setup parameters in the received Sensing Measurement Setup Request frame. In an embodiment, the Status Code field may be set to 0 indicating a successful sensing measurement setup, where the sensing responder accepts the operational attributes included in the Sensing Measurement Setup Request frame. In examples, the sensing responder may indicate in the Sensing Measurement Setup Response frame that the operational attributes included in the Sensing Measurement Setup Request frame sent by the sensing initiator are not accepted, for example, by setting a Status Code field to a non-zero value. In examples, the sensing responder may indicate in the Sensing Measurement Setup Response frame preferred sensing measurement parameters, for example, to indicate to the sensing initiator one or more operational attributes preferred by the sensing responder. In examples, the sensing responder may indicate to the sensing initiator that preferred sensing measurement parameters are included in the Sensing Measurement Setup Response frame by setting a Status Code field to a non-zero value.

In examples, the sensing initiator may assign a role to the sensing responder as part of the sensing measurement setup sent in the Sensing Measurement Setup Request frame. For example, the sensing initiator may indicate to a sensing responder that the sensing responder is to assume the role of a sensing receiver, such as sensing receiver 502-1, or the role of a sensing transmitter, such as sensing transmitter 504-1, or the role of sensing receiver 502-1 and sensing transmitter 504-1. In examples, sensing initiator may indicate to sensing responder whether the sensing responder sends sensing measurement report frames in sensing measurement instances. In an embodiment, the role assigned to the sensing responder and/or whether the sensing responder sends sensing measurement report frames persists until the sensing measurement setup is terminated.

Referring again to FIG. 6 and the sensing session with the STA with MAC ADDR=A identified by the STA AID, AID=1, the sensing measurement setup is followed by one or more sensing measurement instances and measurement reporting instances which may be performed based on the defined operational attribute set. In the example shown in FIG. 6, the one or more sensing measurement instances for the STA with MAC ADDR=A may be assigned sensing measurement instance IDs, for example, a first sensing measurement instance may be assigned sensing measurement instance ID=1, and a second measurement instance may be assigned sensing measurement instance ID=2. In examples, a sensing measurement instance may be uniquely associated with a sensing measurement setup.

Referring again to FIG. 6, a second sensing measurement setup may be initiated for the STA with MAC ADDR=A, which may be identified as sensing measurement setup ID=2. As with sensing measurement setup ID=1, sensing measurement setup ID-2 may be associated with a second operational attribute set. In examples, after the second sensing measurement setup, any subsequent one or more sensing measurement instances may be performed based on either the first operational attribute set (sensing measurement setup ID=1) or the second operational attribute set (sensing setup measurement ID=2.)

Referring again to FIG. 6, FIG. 6 illustrates a sensing session setup with a STA with MAC ADDR=B and UID=2. In examples, the sensing session may be identified by the UID of the STA with MAC ADDR=B. FIG. 6 further illustrates a sensing measurement setup for the STA with MAC ADDR=B. In the example, the operational attribute set for the sensing measurement setup for the STA with MAC ADDR=B is the same as the second operational attribute set established with the STA with MAC ADDR-A, and the sensing measurement setup ID is used for both the STA with MAC ADDR=A and the STA with MAC ADDR=B. That is, a sensing measurement setup ID (which may also be referred to as a sensing measurement setup label) may apply to one or more STA. In examples, according to FIG. 6, subsequent sensing measurement instances associated with sensing measurement setup ID=2 may be associated with the STA with MAC ADDR=A, the STA with MAC ADDR=B, or with both the STA with MAC ADDR=A and the STA with MAC ADDR=B. An example of one-to-many triggering is shown in FIG. 6 where AID=1 and UID=2 are both associated with a single measurement instance and measurement reporting (measurement instance ID=2 and measurement setup ID=2.)

In examples, an operational attribute set of a sensing session may be terminated by performing a sensing measurement setup termination procedure, for example, as is shown in FIG. 6 for sensing measurement setup ID=1 and the STA with MAC ADDR-A. In examples, the sensing measurement setup ID of a terminated sensing measurement setup may be used for a subsequent sensing measurement setup. This is shown in FIG. 6 where a sensing measurement setup with ID=1 is established for the STA with MAC ADDR=B, after the termination of the sensing measurement setup ID=1 with the STA with MAC ADDR=A. In some embodiments, a sensing session may be terminated using a sensing session termination procedure, as shown in FIG. 6.

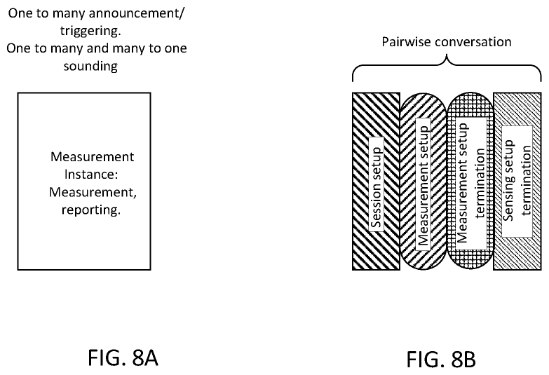

FIG. 8A illustrates exchanges between a sensing initiator and a sensing responder that may be one-to-many or many-to-one. In examples, a measurement instance and/or measurement reporting may have a one-to-one (single device to single device) announcement or triggering or may have a one-to-many (single device to multiple device) announcement or triggering. In examples, a measurement instance may have a one-to-one, one-to-many, or many-to-one (many devices to a single device) sounding.

As previously described, a sensing session is an agreement between a sensing initiator and a sensing responder to participate in a WLAN sensing procedure, that is a sensing session is pairwise and in examples, may be identified by MAC addresses of the sensing initiator and the sensing responder or by the associated AID/UID. FIG. 8B shows an example of pairwise exchanges or procedures that may take place between a sensing initiator and a sensing responder related to a sensing session, which include a sensing session setup, a sensing measurement setup, a sensing measurement setup termination, and a sensing session termination.

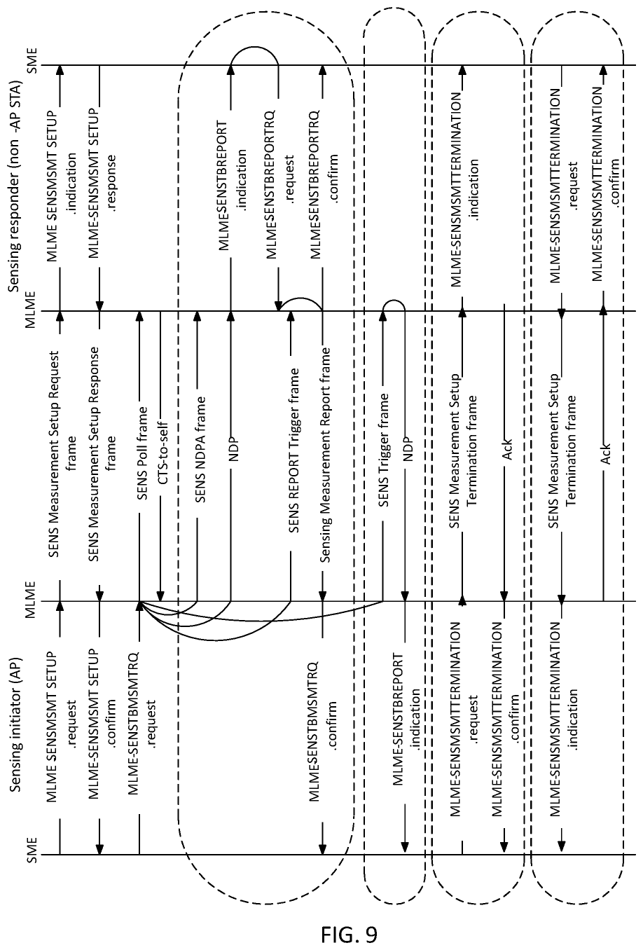

In examples, a sensing measurement instance of a WLAN sensing procedure may be a trigger-based (TB) sensing measurement instance. FIG. 9 depicts a message flow of a sensing session of a WLAN sensing procedure comprising a sensing measurement setup procedure followed by one or more trigger-based (TB) sensing measurement instances that consist of either NDPA sounding or trigger frame (TF) sounding, following by a sensing measurement setup termination procedure, according to some examples. In examples, a TB sensing measurement instance may be used where the sensing initiator is an AP and one or more non-AP STAs are sensing responders. In examples, a TB sensing measurement instance may include a polling phase, an NDPA sounding phase, a trigger frame (TF) sounding phase, and a reporting phase.

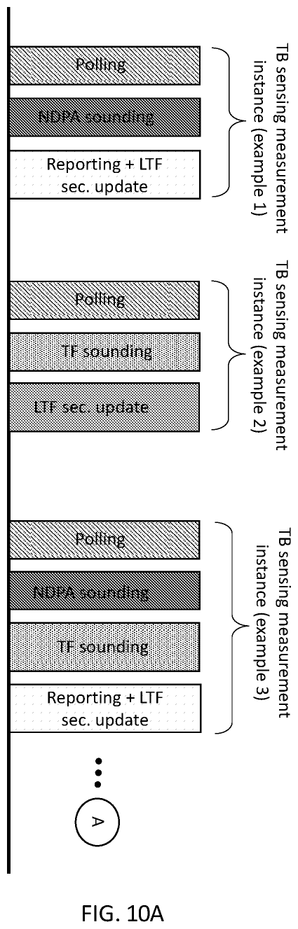

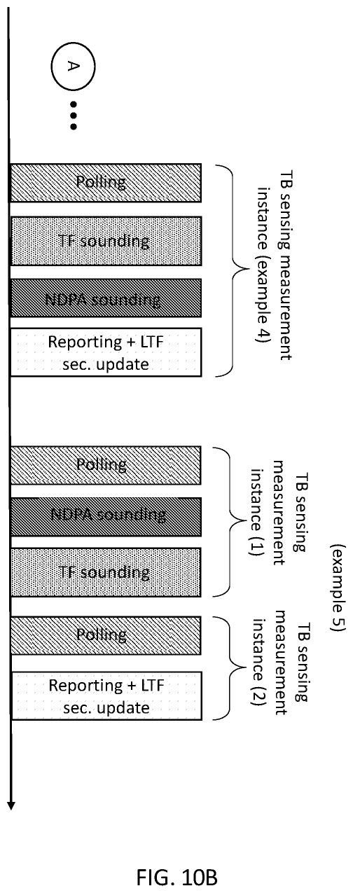

FIG. 10A and FIG. 10B illustrate five examples of TB sensing measurement instances. Example 1 of FIG. 10A illustrates an example of a TB sensing measurement instance comprising a polling phase, an NDPA sounding phase, and a reporting phase. Example 2 of FIG. 10A illustrates an example of a TB sensing measurement instance comprising a polling phase and a TF sounding phase. Example 3 of FIG. 10A and Example 4 of FIG. 10B illustrate two examples of a TB sensing measurement instance comprising a polling phase, an NDPA sounding phase, a TF sounding phase, and a reporting phase. Example 5 of FIG. 10B shows two TB sensing measurement instances, where the first TB sensing measurement instance comprises a polling phase, an NDPA sounding phase, and a TF sounding phase, and the second TB sensing measurement instance comprises a polling phase and a reporting phase. In examples, the TF sounding phase of the TB sensing measurement instance may precede the NDPA sounding phase of the TB sensing measurement instance, for example as in Example 4. In examples, the NDPA sounding phase of the TB sensing measurement instance may precede the NDPA sounding phase of the TB sensing measurement instance, for example as in Example 3. In some embodiments, the reporting phase of the second TB sensing measurement instance in Example 5 may be addressed to sensing responders other than the sensing responders involved in the TF sounding phase or the NDPA sounding phase of the first TB measurement instance.

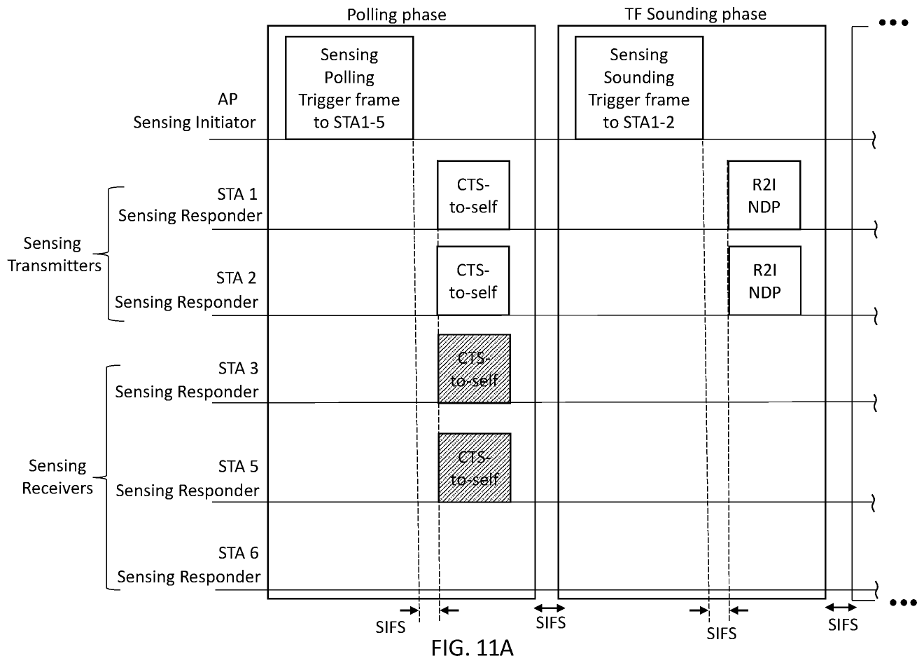

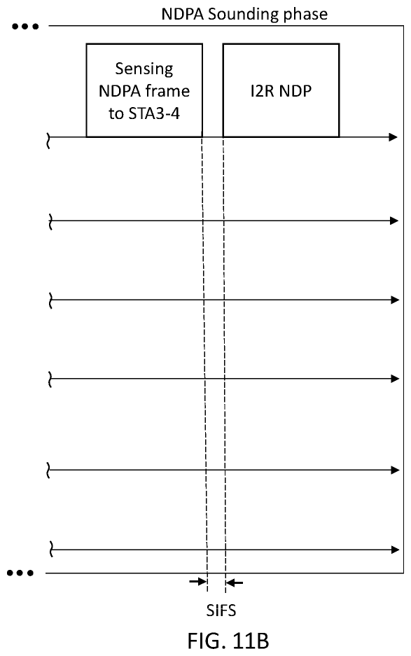

FIG. 11A and FIG. 11B are one example of a TB sensing measurement instance with a single AP in the role of a sensing initiator and five STAs, referred to as STA 1, STA 2, STA 3, STA 4, and STA 5, all of which in the example are sensing responders. In the example, the TB sensing measurement instance comprises a polling phase, a TF sounding phase, and an NDPA sounding phase. In the example, STA 1 and STA 2 are sensing transmitters, such as sensing transmitter 504-1 and sensing transmitter 504-2. In the example of FIG. 11A and FIG. 11B, STA 3, STA 4, and STA 5 are sensing receivers, such as sensing receiver 502-1, sensing receiver 502-2, and sensing receiver 502-3. In examples, in the polling phase, the AP as the sensing initiator transmits a Sensing Polling Trigger frame to STA 1, STA 2, STA 3, STA 4, and STA 5. In an embodiment, sensing transmitter STA 1 (504-1) and sensing transmitter STA 2 (504-2) respond to the Sensing Polling Trigger frame with an indication that the STA is available to participate in a sensing measurement instance. In examples, the indication is a CTS-to-self frame. In an embodiment, sensing receiver STA 3 (502-1) and sensing receiver STA 4 (502-2) respond to the Sensing Polling Trigger frame with an indication that the STA is available to participate in a sensing measurement instance. In examples, the indication is a CTS-to-self frame. In the example, sensing receiver STA 5 (502-3) does not respond to the Sensing Polling Trigger frame sent by the AP as the sensing initiator, indicating that STA 5 (502-3) will not participate in the sensing measurement instance.

The sensing measurement instance of FIG. 11A and FIG. 11B includes a TF Sounding phase. In examples, in the TF Sounding phase, the AP as the sensing initiator sends a Sensing Sounding Trigger frame to sensing transmitter STA 1 (504-1) and to sensing transmitter STA 2 (504-2). In examples, a period of one or more SIFS elapses between the AP receiving the CTS-to-self frames from STA 1, STA 2, STA 3, and STA 4 before sending the Sensing Sounding Trigger frame. In examples, responsive to receiving the Sensing Sounding Trigger frame, sensing transmitter STA 1 (504-1) and sensing transmitter STA 2 (504-2) send sensing transmissions to the AP. In examples, the sensing transmissions may comprise NDP transmissions. In an example, one or more of the NDP transmissions to the AP may be R2I NDP transmissions (as shown in the example of FIG. 11A and FIG. 11B). In examples, a period of one or more SIFS elapses between sensing transmitter STA 1 (504-1) receiving the Sensing Sounding Trigger frame and transmitting a sensing transmission, and in examples a period of one or more SIFS elapses between sensing transmitter STA 2 (504-2) receiving the Sensing Sounding Trigger frame and transmitting a sensing transmission. In examples, the AP may assume the role of sensing receiver 502-4, and the AP may make sensing measurements on the sensing transmissions from sensing transmitter STA 1 (504-1) and sensing transmitter STA 2 (504-2).

Referring again to FIG. 11A and FIG. 11B, in an NDPA sounding phase, the AP acting as sensing initiator assumes the role of sensing transmitter (504-3). In examples, the AP as sensing transmitter 504-3 transmits a sensing transmission. In examples, the sensing transmission may be a broadcast transmission. In examples, the sensing transmission may be a unicast transmission to one or more STAs, for example to sensing receiver STA 3 (502-1) and/or to sensing receiver STA 4 (502-2). In examples, a period of one or more SIFS elapses between the AP as sensing transmitter 504-3 sending the sensing NDPA frame and when the AP as sensing transmitter 504-3 sends the one or more sensing transmissions. In examples, one or more of the sensing transmissions may be a full bandwidth NDP frame. In examples, one or more of the sensing transmissions may be a partial bandwidth NDP frame. In examples, one or more of the NDP frames may be an I2R NDP frame.

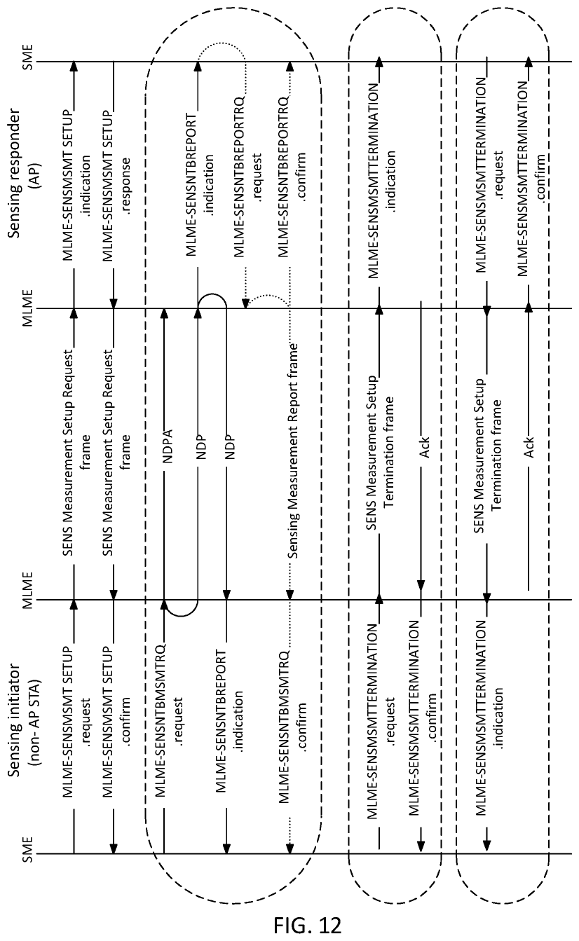

In examples, a sensing measurement instance of a WLAN sensing procedure may be a non-trigger-based (non-TB) sensing measurement instance. FIG. 12 depicts a message flow of a sensing measurement setup procedure followed by one or more non-TB sensing measurement instances of a WLAN sensing procedure that consist of one or more of downlink sounding or uplink sounding, according to some embodiments, followed by a sensing measurement setup termination procedure, according to some examples. In examples, a non-TB sensing measurement instance may be used where the sensing initiator is a non-AP STA and an AP is the sensing responder. In examples of uplink sounding as shown in FIG. 12, the sensing initiator (non-AP STA) acting as a sensing transmitter (for example, sensing transmitter 504-1) transmits a sensing announcement frame followed by a sensing transmission. In examples, the sensing announcement frame may be an NDPA frame. In examples, the sensing transmission may be an NDP frame. In examples, responsive to receiving the sensing transmission, the AP acting as a sensing receiver (for example, sensing receiver 502-1), may transmit to the sensing initiator (non-AP STA in the role of sensing transmitter 504-1) a sensing measurement report, for example one or more Sensing Measurement Report frames. In examples of downlink sounding as shown in FIG. 12, the sensing initiator (non-AP STA) acting as a sensing receiver (for example, sensing receiver 502-1) transmits a sensing announcement frame. In examples, the sensing announcement frame may be an NDPA frame. In examples, responsive to receiving the sensing announcement frame, the AP acting as sensing transmitter (for example, sensing transmitter 504-1) may transmit one or more sensing transmissions. In examples, one or more of the sensing transmissions may be an NDP frame. In examples, the non-AP STA acting as a sensing receiver (502-1), responsive to receiving a sensing transmission, may make a sensing measurement on the sensing transmission. In examples, the sensing measurement setup may be terminated by the sensing initiator or the sensing responder transmitting a SENS Measurement Setup Termination frame. In examples, the sensing responder or sensing initiator (respectively) may respond with an acknowledgment.

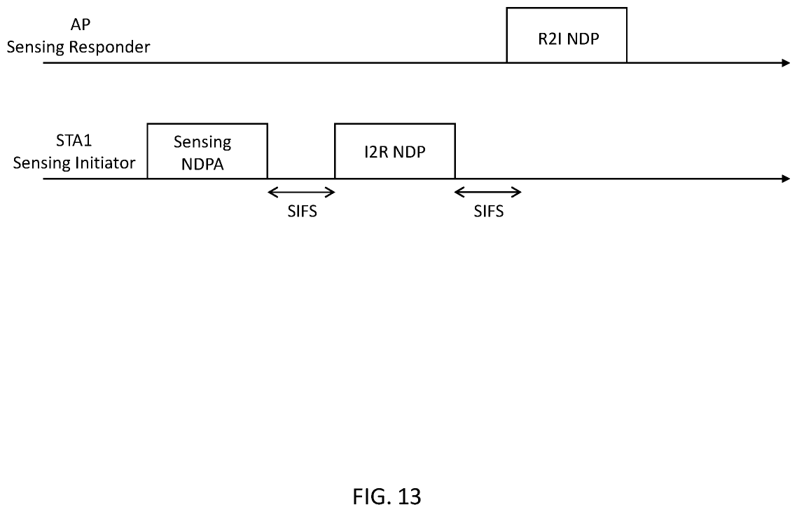

FIG. 13 illustrates a detailed example of a non-TB sensing measurement instance, according to some embodiments. In examples, STA 1 acting as sensing initiator and sensing transmitter, such as sensing transmitter 504-1, transmits a sensing announcement frame. In examples, the sensing announcement frame may be a sensing NDPA frame. In examples, one or more SIFS may elapse followed by STA 1 acting as sensing initiator and sensing transmitter (such as sensing transmitter 504-1) transmitting one or more sensing transmissions. In examples, one or more of the sensing transmissions may be an NDP frame. In an example. STA 1 acting as sensing initiator and sensing receiver, such as sensing receiver 502-1, transmits a sensing announcement frame. In examples, the sensing announcement frame may be a sensing NDPA frame. In examples, one or more SIFS may elapse followed by AP 1 acting as sensing responder and sensing transmitter (such as sensing transmitter 504-1) transmitting one or more sensing transmissions. In examples, one or more of the sensing transmissions may be an NDP frame.

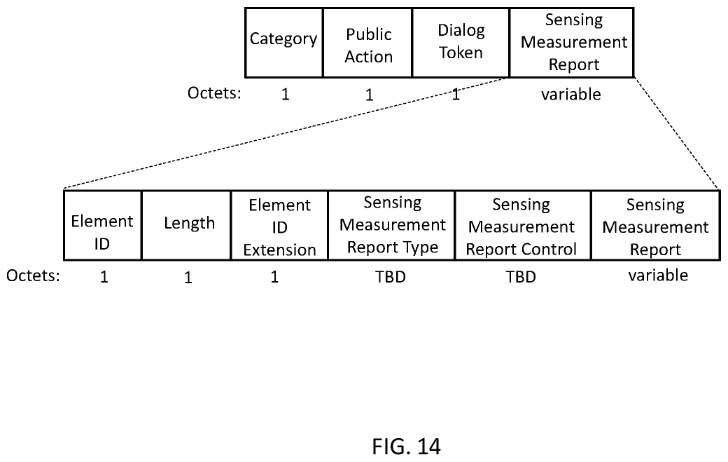

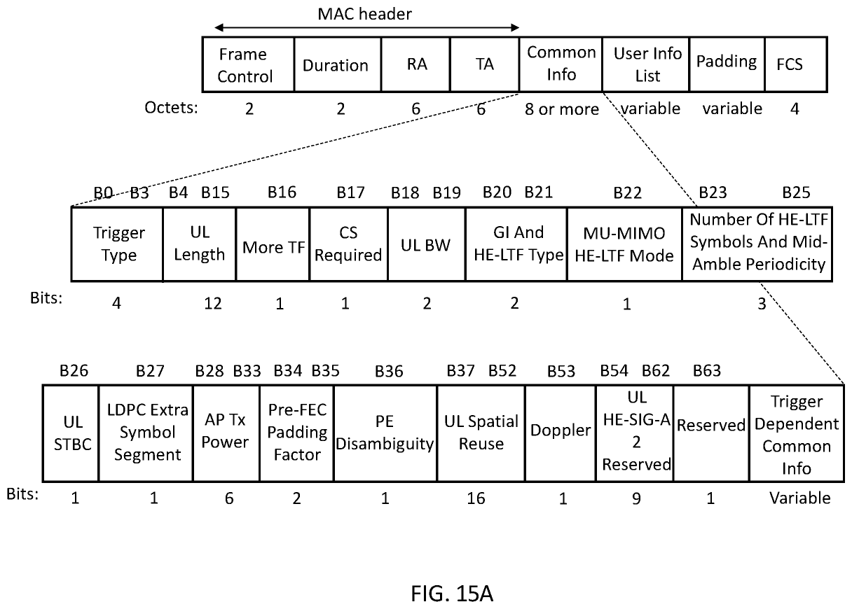

FIG. 14 illustrates an example of a Sensing Measurement Report frame. In some embodiments, a Sensing Measurement Report frame is a Public Action category or a Public Action No Ack category. In some examples, a Sensing Measurement Report frame may be transmitted to provide WLAN sensing measurements, for example to a sensing agent or a sensing algorithm of a sensing initiator. In examples, a Sensing Measurement Report frame may comprise one or more Sensing Measurement Report elements. A Sensing Measurement Report element may comprise a single sensing measurement report, in some embodiments. In examples, a Sensing Measurement Report element may include a Sensing Measurement Report type field, which may contain a number that identifies the type of sensing measurement report. For example, a value of 0 may indicate that the sensing measurement type is a CSI measurement, whereas a non-zero value may indicate that the sensing measurement type is a TD-CRI measurement.

Referring again to FIG. 14, in embodiments a Sensing Measurement Report element may include a Sensing Measurement Report Control field. In examples, the Sensing Measurement Report Control field may contain information necessary to interpret the Sensing Measurement Report field. For example, the Sensing Measurement Report Control field format may comprise one or more subfields. In an embodiment, one or more subfields of the Sensing Measurement Report Control field may include PHY layer parameters used by the sensing receiver when performing the sensing measurement, for example receiver antenna beamforming or spatial layer information.

In a sensing session, exchanges of transmissions between one or more of plurality of sensing receivers 502-(1-M) and one or more of plurality of sensing transmitters 504-(1-N) may occur. In an example, control of these transmissions may be with the MAC layer of the IEEE 802.11 stack. According to an implementation, one or more of plurality of sensing receivers 502-(1-M) may secure a TXOP which may be allocated to one or more sensing transmissions by one or more of plurality of sensing transmitters 504-(1-N). According to an implementation, one or more of plurality of sensing receivers 502-(1-M) may allocate channel resources (or RUs) within a TXOP to the one or more of plurality of sensing transmitters 504-(1-N). In an example, one or more of plurality of sensing receivers 502-(1-M) may allocate the channel resources to the one or more of plurality of sensing transmitters 504-(1-N) by allocating time and bandwidth within the TXOP to the one or more of plurality of sensing transmitters 504-(1-N).

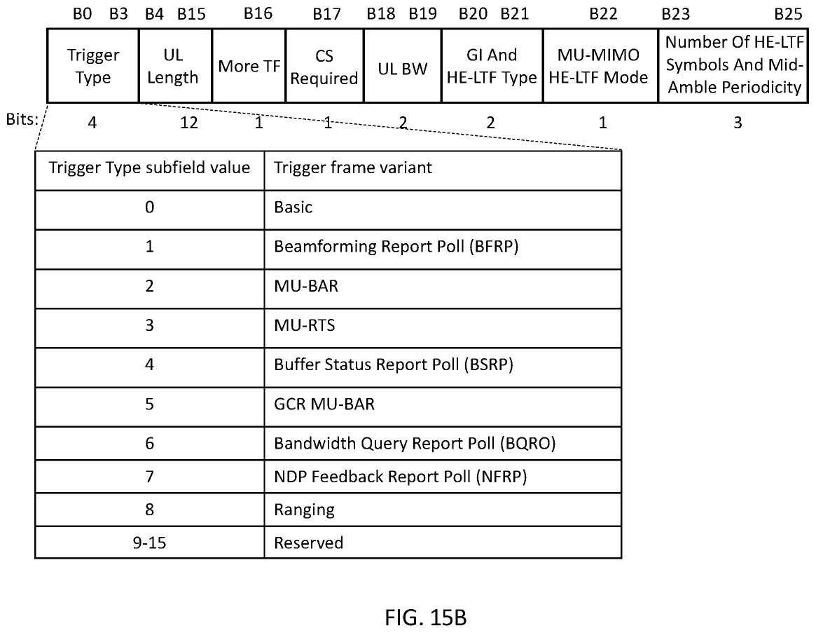

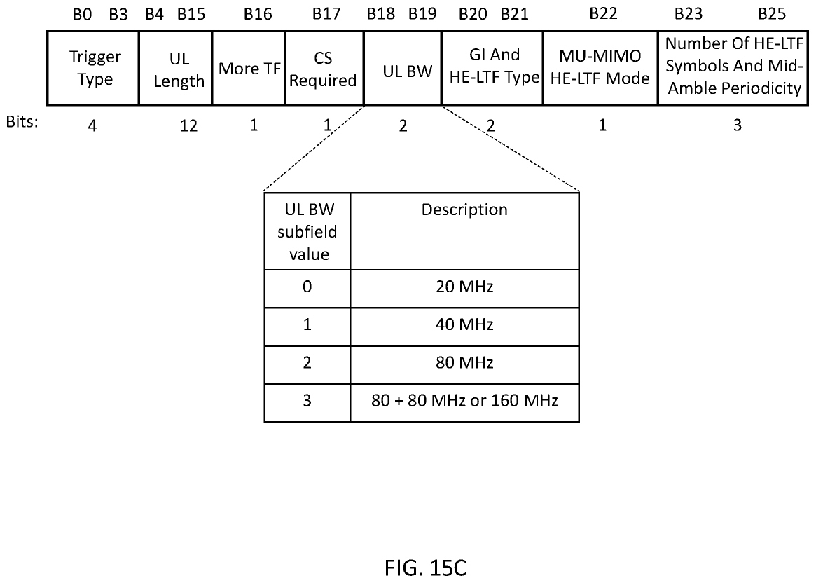

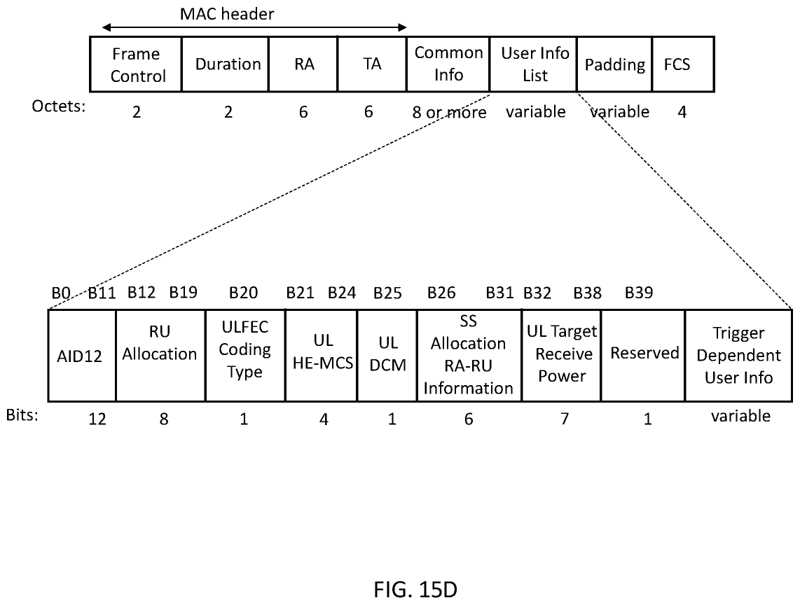

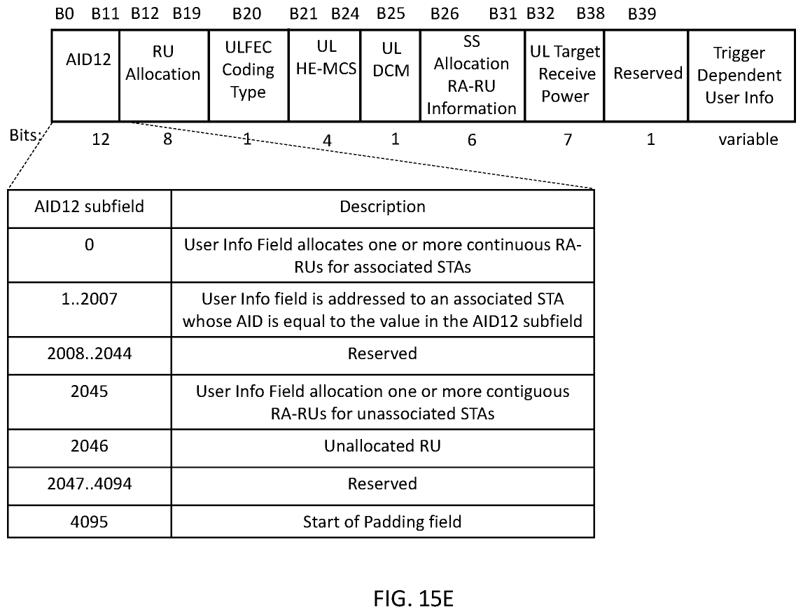

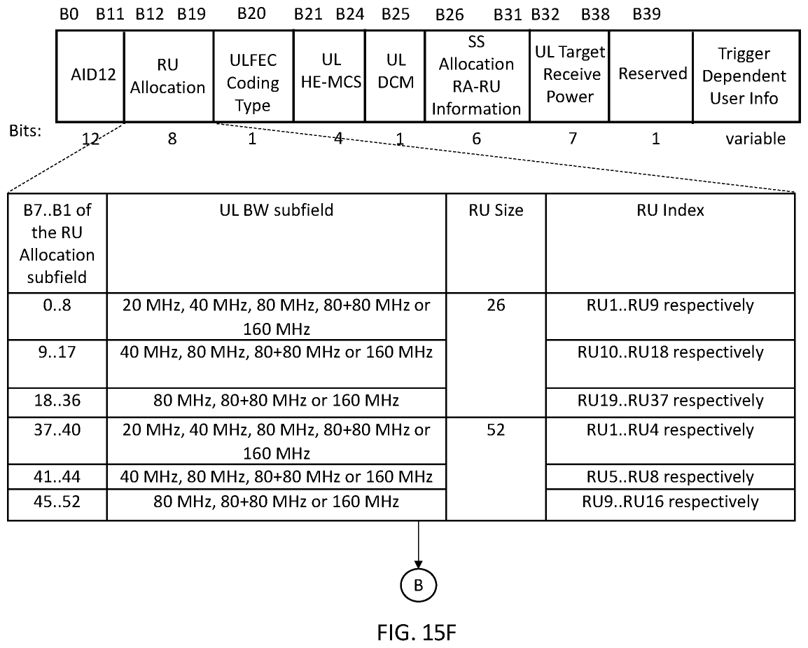

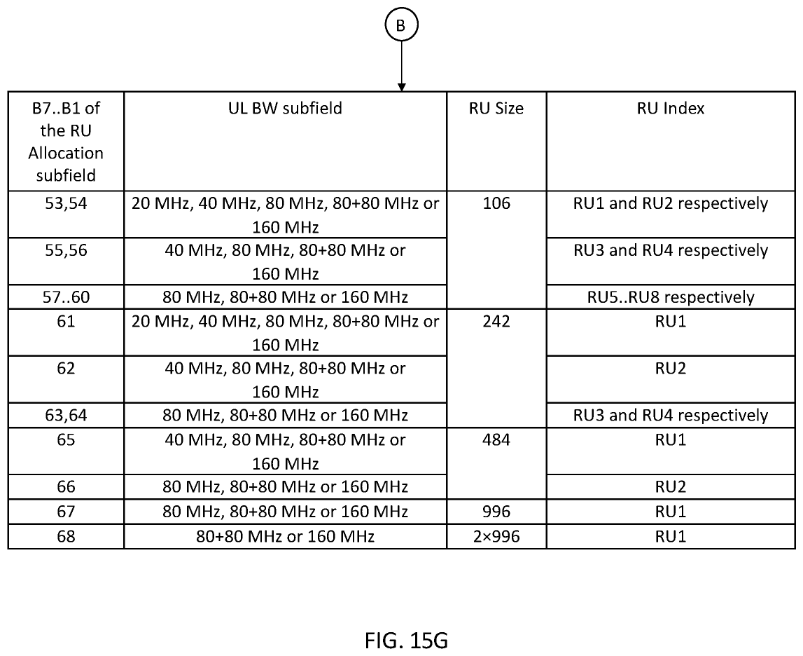

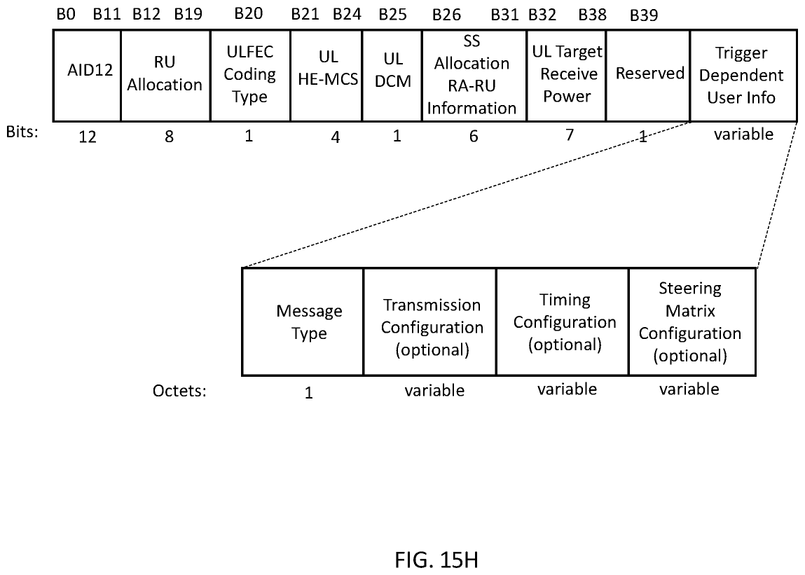

According to an implementation, an example of a hierarchy of fields within sensing trigger message is shown in FIG. 15A to FIG. 15H.

As described in FIG. 15A, the Common Info field may contain information which is common to one or more of plurality of sensing transmitters 504-(1-N). According to some implementations, the requirement of an NDPA preceding an NDP may be optional. This may be indicated to one or more of plurality of sensing transmitters 504-(1-N) and may for example be encoded into a “Trigger Dependent Common Info” field if the requirement is common to plurality of sensing transmitters 504-(1-N), or into a “Trigger Dependent User Info” field if the requirement is specific to one or more of plurality sensing transmitters sensing transmitters 504-(1-N). According to an example, the requirement for a sensing announcement (for example, and NDPA) preceding a sensing response NDP may be encoded by a single bit where 0 (bit clear) indicates that a sensing announcement is optional and 1 (bit set) indicates that a sensing announcement is required.

As described in FIG. 15B, a Trigger Type (within B0 . . . 3 of “Common Info” field) may be defined which represents a sensing trigger message. In examples, a sensing Trigger message may have a Trigger Type subfield value of any Reserved value from 9-15, for example a Sensing Trigger message may have a Trigger Type subfield value of 9. In an example of triggering a sensing transmission from a sensing transmitter 504-1, a Trigger Dependent User Info field may include sensing trigger message data. In an implementation, a time-synchronized sensing transmission may be required from plurality of sensing transmitters 504-(1-N) responding to a sensing trigger message. In an example, the requirement for one or more time-synchronized sensing transmissions may be encoded into a Trigger Dependent Common Info field. According to an example, the requirement for one or more time-synchronized sensing transmissions may be encoded by a single bit where 0 (bit clear) represents a request for a normal or non-time-synchronized response and 1 (bit set) represents a request for a time-synchronized response. In some examples, a method of time-synchronization may be requested in the sensing trigger. In examples, the method of time-synchronization to be requested may be encoded into a Trigger Dependent Common Info field. In examples the encoding may use two bits as shown in the following table.

| Encoding | Method | Description |
|---|---|---|
| 00 | A | Sensing announcement followed by sensing |
| | | NDP. |
| 01 | B | Padding followed by a sensing response |
| | | message. |
| 10 | C | Sensing NDP without an initial sensing |
| | | announcement. |
| 11 | N/A | For future use or extensions. |

As described in FIG. 15C, the sensing trigger message may have an uplink bandwidth (UL BW) subfield value of 0, 1, 2 or 3 corresponding to bandwidths of 20 MHz, 40 MHz, 80 MHz, or 80+80 MHz (160 MHz).

As described in FIG. 15D, the User Info List contains information which is specific to each of the plurality of sensing transmitters 504-(1-N). In examples, the User Info List may include the AID of a sensing transmitter, an RU allocation for a sensing transmitter, and other Trigger Dependent User Info.

As described in FIG. 15E, the AID12 subfield of the User Info List illustrated in FIG. 15D may be used to address a specific sensing transmitter of the plurality of sensing transmitters 504-(1-N).

As described in FIG. 15F and FIG. 15G, the RU Allocation subfield is used to allocate resource units (RU) to each of the plurality of sensing transmitters 504-(1-N).

As described in FIG. 15H, the Trigger Dependent User Info subfield may be used to request the transmission configuration and/or steering matrix configuration for one or more of the plurality of sensing transmitters 504-(1-N) that the sensing trigger message is triggering.

C. Wi-Fi Sensing Taking into Consideration Received Noise Power Information

The present disclosure generally relates to systems and methods for Wi-Fi sensing. In particular, the present disclosure relates to systems and methods for Wi-Fi sensing taking into consideration received noise power information.

A typical Wi-Fi sensing system includes a sensing transmitter (which may be an access point (AP) or a non-AP station (STA)) and a sensing receiver (which is an AP if the sensing transmitter is a STA, and a STA if the sensing transmitter is an AP). A sensing measurement may be performed on a sensing transmission which may be transmitted from the sensing transmitter to the sensing receiver through a sensing space. The sensing space is a free space that may include objects which are to be sensed. Further, the sensing transmitter and the sensing receiver may be Wi-Fi devices that implement both analog and digital processing of the sensing transmission. In an example, the sensing measurement may be a measurement of amplitude (or power) and phase at each of a plurality of frequency channels across a band or a partial band (also referred to as a resource allocation (RU)). In examples, the sensing measurement may be a channel state information (CSI). In an example, the CSI may be a form of channel representation information (CRI). The CSI may be further processed by a sensing algorithm to reduce the content of the sensing measurement. In examples, the sensing measurement may be processed to reduce the size of the sensing measurement and to reduce the overhead of transferring and processing the sensing measurement.

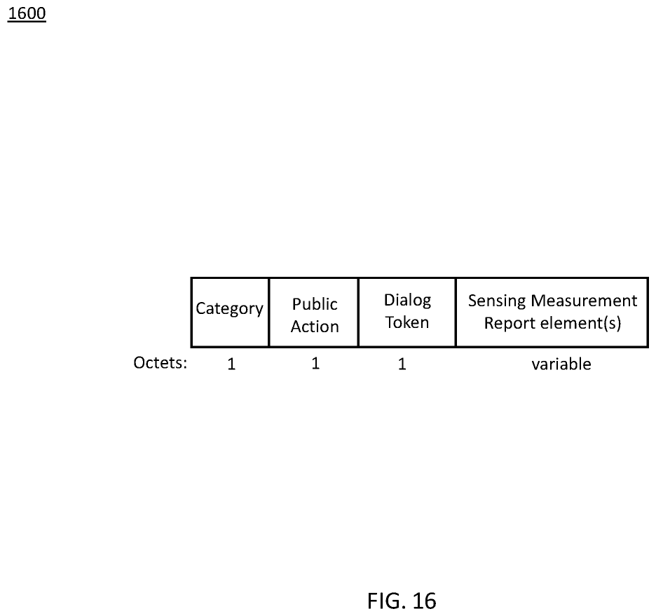

In examples, a sensing transmission may be received at a sensing receiver as a power level. In an example, the sensing transmission typically undergoes amplification in a RF receive chain of the sensing receiver (for example, by a low noise amplifier (LNA) and/or a variable gain amplifier (VGA)). The power level may be measured at a baseband receiver of the sensing receiver as a received signal strength (in dBm) or as a received signal strength indicator (RSSI) (dimensionless scale from 0 to RSSImax). A value of 255 is an example of RSSImax. The LNA and/or VGA setting may typically be provided to the baseband receiver of the sensing receiver. At the same time, the transmission channel (i.e., the sensing space), transmissions from other devices (i.e., interference), and the sensing receiver chain processing contributes to a received noise power in the reception bandwidth of the sensing receiver. A ratio of received signal power and received noise power (or noise plus interference power) provides the signal to noise ratio (SNR) (or signal to interference and noise ratio (SINR)).

Where a sensing measurement is made by a sensing receiver (acting as a sensing responder), the sensing measurement may be transferred to a sensing initiator (acting as a sensing transmitter or a remote processing device). In examples, the sensing measurement may be transferred using a sensing measurement report. In some cases, the sensing measurement report may be triggered by a Sensing Measurement Report frame. The signaling of the Sensing Measurement Report frame is illustrated in FIG. 9. In examples, the signaling of the Sensing Measurement Report frame may also be illustrated for a non-trigger-based sensing measurement instance. This is described in FIG. 12. Further, format 1600 of a Sensing Measurement Report frame is shown in FIG. 16. FIG. 16 is reproduced from FIG. 9-1139d of P802.11bf/D0.2.

In digital communications, the receiver/demodulator may be responsible for maximizing the probability of predicting the correct encoded information, which is typically measured as a bit error rate (BER). Further, for sensing, a sensing algorithm may be responsible for maximizing the correct prediction of environment changes, which is typically measured as a false alarm rate. For both cases, the sensing receiver may rely on the automatic gain control (AGC) to set the front end gain for maximizing the probability of the demodulator or sensing algorithm to achieve their objective. In certain scenarios, the sensing algorithm may attempt to measure disturbances in the transmission channel caused by a physical change in environment. With that, the sensing algorithm needs to understand the noise present in each channel measurement in order to identify environment changes from noise (e.g., precision of input). Further, from measurement instance to measurement instance, the AGC may be required to select a different front end gain configuration, for example, due to adjacent channel interference. In examples, adjacent channel interference is a considerable problem given the channel spacing because it may not be possible to realize a sharp enough filter to fully attenuate a strong adjacent channel's signal, resulting in a potential reduction in gain (or even a different distribution of gain) to avoid compression. As a result, the sensing algorithm may determine if the noise has changed between measurements. Based on the determination, the sensing algorithm may maintain its own prediction error rate (e.g., compensate for change in measurement precision).

In an example, each measurement may include an indication of its precision (e.g., noise). This precision can be a function of how the AGC sets and distributes the gain within the receiver's front end. That means signaling is required for each measurement. A CRI (either CSI or TD-CRI) represents an unknown sensing space. A detection process may be used to identify parts of the CRI that can be distinguished from the background noise or noise plus interference power, and to discount those parts of the CRI that cannot be distinguished from the background noise or noise plus interference power. In a CSI sensing measurement, part of the CRI may be one or more OFDM subcarriers that make up a full CSI over a sensing measurement bandwidth. In a TD-CRI sensing measurement, part of the CRI may be a pulse that represents a delayed (reflected multipath) signal at a given delay of τ. An SNR or SINR of the signal that the CRI is generated on may be an important criteria for determining which parts of the CRI can be distinguished from the noise. In examples, a high SNR indicates that the CRI is likely to be clearly distinguished from noise. Conversely, with a low SNR, a detection from the detection process may be more easily confused with noise and so become a false detection (or a false alarm)). Also, a high SNR may be associated with a high confidence in a detection because the probability of false detection may be lower. As a transmission and channel is wideband, the value of received signal power and received noise power (therefore received SNR) may be frequency dependent.

In examples, a sensing algorithm that is responsible for processing one or more sensing measurement from one or more sensing receivers may not be local to the sensing receiver and may be implemented by a sensing transmitter or by an entirely separate sensing algorithm manager (remote processing device). The sensing algorithm may make a detection from a sensing measurement and so may benefit from knowledge of SNR. To determine an accurate received SNR, a method of optimal transfer, storage, and use of the measurements of received noise power or of received SNR associated with each sensing measurement is required.

The present disclosure describes a method of optimal storage, transfer, and use of the measurements of received noise power or of received SNR associated with one or more sensing measurements. In examples, the received noise power at a sensing receiver may be influenced by external factors or may be influenced by the processing of the sensing receiver itself. The received noise power also may be affected by gain in the sensing receiver processing. In an example, the gain may be variable, and may be independently and automatically controlled by the sensing receiver. In an example, the received noise power may be measured by modeling of the response of the sensing receiver. In some examples, the received noise power may be measured by calibration of the sensing receiver. In some examples, the received noise power may be measured during an engineering mode, where an input port of the sensing receiver is terminated (e.g., coupled to ground). Further, in some examples, the received noise power may be measured during normal operation in the absence of any known signal. In an example, the measurements of the received noise power may be both frequency-dependent and gain-dependent. The measurements of the received noise power may be stored in a form that accommodates the frequency and gain dependencies at the sensing receiver. The received noise power measurement may be associated with a sensing measurement performed on a sensing transmission received at the sensing received. Further, the received noise power measurement and the sensing measurement may be transferred to a sensing initiator or other device (and possibly transferred to a sensing application) using a Sensing Measurement Report frame which includes a Sensing Measurement Report element/field. In examples, the Sensing Measurement Report element/field may be extended to include received noise power measurement or received SNR/SINR relating to the sensing measurement which is reported.

According to an implementation, sensing receiver 502-1 (acting as a sensing responder and referred to as a first networking device) may send a sensing trigger message to sensing transmitter 504-1. In an implementation, sensing agent 516-1 may send the sensing trigger message to sensing transmitter 504-1 to trigger a sensing transmission. In an implementation, in response to the sensing trigger message, sensing transmitter 504-1 may transmit the sensing transmission to sensing receiver 502-1. In examples, sensing agent 516-1 may be configured to receive the sensing transmission from sensing transmitter 504-1. In some implementations, transmission of the sensing transmission may be performed responsive to an action of a sensing initiator (for example, remote processing device 506). In an example, the sensing transmission may be transmitted and received in a specific bandwidth, and may be processed by sensing receiver 502-1 at a specific level of automatic gain. In an implementation, upon receiving the sensing transmission, sensing agent 516-1 may perform a sensing measurement on the sensing transmission. In an implementation, sensing agent 516-1 may obtain a received noise power measurement (or received noise power information).

In examples, received noise power at sensing receiver 502-1 may be influenced by external factors in the transmission channel (sensing space). Examples of the external factors include, but are not limited to, thermal noise and external signals from other devices transmitting in the same band as sensing receiver 502-1, either directly or by out-of-band spurious transmissions. In an example, the other devices may include other sensing devices, other Wi-Fi devices, or other devices that share a frequency allocation with sensing receiver 502-1. In some implementations, the received noise power at sensing receiver 502-1 may be influenced by the processing of sensing receiver 502-1 itself (for example, the noise figure of the receiver front end, the quantization noise of the analog-to-digital conversion, etc.). According to some implementations, the received noise power may be affected by gain in the sensing receiver processing. In examples, the gain may be variable, and may be independently and automatically controlled by sensing receiver 502-1. In an example, multistage amplifiers may allow for distribution of gain throughout the signal chain, thereby providing implementation of specific system level tradeoffs when producing a specific gain level. One such tradeoff may be noise, as the selection of where to generate the gain may result in more or less noise added to the signal.

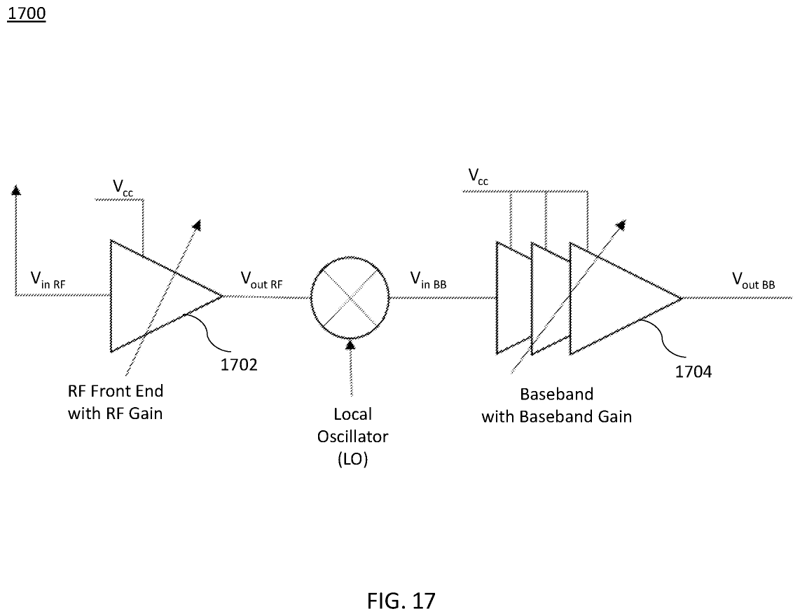

FIG. 17 illustrates example 1700 of a simplified receive chain of sensing receiver 502-1, according to some embodiments.

In examples, the receive chain of sensing receiver 502-1 includes RF front end 1702 and baseband 1704. According to the example of FIG. 17, there may be two gain components that may be present, referred to as, a programmable RF gain and a programmable baseband gain. In examples, these two gain components may work independently to condition an input signal for subsequent processing, and may be controlled using a feedback loop. In an example, both the gain components may be designed to sufficiently accommodate the full bandwidth of a sensing transmission and may be implemented by a band-limited amplifier, a pre-amplification bandpass filter, or a post-amplification bandpass filter. According to an implementation, by adding control logic around the gain components, the gain can be set to optimize receiver performance for a given receive signal. The control logic may be referred to as automatic gain control (AGC).

In an example, both gain components of the AGC may act to normalize the received power within the dynamic range of the baseband processing and so act to amplify both signal and noise. As such, a measurement of SNR/SINR may be dependent on the level of both automatic RF gain and automatic baseband gain. In some examples, a combined value of total automatic gain may be used and a measurement of SNR/SINR may be dependent on the single level of automatic gain.

As previously described, sensing agent 516-1 may obtain the received noise power measurement. In examples, the received noise power measurement may be obtained based on modeling a response of sensing receiver 502-1 and optionally a transmission channel. In some examples, the received noise power measurement may be obtained by calibrating sensing receiver 502-1. In some examples, the received noise power measurement may be obtained by operating sensing receiver 502-1 in an engineering mode, and determining the received noise power measurement in the engineering mode. In some examples, the received noise power measurement may be obtained based on accessing the received noise power measurement from a data storage (for example, noise power measurement storage 523-1). In an example, accessing the received noise power measurement from the data storage may include accessing the received noise power measurement according to a gain and a frequency. Further, in some examples, the received noise power measurement may be obtained based on determining the received noise power measurement during a standard operational mode of sensing receiver 502-1. In an implementation, determining the received noise power measurement may include performing the received noise power measurement during a period in which no signal is received. In an example, the period in which no signal is received may be associated with null carriers in the sensing transmission. Further, in an example, the period in which no signal is received may be associated with gaps between the sensing transmission and another transmission.

Examples by which the received noise power measurement is obtained or determined are described in detail below. In an example, the received noise power measurement may be determined as a function of both frequency and gain.

According to an implementation, sensing agent 516-1 may obtain the received noise power measurement by modeling (simulating) a response of sensing receiver 502-1 and optionally a transmission channel. According to some implementations, sensing agent 516-1 may obtain the received noise power measurement by operating sensing receiver 502-1 in an engineering mode. In an implementation, sensing agent 516-1 may determine the received noise power measurement when sensing receiver 502-1 is operated in the engineering mode. In examples, sensing agent 516-1 may terminate an input port of sensing receiver 502-1 by coupling the input port to ground. Further, sensing agent 516-1 may detect only the noise of the sensing receiver processing.

In some implementations, calibration unit 524-1 may be configured to calibrate sensing receiver 502-1 in order to determine the received noise power measurement. In an example, calibration unit 524-1 may calibrate sensing receiver 502-1 during manufacturing of sensing receiver 502-1 or during commissioning of sensing receiver 502-1.

According to some implementations, noise power measurement unit 525-1 may be configured to determine the received noise power measurement during a standard operational mode of sensing receiver 502-1. In an example, the standard operational mode of sensing receiver 502-1 may be a normal operating mode of sensing receiver 502-1. In an implementation, noise power measurement unit 525-1 may perform the received noise power measurement during a period in which no signal is received. In an example, the period in which no signal is received may be associated with null carriers in the sensing transmission. In some examples, the period in which no signal is received may be associated with gaps between the sensing transmission and another transmission. In an example, measurement of the received noise power may be made in absence of any known signal. This allows the measurement of the combination of received noise power from the transmission channel and the received noise power from the sensing receiver processing. In an implementation, determination of the received noise power measurement during the standard operational mode of sensing receiver 502-1 may provide the most accurate measurement of the received noise power of sensing receiver 502-1.

In an implementation, noise power measurement unit 525-1 may perform the received noise power measurement during another measurement (for example, the sensing measurement performed by sensing receiver 502-1 on the sensing transmission). In examples, determination of the received noise power measurement may occur between receiving the sensing transmission and transferring the sensing measurement. In some implementations, noise power measurement unit 525-1 may determine a time of measurement of the received noise power measurement. In an implementation, noise power measurement unit 525-1 may perform the received noise power measurement based on the sensing transmission received from sensing transmitter 504-1. In an example, noise power measurement unit 525-1 may measure a time-frequency resource where no signal is received (i.e., null-carriers in the sensing transmission). In examples, the time-frequency resource may be a zero-power resource. In an example, the zero-power time-frequency resource may be in the frequency domain where there are null carriers in the sensing transmission. In some examples, the zero-power time-frequency resource may be in the time domain between active transmissions (for example, in a SIFS between the sensing trigger message and the sensing transmission). Further, in some examples, the zero-power time-frequency resource may be in the time domain and may be created or measured by configuring the sensing transmission with one or two long training field (LTF). In examples, sensing receiver 502-1 may be configured to oversample by a factor of two or four, respectively. In this case, the samples which do not align with a transmitted LTF may include only noise. In an implementation, when the received noise power measurement is performed between active transmissions, then the received noise power measurement may be made over a wide bandwidth. In some implementations, when the received noise power measurement is performed in the location of null carriers, then the received noise power measurement may be limited by the bandwidth of the null carriers.

According to an implementation, in examples, where measurements of the received noise power are made prior to performing the sensing measurement (for example, based on modeling the response of sensing receiver 502-1, based on calibrating sensing receiver 502-1, or based on operating sensing receiver 502-1 in the engineering mode), then the received noise power measurement may be stored prior to use. In an implementation, received noise power measurement may be stored in noise power measurement storage 523-1. In examples, since the received noise power measurement is both frequency-dependent and gain-dependent, the received noise power measurement may be stored in a form that accommodates these dependencies. In an example, noise power measurement storage 523-1 may store a plurality of received noise power measurements according to associated gains and associated frequencies.

In an implementation, sensing agent 516-1 may generate a data table including the plurality of received noise power measurements stored in noise power measurement storage 523-1 according to associated gains and associated frequencies. In an example, the data table may include the received noise power measurement obtained by sensing agent 516-1. In an implementation, the data table may be indexed by the tuple (index_{gain}, index_{frequency}). In this example, the gain refers to the total receiver gain that is made up of RF gain and baseband gain. The variables index_{gain} and index_{frequency} may be ranges of values. In an example, the variables index_{gain} and index_{frequency} may be expressed in terms of absolute values (for example, a frequency range such as 2.401 to 2.443 MHz, a gain range such as 0 to 5 dB, etc.). In some examples, the variables index_{gain} and index_{frequency} may be expressed in terms of a percentage (for example, a percentage of bandwidth range such as 0 to 5% of bandwidth range). In some examples, the variables index_{gain} and index_{frequency} may be expressed in terms of a percentage of gain range (such as 0 to 5% of gain range). In some examples, the variables index_{gain} and index_{frequency} may be expressed in terms of a normalized range between 0.0 and 1.0 (for example, a part of bandwidth range or of gain range such as 0 to 0.05 of bandwidth range or of gain range, where the maximum bandwidth or maximum gain is normalized to 1.0). In an example, a map may be used to translate the range into an index. For example, for frequency, the frequency range 2.401 to 2.443 MHz may map to frequency index 1, and the frequency range 2.446 to 2.495 MHz may map to frequency index 2. In some examples, for gain, the gain range 0 to 5 dB may map to gain index 1, and the gain range 5 to 10 dB may map to gain index 2. In some examples, the values that define the range may not be disclosed by sensing receiver 502-1, thereby allowing sensing receiver 502-1 to represent a relative value of gain without disclosing the absolute value of gain. In some examples, index_{frequency} may correspond to a subcarrier index which relates to OFDM subcarriers which make up the sensing transmission that the sensing measurement is performed on, i.e., the OFDM subcarriers for which CSI is calculated. For example, there may be 64 subcarriers in a 20 MHz sensing measurement and index_{frequency} may range from 0 to 63, and there may be a measurement of received noise power at each of the 64 subcarrier frequencies.

In some examples, the data table may be indexed by the tuple (index_{RF gain}, index_{baseband gain}, and index_{frequency}) where both components of the gain (i.e., RF gain and baseband gain) contribute to the indexing. In some examples, the data table may accommodate more measurements than can be made. For example, the data table may accommodate 20 discrete frequency ranges, however only 10 frequency ranges may be measured. In such scenario, a missing frequency range may be populated with an indicator that signals that the measurement is not available. In some cases, an algorithm may process measurements that are available to make an estimation of measurements that are missing (for example, by interpolating adjacent measurements or by making a regression-based fit to available measurements). In other examples, the size of the data table may be varied dynamically such that it is large enough only to accommodate measurements that can be made.

According to an implementation, where measurements of the received noise power are made in real-time or in parallel to the sensing measurement (for example, based on determining the received noise power measurement during the standard operational mode of sensing receiver 502-1), the value of received noise power measurement may be used immediately and may not be stored in noise power measurement storage 523-1. In some implementations, the value of received noise power measurement may be stored in the data table and may be used for the sensing measurement based on which the received noise power measurement was determined and for future sensing measurements for which the received noise power measurement may be applicable. In an example, the real-time measurement of received noise power may also be a function of RF gain, baseband gain, and frequency.

According to some implementations, the time of measurement of the received noise power measurement (as determined by sensing agent 516-1) may be stored along with the received noise power measurement in noise power measurement storage 523-1. In an example, timing synchronization function (TSF) time may be used as a time reference. According to an implementation, where the received noise power measurement is determined by either modeling, calibration of sensing receiver 502-1, or the use of the engineering mode, then a complete data table may be populated. In this case, received noise power values corresponding to each tuple may be modeled or measured, and stored in the data table. Further, where the received noise power is determined by a measurement during the standard operational mode, then only the value(s) of the received noise power measurement that are accommodated during the standard operational mode may be measured and stored.

According to an implementation, sensing agent 516 may be configured to generate time domain channel representation information (TD-CRI) of the sensing transmission. In examples, sensing agent 516-1 may transform the CSI to the time domain to generate a TD-CRI of the sensing transmission. In an implementation, sensing agent 516-1 may generate the TD-CRI using an inverse discrete Fourier transform (IDFT) or an inverse fast Fourier transform (IFFT). Further, sensing agent 516 may generate a time domain received noise power measurement. In examples, the received noise power measurement may be transformed into the time domain to form delay-dependent measurements of the received noise power. In examples, sensing agent 516-1 may generate the time domain received noise power measurement using IDFT or IFFT. In an example, where delay-dependent measurements of the received noise power are supported, the data table may be extended to accommodate storage of the delay-dependent measurements of the received noise power. The delay-dependent measurements of the received noise power may be stored and accessed in a similar fashion to received noise power measurement and the access tuple may be (index_{gain}, index_{delay}) or (index_{RF gain}, index_{baseband gain}, index_{delay}).

According to an implementation, association unit 526-1 may be configured associate the received noise power measurement with the sensing measurement. In some implementations, association unit 526-1 may associate the time of measurement of the received noise power measurement with the received noise power measurement. In an implementation, association unit 526-1 may associate the received noise power measurement with the sensing measurement based upon a gain or a frequency or both.

In an implementation, sensing agent 516-1 may transfer the sensing measurement and the received noise power measurement to a sensing initiator. In examples, the sensing initiator may be sensing transmitter 504-1. In some examples, the sensing initiator may be remote processing device 506. According to some implementations, sensing agent 516-1 may transfer the sensing measurement and the received noise power measurement to a sensing application. Upon receiving the sensing measurement and the received noise power measurement, the sensing application may perform a sensing algorithm to achieve a sensing goal according to the sensing measurement and the received noise power measurement. In examples, transfer of the sensing measurement and the received noise power measurement to the sensing application and transfer of the sensing measurement and the received noise power measurement to the sensing initiator may be performed by transferring the sensing measurement and the received noise power measurement to a second networking device acting as the sensing initiator and executing the sensing application. In this example, the second networking device may be remote processing device 506 executing sensing application 558. In some examples, the second networking device may be sensing transmitter 504-1 executing sensing application 538-1. Further, in some examples, transfer of the sensing measurement and the received noise power measurement to the sensing application may include transferring the sensing measurement and the received noise power measurement from a second networking device acting as the sensing initiator to a third networking device executing the sensing application. In this example, the second networking device may be sensing transmitter 504-1 and the third networking device may be remote processing device 506 executing sensing application 558.

According to an implementation, sensing agent 516-1 may transfer the sensing measurement and the received noise power measurement to the sensing initiator (for example, the second networking device acting as the sensing initiator) in a sensing measurement report (non-TB sensing). As described previously, in an example, the sensing initiator may be sensing transmitter 504-1. In some examples, the sensing initiator may be remote processing device 506.

In some implementations, the sensing initiator may calculate the sensing measurement, for example, following the reception of a sensing transmission which may be triggered by a Trigger frame (TB sensing). The sensing initiator may transfer the sensing measurement to the sensing application for further processing. In examples, where the sensing application runs on the sensing initiator, the sensing initiator may transfer the sensing measurement from a MAC layer to an application layer. In examples, where the sensing application runs on a device separate to the sensing initiator, the sensing initiator may transfer of the sensing measurement via a data frame. According to some implementations, the sensing measurement may be transferred to any device which may be supported by a MAC message and that may be addressed by either an association ID (AID) or a MAC address (depending on the type of message used).

In an implementation, where the measurement of the received noise power is made in parallel to the sensing measurement (for example, based on determining the received noise power measurement during the standard operational mode of sensing receiver 502-1), measurement of the received noise power may be made in the bandwidth of the sensing transmission. In this case, the measurement of the received noise power may be a single value which covers the complete frequency band of the sensing measurement or may be multiple values with each value representing the received noise power in a range of frequencies (as described previously). In some examples, multiple values of the received noise power measurement in a range of frequencies may be processed into a single value (for example, by taking the mean value of all received noise power measurements).

In an implementation, where a measurement of received noise power cannot be made in parallel to the sensing measurement, the level of automatic gain may be processed to determine the tuple value, index_{RF gain} and index_{baseband gain}, or the tuple value, index_{gain}. According to an implementation, sensing agent 516-1 may process the bandwidth of the sensing transmission to determine the tuple value(s), index_{frequency}. The bandwidth of the sensing transmission may be within a single value of index_{frequency} or it may cross (exceed) multiple index frequency. In examples, the tuple of (index_{RF gain}, index_{baseband gain}, index_{frequency}) or (index_{gain}, index_{frequency}) may be used by sensing receiver 502-1 to retrieve a value of received noise power from the data table. In examples, where there are multiple tuples corresponding to multiple ranges of frequencies, then a received noise power measurement corresponding to each tuple may be retrieved. In this case, further processing may reduce the multiple values of received noise power to a single value (for example, by taking the mean value of all received noise power measurements). In some implementations, if a sensing measurement is converted to the time domain representation of TD-CRI, then the same process as described, modified to the time domain, may determine the delay-dependent received noise power measurements.

In an implementation, sensing agent 516-1 may transmit the received noise power measurement associated with the sensing measurement to the sensing initiator or to another device along with the sensing measurement. As described previously, the sensing initiator (or another device) may transfer the sensing measurement, including the received noise power measurement to the sensing application. In some examples, the received noise power measurement may be combined with the received signal power information to compute the SNR (or SINR if the received noise power is measured along with the sensing measurement). Further, the SNR (SINR) may be transferred with the sensing measurement to the sensing application. In examples, a value of the automatic gain of sensing receiver 502-1 (which is represented by index_{RF gain}, index_{baseband gain} or index_{gain}) may also be transferred with the sensing measurement to indicate the level of automatic amplification which was required to condition the signal for processing. In an example, if the gain of the automatic gain elements is either in underflow or in overflow, then this condition may be signaled.

According to an implementation, sensing agent 516-1 may be configured to transfer the data table including the received noise power measurement of sensing receiver 502-1 stored according to associated gains and associated frequencies to the sensing initiator executing the sensing application, or another device (and potentially transferred to the sensing application where the sensing application does not run or execute on the sensing initiator). In this case, the data table may include a complete table of received noise power measurements as a function of all frequencies and all automatic gains. In some cases, the data table may be generated or populated when the received noise power measurement is determined by either modeling, calibration of sensing receiver 502-1, or the use of the engineering mode. As a result, the data table may be known in its complete form before, for example, a sensing setup phase. In an example, sensing agent 516-1 may transmit the data table to the sensing initiator or another device at the beginning of the sensing setup phase. The sensing initiator or another device may refer the data table by lookup rather than by sending a noise power (or SNR) measurement with every measurement. This may be a part of the sensing setup phase or a phase when the sensing initiator determines its set of sensing responders. In an example, the complete data table or parts of data table may be refreshed and updated at any time via a predetermined message. In examples, this method may remove the requirement to send a received noise power measurement with every sensing measurement.

According to an implementation, if a time of validity or a time of measurement is stored with the received noise power measurement, then the time of measurement may be used to determine if the received noise power measurement should be used. In examples, if it is determined that the received noise power measurement is too old or is not valid, then no received noise power measurement may be sent to the sensing initiator.

According to an implementation, the sensing measurement including the received noise power measurement may be transferred from sensing receiver 502-1 (acting as the sensing responder) to the sensing initiator or another device (and then transferred to the sensing application) by a sensing measurement report. In examples, the sensing measurement report may be implemented by a Sensing Measurement Report frame. In an example, the Sensing Measurement Report frame may include a Sensing Measurement Report element or a Sensing Measurement Report field which includes the sensing measurement and a Received Noise Power Report element or a Received Noise Power Report field which includes the received noise power measurement associated with the sensing measurement. The type of the sensing measurement and received noise power measurement may be described by a Sensing Measurement Report Type in the corresponding field and may be at least CSI or TD-CRI. In an example, the Sensing Measurement Report element as defined by P802.11bf/D0.2 may be adapted to carry the received noise power information.

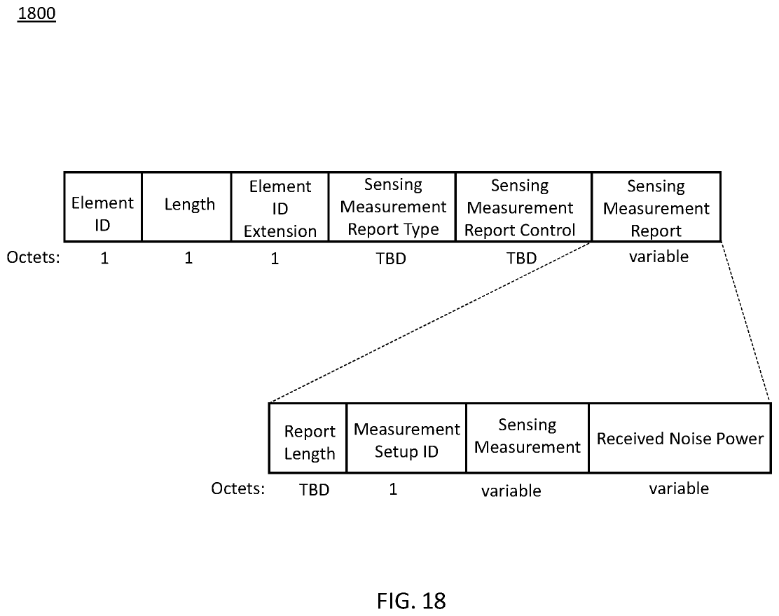

FIG. 18 illustrates example 1800 of Sensing Measurement Report element including a provision for received noise power measurement, according to some embodiment.

The Sensing Measurement Report element may include a single sensing measurement report. The Sensing Measurement Report element may be included in the Sensing Measurement Report frame. The Sensing Measurement Report Type field is set to a number that identifies the type of sensing measurement report and this field may signal the presence of a received noise power subelement. In an example, the values shown in Table 1 may be defined.

TABLE 1
New Trigger type subfield of the Common Info field

| Value | Sensing Measurement Type |
|---|---|
| 0 | CSI |
| 1 | TD-CRI |
| 2 | CSI and Received Noise Power |
| 3 | TD-CRI and Received Noise Power |
| 4-255 | Reserved |

In examples, if the Sensing Measurement Report Type is “CSI and Received Noise Power” (i.e., Value=2), then the Sensing Measurement subelement may include a CSI measurement report and the Received Noise Power subelement may include a received noise power measurement report in the frequency domain. Further, in examples, if the Sensing Measurement Report Type is “TD-CRI and Received Noise Power” (i.e., Value=3), then the Sensing Measurement subelement may include a TD-CRI measurement report and the Received Noise Power subelement may include a received noise power measurement report in the time domain.

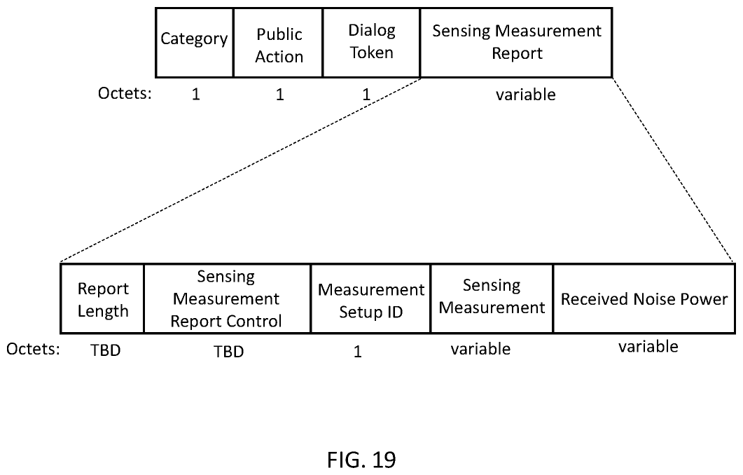

FIG. 19 illustrates example 1900 of a Sensing Measurement Report frame implemented as a field and including a provision for received noise power measurement, according to some embodiments.

In this example, the Sensing Measurement Report Type may be carried as part of Sensing Measurement Report Control and may be encoded as described in Table 1. The Received Noise Power subelement/subfield may include the value of received noise power measurement and other parameter as described in Table 2.

TABLE 2
Example of a Noise Measurement subelement/subfield

| Name | Type | Valid Range | Description |
|---|---|---|---|
| FrequencyIndex1 or | Unsigned Integer | 0 . . . 1023 | Index of the |
| DelayIndex1 | | | frequency at which |
| | | | the corresponding |
| | | | received noise |
| | | | power is measured |
| ReceivedNoisePower1 | Signed Integer | −128 . . . 127 | Received noise |
| | | | power in dBm. In |
| | | | an example, an |
| | | | offset may be |
| | | | applied to the value |
| | | | to offset the range |
| | | | to accommodate |
| | | | values which have a |
| | | | non-zero mean |
| | | | (e.g., from −160 to |
| | | | 95 with an offset |
| | | | of −32 applied). |
| ReceivedRFGain1 | Signed Integer | −20 . . . 20 | OPTIONAL: RF |
| | | | gain in dB at the |
| | | | frequency index. |
| | | | In an |
| | | | implementation, the |
| | | | value of RF gain |
| | | | may be a |
| | | | dimensionless value |
| | | | that represents a |
| | | | relative gain (e.g., a |
| | | | value of 5 indicates |
| | | | a higher gain than |
| | | | 4, but the absolute |
| | | | value of gain is not |
| | | | represented). |
| ReceivedBasebandGain1 | Signed Integer | −20 . . . 20 | OPTIONAL: |
| | | | Baseband gain in |
| | | | dB at the frequency |
| | | | index. |
| | | | In an |
| | | | implementation, the |
| | | | value of RF gain |
| | | | may be a |
| | | | dimensionless value |
| | | | that represents a |
| | | | relative gain (e.g., a |
| | | | value of 5 indicates |
| | | | a higher gain than |
| | | | 4, but the absolute |
| | | | value of gain is not |
| | | | represented). |
| . | . | . | . |
| . | . | . | . |
| . | . | . | . |
| FrequencyIndexn or | Unsigned Integer | 0 . . . 1023 | Index of the |
| DelayIndexn | | | frequency at which |
| | | | the corresponding |
| | | | received noise |
| | | | power is measured |
| ReceivedNoisePowern | Signed Integer | −128 . . . 127 | Received noise |
| | | | power in dBm. In |
| | | | an example, an |
| | | | offset may be |
| | | | applied to the value |
| | | | to offset the range |
| | | | to accommodate |
| | | | values which have a |
| | | | non-zero mean |
| | | | (e.g., from −160 to |
| | | | 95). |
| ReceivedRFGainn | Signed Integer | −20 . . . 20 | OPTIONAL: RF |
| | | | gain in dB at the |
| | | | frequency index. |
| | | | In an |
| | | | implementation, the |
| | | | value of RF gain |
| | | | may be a |
| | | | dimensionless value |
| | | | that represents a |
| | | | relative gain (e.g., a |
| | | | value of 5 indicates |
| | | | a higher gain than |
| | | | 4, but the absolute |
| | | | value of gain is not |
| | | | represented). |
| ReceivedBasebandGainn | Signed Integer | −20 . . . 20 | OPTIONAL: |
| | | | Baseband gain in |
| | | | dB at the frequency |
| | | | index. |
| | | | In an |
| | | | implementation, the |
| | | | value of RF gain |
| | | | may be a |
| | | | dimensionless value |
| | | | that represents a |
| | | | relative gain (e.g., a |
| | | | value of 5 indicates |
| | | | a higher gain than |
| | | | 4, but the absolute |
| | | | value of gain is not |
| | | | represented). |

In the example of Table 2, FrequencyIndex1 may refer to a frequency-domain received noise measurement and DelayIndex1 may refer to a time-domain received noise measurements, and this is in turn dependent on the received noise power measurement that is transferred by the element/field. In examples, the valid range “0 . . . 1023” may correspond to the maximum number of subcarriers in a single sensing measurement.

In an example, Sensing Measurement Report Control may indicate the number of frequencies at which a received noise power measurement is available (for example, n in Table 2). This may be an unsigned integer value and may be in the range of 0 . . . 1023. Sensing Measurement Report Control may also indicate whether ReceivedRFGain and ReceivedBasebandGain are included in the table. This may be with two Boolean flags encoded by two bits.

In the case of a CSI measurement, there may be a measurement of received noise power for each CSI measurement pulse (for example, made in a zero-power time-frequency resources) or of received SNR/SINR. In the case of a TD-CRI measurement, there may be a measurement of received noise power for each TD-CRI measurement pulse (for example, formed by a transformation of a frequency-dependent received noise power measurement) or of received SNR/SINR (related to the formation of a frequency-dependent received noise power measurement). In an example, where a one-to-one mapping exists, the received noise power measurements may be sequenced in the same manner for the CSI or TD-CRI measurement and the received noise power measurement. In some examples, there may be fewer received noise power measurements transferred than CSI or TD-CRI measurements pulse, and each transferred value of received noise power may be associated with multiple CSI or TD-CRI measurement pulses. In an example, there may be a single value of received noise power transferred and this single value may be associated with all CSI or TD-CRI measurement pulses.

Where there are fewer received noise power measurements than CSI or TD-CRI measurement pulses, then sensing receiver 502-1 may inform the sensing initiator or another device of the frequency or delays at which a corresponding received noise power measurement is valid. In an example, sensing receiver 502-1 may inform the sensing initiator or another device of the mapping as part of the sensing measurement report. In examples, the mapping may be present in every sensing measurement report. In some examples, the mapping may be present for a first sensing measurement report which relates to the Measurement Setup ID and this mapping may be used by the sensing initiator or another device for all subsequent sensing measurement reports corresponding to the same Measurement Setup ID. In examples, the mapping may be transferred as part of the Received Noise Power subelement/subfield or may be transferred as part of Sensing Measurement Report Control.

In an example, the low frequency of a frequency band over which the received noise power measurement is transferred between sensing receiver 502-1 and sensing initiator or another device is described in Table 3 provided below.

TABLE 3
Example of a description of a mapping of frequency/delay
bands to a frequency/delay index

| Name | Type | Valid Range | Description |
|---|---|---|---|
| BandLow1 or | Unsigned Integer | −512 . . . 511 | Number of the |
| DelayLow1 | | | subcarrier in the |
| | | | bandwidth of the |
| | | | sensing |
| | | | measurement at |
| | | | which the received |
| | | | noise power is |
| | | | measured. |
| . | . | . | . |
| . | . | . | . |
| . | . | . | . |
| BandLown or | Unsigned Integer | −512 . . . 511 | Number of the |
| DelayLown | | | subcarrier in the |
| | | | bandwidth of the |
| | | | sensing |
| | | | measurement at |
| | | | which the received |
| | | | noise power is |
| | | | measured. |

In the example of Table 3, BandLow1 refers to a frequency-domain received noise measurement and DelayLow1 refers to a time-domain received noise measurements and this is in turn dependent on the received noise power that is transferred by the element/field.

In an example, where a complete data table is transferred between sensing receiver 502-1 and the sensing initiator or another device (for example, during a sensing session setup exchange), then a dedicated message may be used. In an example, the format described by Table 2 may be used to populate the message and the data table may be repeated for each value of RF gain and baseband gain that is to be transferred. On receiving the data table, the sensing initiator or another device may build a copy of the data table that may be used to determine the received noise power measurement of sensing receiver 502-1 when this information is not shared as part of the sensing measurement report.

Although the Sensing Measurement Report element (or field) and the Received Noise Power Report element (or field) are described separately, in an implementation, the sensing measurement and the received noise power measurement may be combined into a single element (e.g., a Sensing Measurement Report element/field). As described previously, SNR/SINR may be transferred in place of the received noise power measurement. In examples, where the sensing measurement including the received noise power measurement or SNR/SINR is transferred from the sensing initiator or another device to the sensing application, then a data frame may be used.

According to some embodiments, the sensing initiator may transmit a sensing transmission to sensing receiver 502-1. Upon receiving the sensing transmission, sensing receiver 502-1 may perform a sensing measurement based on the sensing transmission. Further, sensing receiver 502-1 may transmit the sensing measurement to the sensing initiator. In examples, the sensing initiator may receive the sensing measurement from sensing receiver 502-1. Subsequently, the sensing initiator may obtain a received noise power measurement associated with sensing receiver 502-1. In an implementation, the sensing initiator may transfer the sensing measurement and the received noise power measurement to a sensing application. In examples, the sensing initiator may be sensing transmitter 504-1. In an example, determination unit 544-1 of sensing transmitter 504-1 may obtain the received noise power measurement associated with sensing receiver 502-1 by accessing the received noise power measurement from noise power measurement storage 543-1. In an example, the data table including the received noise power measurement of sensing receiver 502-1 may be stored in noise power measurement storage 543-1 according to associated gain and associated frequency. In an example, determination unit 544-1 may refer the data table by lookup to obtain the received noise power measurement associated with sensing receiver 502-1. In examples, sensing transmitter 504-1 may receive the data table from sensing receiver 502-1 at the beginning of a sensing setup phase. Further, in an example, the sensing application may be sensing application 538-1 that executes on sensing transmitter 504-1. In some examples, the sensing application may be sensing application 558 that executes on remote processing device 506. According to an implementation, the sensing application may associate the received noise power measurement with the sensing measurement. Further, the sensing application may perform a sensing algorithm to achieve a sensing goal according to the sensing measurement and the received noise power measurement.

FIG. 20 depicts flowchart 2000 for associating a received noise power measurement with a sensing measurement, and transferring the sensing measurement and the received noise power measurement to a sensing initiator, according to some embodiments. In an implementation, flowchart 2000 may be carried out by a first networking device configured to operate as a sensing responder (for example, sensing receiver 502-1). In examples, the sensing initiator may be sensing transmitter 504-1. In some examples, the sensing initiator may be remote processing device 506.

In a brief overview of an implementation of flowchart 2000, at step 2002, a sensing transmission transmitted from a sensing transmitter (for example, sensing transmitter 504-1) may be received. At step 2004, a sensing measurement may be performed on the sensing transmission. At step 2006, a received noise power measurement may be obtained. At step 2008, the received noise power measurement may be associated with the sensing measurement. At step 2010, the sensing measurement and the received noise power measurement may be transferred to a sensing initiator (for example, remote processing device 506).

Step 2002 includes receiving a sensing transmission transmitted from a sensing transmitter. According to an implementation, sensing receiver 502-1 may be configured to receive the sensing transmission transmitted from sensing transmitter 504-1. In some implementations, transmission of the sensing transmission may be performed responsive to an action of a sensing initiator.

Step 2004 includes performing a sensing measurement on the sensing transmission. According to an implementation, sensing receiver 502-1 may be configured to perform the sensing measurement on the sensing transmission.

Step 2006 includes obtaining a received noise power measurement. According to an implementation, sensing receiver 502-1 may be configured to obtain the received noise power measurement. In an implementation, obtaining the received noise power measurement includes accessing the received noise power measurement from a data storage (for example, noise power measurement storage 523-1). Further, in an implementation, accessing the received noise power measurement from the data storage includes accessing the received noise power measurement according to a gain and a frequency. In some implementations, obtaining the received noise power measurement includes modeling a response of the sensing responder and optionally a transmission channel. In an example, the sensing responder may be sensing receiver 502-1. In some implementations, obtaining the received noise power measurement includes calibrating the sensing responder (for example, sensing receiver 502-1). According to some embodiments, obtaining the received noise power measurement includes operating the sensing responder (for example, sensing receiver 502-1) in an engineering mode, and determining the received noise power measurement in the engineering mode. In some embodiments, obtaining the received noise power measurement includes determining the received noise power measurement during a standard operational mode of the sensing responder (for example, sensing receiver 502-1), where determining the received noise power measurement includes performing the received noise power measurement during a period in which no signal is received. In examples, the period in which no signal is received is associated with null carriers in the sensing transmission. In some examples, the period in which no signal is received is associated with gaps between the sensing transmission and another transmission. In an implementation, determining the received noise power measurement occurs between receiving the sensing transmission and transferring the sensing measurement and the received noise power measurement. According to an implementation, sensing receiver 502-1 may be configured to determine a time of measurement and associate the time of measurement with the received noise power measurement.

Step 2008 includes associating the received noise power measurement with the sensing measurement. According to an implementation, sensing receiver 502-1 may be configured to associate the received noise power measurement with the sensing measurement. In examples, associating the received noise power measurement with the sensing measurement may be performed based upon a gain or a frequency or both.

Step 2010 includes transferring the sensing measurement and the received noise power measurement to a sensing initiator. According to an implementation, sensing receiver 502-1 may be configured to transfer the sensing measurement and the received noise power measurement to the sensing initiator. In examples, transferring the sensing measurement and the received noise power measurement to the sensing initiator is performed by transferring the sensing measurement and the received noise power measurement to a second networking device acting as the sensing initiator and executing the sensing application. In some examples, transferring the sensing measurement and the received noise power measurement to the sensing initiator includes transmitting the sensing measurement and the received noise power measurement to a second networking device acting as the sensing initiator in a sensing measurement report. In an example, the second networking device may be remote processing device 506 executing sensing application 558. In some examples, the second networking device may be sensing transmitter 504-1 executing sensing application 538-1.

FIG. 21A and FIG. 21B depict flowchart 2100 for associating a received noise power measurement with a sensing measurement, and transferring the sensing measurement and the received noise power measurement to a sensing application for achieving a sensing goal according to the sensing measurement and the received noise power measurement, according to some embodiments. In an implementation, flowchart 2100 may be carried out by a first networking device configured to operate as a sensing responder (for example, sensing receiver 502-1).

In a brief overview of an implementation of flowchart 2100, at step 2102, a sensing transmission transmitted from a sensing transmitter (for example, sensing transmitter 504-1) may be received. At step 2104, time domain channel representation information (TD-CRI) of the sensing transmission may be generated. At step 2106, a sensing measurement may be performed on the sensing transmission. At step 2108, a received noise power measurement may be obtained. At step 2110, a time domain received noise power measurement may be generated. At step 2112, the received noise power measurement may be associated with the sensing measurement. At step 2114, the sensing measurement and the received noise power measurement may be transferred to a sensing initiator.

Step 2102 includes receiving a sensing transmission transmitted from a sensing transmitter. According to an implementation, sensing receiver 502-1 may be configured to receive a sensing transmission transmitted from sensing transmitter 504-1. In some implementations, transmission of the sensing transmission may be performed responsive to an action of a sensing initiator.

Step 2104 includes generating time domain channel representation information (TD-CRI) of the sensing transmission. According to an implementation, sensing receiver 502-1 may be configured to generate TD-CRI of the sensing transmission.

Step 2106 includes performing a sensing measurement on the sensing transmission. According to an implementation, sensing receiver 502-1 may be configured to perform the sensing measurement on the sensing transmission.

Step 2108 includes obtaining a received noise power measurement. According to an implementation, sensing receiver 502-1 may be configured to obtain the received noise power measurement. In an implementation, obtaining the received noise power measurement includes accessing the received noise power measurement from a data storage (for example, noise power measurement storage 523-1). Further, in an implementation, accessing the received noise power measurement from the data storage includes accessing the received noise power measurement according to a gain and a frequency. In some implementations, obtaining the received noise power measurement includes modeling a response of the sensing responder (for example, sensing receiver 502-1) and optionally a transmission channel. In some implementations, obtaining the received noise power measurement includes calibrating the sensing responder (for example, sensing receiver 502-1). According to some embodiments, obtaining the received noise power measurement includes operating the sensing responder (for example, sensing receiver 502-1) in an engineering mode, and determining the received noise power measurement in the engineering mode. In some embodiments, obtaining the received noise power measurement includes determining the received noise power measurement during a standard operational mode of the sensing responder (for example, sensing receiver 502-1), where determining the received noise power measurement includes performing the received noise power measurement during a period in which no signal is received. In examples, the period in which no signal is received is associated with null carriers in the sensing transmission. In some examples, the period in which no signal is received is associated with gaps between the sensing transmission and another transmission. In an implementation, determining the received noise power measurement occurs between receiving the sensing transmission and transferring the sensing measurement and the received noise power measurement. According to an implementation, sensing receiver 502-1 may be configured to determine a time of measurement and associate the time of measurement with the received noise power measurement.

Step 2110 includes generating a time domain received noise power measurement. According to an implementation, sensing receiver 502-1 may be configured to generate the time domain received noise power measurement.

Step 2112 associating the received noise power measurement with the sensing measurement. According to an implementation, sensing receiver 502-1 may be configured to associate the received noise power measurement with the sensing measurement. In examples, associating the received noise power measurement with the sensing measurement may be performed based upon a gain or a frequency or both.

Step 2114 includes transferring the sensing measurement and the received noise power measurement to a sensing application for achieving a sensing goal according to the sensing measurement and the received noise power measurement. According to an implementation, sensing receiver 502-1 may be configured to transfer the sensing measurement and the received noise power measurement to a sensing application for achieving a sensing goal according to the sensing measurement and the received noise power measurement. In an implementation, upon receiving the sensing measurement and the received noise power measurement, the sensing application may perform the sensing algorithm to achieve the sensing goal according to the sensing measurement and the received noise power measurement. In an example, transferring the sensing measurement and the received noise power measurement to the sensing application is performed by transferring the sensing measurement and the received noise power measurement to a second networking device acting as a sensing initiator and executing the sensing application. In this example, the second networking device may be sensing transmitter 504-1 executing sensing application 538-1. In some examples, transferring the sensing measurement and the received noise power measurement to the sensing application includes transferring the sensing measurement and the received noise power measurement from a second networking device acting as the sensing initiator to a third networking device executing the sensing application. In this example, the second networking device may be sensing transmitter 504-1 and the third networking device may be remote processing device 506 executing sensing application 558.

FIG. 22 depicts flowchart 2200 for generating a data table including a received noise power measurement, and transferring a sensing measurement and the data table to a sensing initiator, according to some embodiments. In an implementation, flowchart 2200 may be carried out by a first networking device configured to operate as a sensing responder (for example, sensing receiver 502-1).

In a brief overview of an implementation of flowchart 2200, at step 2202, a sensing transmission transmitted from a sensing transmitter (for example, sensing transmitter 504-1) may be received. At step 2204, a sensing measurement may be performed on the sensing transmission. At step 2206, a received noise power measurement may be obtained. At step 2208, a data table including a plurality of received noise power measurements stored according to associated gains and associated frequencies may be generated. In an example, the data table may include the received noise power measurement. At step 2210, the sensing measurement and the data table may be transferred to a sensing initiator.

Step 2202 includes receiving a sensing transmission transmitted from a sensing transmitter. According to an implementation, sensing receiver 502-1 may be configured to receive the sensing transmission transmitted from sensing transmitter 504-1. In some implementations, transmission of the sensing transmission may be performed responsive to an action of a sensing initiator.

Step 2204 includes performing a sensing measurement on the sensing transmission. According to an implementation, sensing receiver 502-1 may be configured to perform the sensing measurement on the sensing transmission.

Step 2206 includes obtaining a received noise power measurement. According to an implementation, sensing receiver 502-1 may be configured to obtain the received noise power measurement. In an implementation, obtaining the received noise power measurement includes accessing the received noise power measurement from a data storage (for example, noise power measurement storage 523-1). Further, in an implementation, accessing the received noise power measurement from the data storage includes accessing the received noise power measurement according to a gain and a frequency. In some implementations, obtaining the received noise power measurement includes modeling a response of the sensing responder and optionally a transmission channel. In an example, the sensing responder may be sensing receiver 502-1. In some implementations, obtaining the received noise power measurement includes calibrating the sensing responder (for example, sensing receiver 502-1). According to some embodiments, obtaining the received noise power measurement includes operating the sensing responder (for example, sensing receiver 502-1) in an engineering mode, and determining the received noise power measurement in the engineering mode. In some embodiments, obtaining the received noise power measurement includes determining the received noise power measurement during a standard operational mode of the sensing responder (for example, sensing receiver 502-1), where determining the received noise power measurement includes performing the received noise power measurement during a period in which no signal is received. In examples, the period in which no signal is received is associated with null carriers in the sensing transmission. In some examples, the period in which no signal is received is associated with gaps between the sensing transmission and another transmission. In an implementation, determining the received noise power measurement occurs between receiving the sensing transmission and transferring the sensing measurement and the received noise power measurement. According to an implementation, sensing receiver 502-1 may be configured to determine a time of measurement and associate the time of measurement with the received noise power measurement.

Step 2208 includes generating a data table including a plurality of received noise power measurements stored according to associated gains and associated frequencies, the data table including the received noise power measurement. According to an implementation, sensing receiver 502-1 may be configured to generate the data table including the plurality of received noise power measurements stored according to associated gains and associated frequencies. In examples, the data table includes the received noise power measurement.

Step 2210 includes transferring the sensing measurement and the data table to a sensing initiator. According to an implementation, sensing receiver 502-1 may be configured to transfer the sensing measurement and the data table to a second networking device configured to execute a sensing application. In examples, the second networking device may be remote processing device 506 executing sensing application 558. In some examples, the second networking device may be sensing transmitter 504-1 executing sensing application 538-1.

FIG. 23 depicts flowchart 2300 for obtaining a sensing measurement and a received noise power measurement associated with a sensing responder, and transferring the sensing measurement and the received noise power measurement to a sensing application, according to some embodiments. In an implementation, flowchart 2300 may be carried out by a networking device configured to operate as a sensing initiator (for example, sensing transmitter 504-1).

In a brief overview of an implementation of flowchart 2300, at step 2302, a sensing transmission may be transmitted to a sensing responder. At step 2304, a sensing measurement based on the sensing transmission may be received. At step 2306, a received noise power measurement associated with the sensing responder may be obtained. At step 2308, the sensing measurement and the received noise power measurement may be transferred to a sensing application.

Step 2302 includes transmitting a sensing transmission to a sensing responder. According to an implementation, sensing transmitter 504-1 may be configured to transmit the sensing transmission to the sensing responder. In an example, the sensing responder may be sensing receiver 502-1.

Step 2304 includes receiving a sensing measurement based on the sensing transmission. According to an implementation, sensing transmitter 504-1 may be configured to receive the sensing measurement based on the sensing transmission. In an implementation, upon receiving the sensing transmission, the sensing responder may be configured to perform a sensing measurement on the sensing transmission. In an example, the sensing responder may be configured to transmit the sensing measurement to sensing transmitter 504-1.

Step 2306 includes obtaining a received noise power measurement associated with the sensing responder. According to an implementation, sensing transmitter 504-1 may be configured to obtain the received noise power measurement associated with the sensing responder. In examples, sensing transmitter 504-1 may be configured to obtain a data table including a plurality of received noise power measurements stored according to associated gains and associated frequencies from the sensing responder. In an example, the data table may include the received noise power measurement.

Step 2308 includes transferring the sensing measurement and the received noise power measurement to a sensing application. According to an implementation, sensing transmitter 504-1 may be configured to transfer the sensing measurement and the received noise power measurement to a sensing application. In examples, the sensing application may be executed by a remote device, such as remote processing device 506, where the sensing application may be sensing application 558. In this example, sensing transmitter 504-1 may transfer the sensing measurement and the received noise power measurement to sensing application 558 via a data frame. In some examples, the sensing application may run on sensing transmitter 504-1 (sensing initiator) itself. In this example, the sensing application may be sensing application 538-1. In an example, sensing transmitter 504-1 may transfer the sensing measurement and the received noise power measurement to sensing application 538-1 from a MAC layer to an application layer.

Additional embodiments of the presently disclosed technology includes the following.
Embodiment 1 is a method for Wi-Fi sensing carried out by a networking device configured to operate as a sensing responder and including at least one processor configured to execute instructions, the method comprising: receiving, by the sensing responder, a sensing transmission transmitted from a sensing transmitter; performing, by the sensing responder, a sensing measurement on the sensing transmission; obtaining, by the sensing responder, a received noise power measurement; associating, by the sensing responder, the received noise power measurement with the sensing measurement; and transferring, by the sensing responder, the sensing measurement and the received noise power measurement to a sensing initiator.
Embodiment 2 is the method of embodiment 1, wherein obtaining the received noise power measurement includes accessing the received noise power measurement from data storage.
Embodiment 3 is method of embodiment 2, wherein accessing the received noise power measurement from data storage includes accessing the received noise power measurement according to a gain and a frequency.
Embodiment 4 is the method of any of embodiments 1-3, wherein obtaining the received noise power measurement includes modeling a response of the sensing responder and optionally a transmission channel.
Embodiment 5 is the method of any of embodiments 1-4, wherein obtaining the received noise power measurement includes calibrating the sensing responder.
Embodiment 6 is the method of any of embodiments 1-5, wherein obtaining the received noise power measurement includes: operating the sensing responder in an engineering mode; and determining the received noise power measurement in the engineering mode.
Embodiment 7 is the method of any of embodiments 1-6, wherein obtaining the received noise power measurement includes determining the received noise power measurement during a standard operational mode of the sensing responder.
Embodiment 8 is the method of embodiment 7, wherein determining the received noise power measurement includes performing the received noise power measurement during a period in which no signal is received.
Embodiment 9 is the method of embodiment 8, wherein the period in which no signal is received is associated with null carriers in the sensing transmission.
Embodiment 10 is the method of any of embodiments 7-9, wherein the period in which no signal is received is associated with gaps between the sensing transmission and another transmission.
Embodiment 11 is the method of any of embodiments 7-10, wherein determining the received noise power measurement occurs between receiving the sensing transmission and transferring the sensing measurement and the received noise power measurement.
Embodiment 12 is the method of embodiment 11, further comprising determining a time of measurement and associating the time of measurement with the received noise power measurement.
Embodiment 13 is the method of any of embodiments 1-12, further comprising: generating time domain channel representation information (TD-CRI) of the sensing transmission; and generating a time domain received noise power measurement.
Embodiment 14 is the method of any of embodiments 1-13, further comprising: transferring the sensing measurement and the received noise power measurement to a sensing application; and performing, by the sensing application, a sensing algorithm to achieve a sensing goal according to the sensing measurement and the received noise power measurement.
Embodiment 15 is the method of embodiment 14, wherein transferring the sensing measurement and the received noise power measurement to the sensing application and transferring the sensing measurement and the received noise power measurement to the sensing initiator are performed by transferring the sensing measurement and the received noise power measurement to a second networking device acting as the sensing initiator and executing the sensing application.
Embodiment 16 is the method of any of embodiments 14-15, wherein transferring the sensing measurement and the received noise power measurement to the sensing application includes transferring the sensing measurement and the received noise power measurement from a second networking device acting as the sensing initiator to a third networking device executing the sensing application.
Embodiment 17 is the method of any of embodiments 1-16, wherein transferring the sensing measurement and the received noise power measurement to the sensing initiator includes transmitting the sensing measurement and the received noise power measurement in a sensing measurement report to a second networking device acting as the sensing initiator.
Embodiment 18 is the method of any of embodiments 1-17, further comprising: generating a data table including a plurality of received noise power measurements stored according to associated gains and associated frequencies, the data table including the received noise power measurement.
Embodiment 19 is the method of embodiment 18, further comprising: transferring the data table to a second networking device configured to execute a sensing application.
Embodiment 20 is the method of any of embodiments 1-19, wherein the sensing responder is a sensing receiver.
Embodiment 21 is the method of any of embodiments 1-20, wherein transmission of the sensing transmission is performed responsive to an action of the sensing initiator.
Embodiment 22 is the method of any of embodiments 1-21, wherein associating the received noise power measurement with the sensing measurement is performed based upon a gain or a frequency or both.
Embodiment 23 is a method for Wi-Fi sensing carried out by a networking device configured to operate as a sensing initiator and including at least one processor configured to execute instructions, the method comprising: transmitting, by the sensing initiator, a sensing transmission to a sensing responder; receiving, by the sensing initiator, a sensing measurement based on the sensing transmission; obtaining, by the sensing initiator, a received noise power measurement associated with the sensing responder; and transferring, by the sensing initiator, the sensing measurement and the received noise power measurement to a sensing application.
Embodiment 24 is a system for Wi-Fi sensing comprising a networking device configured to operate as a sensing responder and including at least one processor configured to execute instructions, the system being configured for: receiving sensing transmission transmitted from a sensing transmitter; performing a sensing measurement on the sensing transmission; obtaining a received noise power measurement; associating the received noise power measurement with the sensing measurement; and transferring the sensing measurement and the received noise power measurement to a sensing initiator.
Embodiment 25 is the system of embodiment 24, wherein obtaining the received noise power measurement includes accessing the received noise power measurement from data storage.
Embodiment 26 is the system of any of embodiments 24-25, wherein accessing the received noise power measurement from data storage includes accessing the received noise power measurement according to a gain and a frequency.
Embodiment 27 is the system of any of embodiments 24-26, wherein obtaining the received noise power measurement includes modeling a response of the sensing responder and optionally a transmission channel.
Embodiment 28 is the system of any of embodiments 24-27, wherein obtaining the received noise power measurement includes calibrating the sensing responder.
Embodiment 29 is the system of any of embodiments 24-28, wherein obtaining the received noise power measurement includes: operating the sensing responder in an engineering mode; and determining the received noise power measurement in the engineering mode.
Embodiment 30 is the system of any of embodiments 24-29, wherein obtaining the received noise power measurement includes determining the received noise power measurement during a standard operational mode of the sensing responder.
Embodiment 31 is the system of any of embodiments 24-30, wherein determining the received noise power measurement includes performing the received noise power measurement during a period in which no signal is received.
Embodiment 32 is the system of any of embodiments 24-31, wherein the period in which no signal is received is associated with null carriers in the sensing transmission.
Embodiment 33 is the system of any of embodiments 24-32, wherein the period in which no signal is received is associated with gaps between the sensing transmission and another transmission.
Embodiment 34 is the system of any of embodiments 30-33, wherein determining the received noise power measurement occurs between receiving the sensing transmission and transferring the sensing measurement and the received noise power measurement.
Embodiment 35 is the system of embodiment 34, wherein the system is further configured for determining a time of measurement and associating the time of measurement with the received noise power measurement.
Embodiment 36 is the system of any of embodiments 24-35, further comprising: generating time domain channel representation information (TD-CRI) of the sensing transmission; and generating a time domain received noise power measurement.
Embodiment 37 is the system of any of embodiments 24-36, wherein the system is further configured for: transferring the sensing measurement and the received noise power measurement to a sensing application; and performing, by the sensing application, a sensing algorithm to achieve a sensing goal according to the sensing measurement and the received noise power measurement.
Embodiment 38 is the system of embodiment 37, wherein transferring the sensing measurement and the received noise power measurement to the sensing application and transferring the sensing measurement and the received noise power measurement to the sensing initiator are performed by transferring the sensing measurement and the received noise power measurement to a second networking device acting as the sensing initiator and executing the sensing application.
Embodiment 39 is the system of any of embodiments 37-38, wherein transferring the sensing measurement and the received noise power measurement to the sensing application includes transferring the sensing measurement and the received noise power measurement from a second networking device acting as the sensing initiator to a third networking device executing the sensing application.
Embodiment 40 is the system of any of embodiments 24-39, wherein transferring the sensing measurement and the received noise power measurement to the sensing initiator includes transmitting the sensing measurement and the received noise power measurement to a second networking device acting as the sensing initiator in a sensing measurement report.
Embodiment 41 is the system of any of embodiments 24-40, wherein the system is further configured for: generating a data table including a plurality of received noise power measurements stored according to associated gains and associated frequencies, the data table including the received noise power measurement.
Embodiment 42 is the system of embodiment 41, further comprising: transferring the data table to a second networking device configured to execute a sensing application.
Embodiment 43 is the system of any of embodiments 24-42, wherein the sensing responder is a sensing receiver.
Embodiment 44 is the system of any of embodiments 24-43, wherein transmission of the sensing transmission is performed responsive to an action of the sensing initiator.
Embodiment 45 is the system of any of embodiments 24-44, wherein associating the received noise power measurement with the sensing measurement is performed based upon a gain or a frequency or both.
Embodiment 46 is a system for Wi-Fi sensing comprising a networking device configured to operate as a sensing initiator and including at least one processor configured to execute instructions, the system being configured for: transmitting, by the sensing initiator, a sensing transmission to a sensing responder; receiving, by the sensing initiator, a sensing measurement based on the sensing transmission; obtaining, by the sensing initiator, a received noise power measurement associated with the sensing responder; and transferring, by the sensing initiator, the sensing measurement and the received noise power measurement to a sensing application.

While various embodiments of the methods and systems have been described, these embodiments are illustrative and in no way limit the scope of the described methods or systems. Those having skill in the relevant art can effect changes to form and details of the described methods and systems without departing from the broadest scope of the described methods and systems. Thus, the scope of the methods and systems described herein should not be limited by any of the illustrative embodiments and should be defined in accordance with the accompanying claims and their equivalents.

1. A method for Wi-Fi sensing carried out by a networking device configured to operate as a sensing responder and including at least one processor configured to execute instructions, the method comprising:
receiving, by the sensing responder, a sensing transmission transmitted from a sensing initiator;
performing, by the sensing responder, a sensing measurement on the sensing transmission;
obtaining, by the sensing responder, a received noise power measurement;
associating, by the sensing responder, the received noise power measurement with the sensing measurement; and
transferring, by the sensing responder, the sensing measurement and the received noise power measurement to a sensing initiator.

2. The method of claim 1, wherein obtaining the received noise power measurement includes accessing the received noise power measurement from data storage.

3-6. (canceled)

7. The method of claim 1, wherein obtaining the received noise power measurement includes determining the received noise power measurement during a standard operational mode of the sensing responder.

8. The method of claim 7, wherein determining the received noise power measurement includes performing the received noise power measurement during a period in which no signal is received.

9-12. (canceled)

13. The method of claim 1, further comprising:
generating time domain channel representation information (TD-CRI) of the sensing transmission; and
generating a time domain received noise power measurement.

14. The method of claim 1, further comprising:
transferring the sensing measurement and the received noise power measurement to a sensing application; and
performing, by the sensing application, a sensing algorithm to achieve a sensing goal according to the sensing measurement and the received noise power measurement.

15. The method of claim 14, wherein transferring the sensing measurement and the received noise power measurement to the sensing application and transferring the sensing measurement and the received noise power measurement to the sensing initiator are performed by transferring the sensing measurement and the received noise power measurement to a second networking device acting as the sensing initiator and executing the sensing application.

16. (canceled)

17. The method of claim 1, wherein transferring the sensing measurement and the received noise power measurement to the sensing initiator includes transmitting the sensing measurement and the received noise power measurement to a second networking device acting as the sensing initiator in a sensing measurement report.

18. The method of claim 1, further comprising:
generating a data table including a plurality of received noise power measurements stored according to associated gains and associated frequencies, the data table including the received noise power measurement.

19-21. (canceled)

22. The method of claim 1, wherein associating the received noise power measurement with the sensing measurement is performed based upon a gain or a frequency or both.

23. A method for Wi-Fi sensing carried out by a networking device configured to operate as a sensing initiator and including at least one processor configured to execute instructions, the method comprising:
transmitting, by the sensing initiator, a sensing transmission to a sensing responder;
receiving, by the sensing initiator, a sensing measurement based on the sensing transmission;
obtaining, by the sensing initiator, a received noise power measurement associated with the sensing responder; and
transferring, by the sensing initiator, the sensing measurement and the received noise power measurement to a sensing application.

24. A system for Wi-Fi sensing comprising a networking device configured to operate as a sensing responder and including at least one processor configured to execute instructions, the system being configured for:
receiving sensing transmission transmitted from a sensing initiator;
performing a sensing measurement on the sensing transmission;
obtaining a received noise power measurement;
associating the received noise power measurement with the sensing measurement; and
transferring the sensing measurement and the received noise power measurement to a sensing initiator.

25. The system of claim 24, wherein obtaining the received noise power measurement includes accessing the received noise power measurement from data storage.

26-29. (canceled)

30. The system of claim 24, wherein obtaining the received noise power measurement includes determining the received noise power measurement during a standard operational mode of the sensing responder.

31. The system of claim 30, wherein determining the received noise power measurement includes performing the received noise power measurement during a period in which no signal is received.

32-36. (canceled)

37. The system of claim 24, wherein the system is further configured for:
transferring the sensing measurement and the received noise power measurement to a sensing application; and
performing, by the sensing application, a sensing algorithm to achieve a sensing goal according to the sensing measurement and the received noise power measurement.

38. The system of claim 37, wherein transferring the sensing measurement and the received noise power measurement to the sensing application and transferring the sensing measurement and the received noise power measurement to the sensing initiator are performed by transferring the sensing measurement and the received noise power measurement to a second networking device acting as the sensing initiator and executing the sensing application.

39. (canceled)

40. The system of claim 24, wherein transferring the sensing measurement and the received noise power measurement to the sensing initiator includes transmitting the sensing measurement and the received noise power measurement to a second networking device acting as the sensing initiator in a sensing measurement report.

41. The system of claim 24, wherein the system is further configured for:
generating a data table including a plurality of received noise power measurements stored according to associated gains and associated frequencies, the data table including the received noise power measurement.

42-44. (canceled)

45. The system of claim 24, wherein associating the received noise power measurement with the sensing measurement is performed based upon a gain or a frequency or both.

46. (canceled)
